(19) United States
(12) Patent Application Publication
(10) Pub. No.: US 2025/0347997 A1
(43) Pub. Date: Nov. 13, 2025

(54) ACTINIC RAY-SENSITIVE OR RADIATION-SENSITIVE RESIN COMPOSITION, RESIST FILM, PATTERN FORMING METHOD, AND METHOD FOR PRODUCING ELECTRONIC DEVICE

(71) Applicant: FUJIFILM CORPORATION, Tokyo (JP)

(72) Inventors: Tsutomu Yoshimura, Shizuoka (JP); Masafumi Kojima, Shizuoka (JP); Akiyoshi Goto, Shizuoka (JP); Kazuhiro Marumo, Shizuoka (JP)

(21) Appl. No.: 19/279,375

(22) Filed: Jul. 24, 2025

Related U.S. Application Data
(63) Continuation of application No. PCT/JP2024/006767, filed on Feb. 26, 2024.

(30) Foreign Application Priority Data
Mar. 8, 2023 (JP) 2023-035626

(51) Int. Cl. G03F 7/004

(52) U.S. Cl. CPC G03F 7/0045

(57) ABSTRACT

A first object of the invention is to provide an actinic ray-sensitive or radiation-sensitive resin composition that can maintain the ability to form a pattern having a good shape profile even after long-term storage. A second object of the invention is to provide a resist film, a pattern forming method, and an electronic device production method that use the actinic ray-sensitive or radiation-sensitive resin composition described above.

The actinic ray-sensitive or radiation-sensitive resin composition of the invention includes an onium salt represented by formula (1), an acid-decomposable resin, and a solvent.

### CROSS-REFERENCE TO RELATED APPLICATIONS

This application is a Continuation of PCT International Application No. PCT/JP2024/006767 filed on Feb. 26, 2024, which claims priority under 35 U.S.C. § 119(a) to Japanese Patent Application No. 2023-035626 filed on Mar. 8, 2023. The above applications are hereby expressly incorporated by reference, in their entirety, into the present application.

### BACKGROUND OF THE INVENTION

### 1. Field of the Invention

The present invention relates to an actinic ray-sensitive or radiation-sensitive resin composition, a resist film, a pattern forming method, and a method for producing an electronic device.

### 2. Description of the Related Art

Since the advent of resists for a KrF excimer laser (248 nm), a pattern forming method using chemical amplification has been used in order to compensate for a reduction in sensitivity due to light absorption. For example, in a positive chemical amplification method, a photoacid generator contained in exposed portions is first decomposed by irradiation with light to generate an acid. In the course of, for example, baking after the exposure (PEB: Post Exposure Baking), alkali-insoluble groups in a resin contained in an actinic ray-sensitive or radiation-sensitive resin composition are converted to alkali-soluble groups by the catalytic action of the acid generated to thereby change the solubility of the actinic ray-sensitive or radiation-sensitive resin composition in a developer. Then development is performed using, for example, a basic aqueous solution. In this manner, the exposed portions are removed, and a desired pattern is obtained.

To obtain semiconductor devices with finer features, the wavelengths of exposure light sources are being reduced, and the numerical apertures (NA) of projection lenses are being increased. An exposure device that uses an ArF excimer laser with a wavelength of 193 nm as a light source has already been developed. Moreover, the use of pattern forming methods using extreme ultraviolet rays (EUV light) and electron beams (EBs) has recently been considered.

In view of the foregoing circumstances, actinic ray-sensitive or radiation-sensitive resin compositions having various features have been proposed.

For example, WO2020/158313A discloses an actinic ray-sensitive or radiation-sensitive resin composition including the following compound (hereinafter referred to as a “compound Ba-1”) as a photoacid generator.

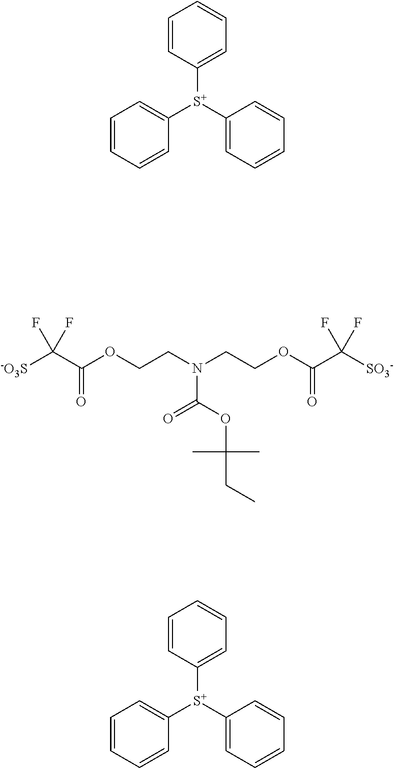

### SUMMARY OF THE INVENTION

The inventors have prepared an actinic ray-sensitive or radiation-sensitive resin composition containing the above-described compound (compound Ba-1) as a photoacid generator with reference to WO2020/158313A and conducted studies on the actinic ray-sensitive or radiation-sensitive resin composition. The inventors have found that there is room for improvement in the shape profile of a pattern formed using the actinic ray-sensitive or radiation-sensitive resin composition stored for a long time. More specifically, the inventors have found that there is room for further studies on an actinic ray-sensitive or radiation-sensitive resin composition that, even after long-term storage, can be used to form a pattern having a shape profile comparable to that of a pattern formed using the actinic ray-sensitive or radiation-sensitive resin composition immediately after its preparation (this actinic ray-sensitive or radiation-sensitive resin composition is hereinafter referred to also as an “actinic ray-sensitive or radiation-sensitive resin composition that can maintain the ability to form a pattern having a good shape profile even after long-term storage).

Accordingly, it is an object of the invention to provide an actinic ray-sensitive or radiation-sensitive resin composition that can maintain the ability to form a pattern having a good shape profile even after long-term storage.

It is another object of the invention to provide a resist film, a pattern forming method, and an electronic device production method that use the actinic ray-sensitive or radiation-sensitive resin composition described above.

The inventors have found that the foregoing problem can be solved by the following aspects.
[1] An actinic ray-sensitive or radiation-sensitive resin composition including:
an onium salt represented by formula (1) described later;
an acid-decomposable resin; and
a solvent.
[2] The actinic ray-sensitive or radiation-sensitive resin composition according to [1], wherein W is a group represented by any of formulas (W1) to (W4) described later.
[3] The actinic ray-sensitive or radiation-sensitive resin composition according to [1] or [2], wherein A is a group represented by formula (3) described later.
[4] The actinic ray-sensitive or radiation-sensitive resin composition according to any of [1] to [3], wherein at least one of M₁⁺ or M₂⁺ is an organic cation having a halogen atom in a molecule thereof.
[5] The actinic ray-sensitive or radiation-sensitive resin composition according to any of [1] to [4], wherein the acid-decomposable resin includes a repeating unit having a phenolic hydroxy group.
[6] A resist film formed of the actinic ray-sensitive or radiation-sensitive resin composition according to any of [1] to [5].
[7] A pattern forming method including the steps of:
forming a resist film on a substrate using the actinic ray-sensitive or radiation-sensitive resin composition according to any of [1] to [5];
exposing the resist film to light; and
developing the resist film exposed to the light using a developer to form a pattern.
[8] A method for producing an electronic device, the method including the pattern forming method according to [7].

The present invention can provide an actinic ray-sensitive or radiation-sensitive resin composition that can maintain the ability to form a pattern having a good shape profile even after long-term storage.

The present invention can also provide a resist film, a pattern forming method, and an electronic device production method that use the actinic ray-sensitive or radiation-sensitive resin composition.

### DESCRIPTION OF THE PREFERRED EMBODIMENTS

The present invention will next be described in detail.

Description of structural requirements described below may be made on the basis of representative embodiments of the present invention. However, the invention is not limited to theses embodiments.

With respect to the notations of groups (atomic groups) in the present specification, a notation that is not specified as substituted or unsubstituted is intended to encompass groups having no substituent and groups having a substituent, so long as the notation does not depart from the spirit of the invention. For example, an “alkyl group” is intended to encompass not only an alkyl group having no substituent (an unsubstituted alkyl group) but also an alkyl group having a substituent (a substituted alkyl group). In the present specification, an “organic group” is a group including at least one carbon atom.

Preferably, the substituent is a monovalent substituent, unless otherwise specified.

In the present specification, “actinic rays” or “radiation” means, for example, an emission line spectrum of a mercury lamp, far-ultraviolet rays typified by excimer laser light, extreme ultraviolet light (EUV light), X-rays, an electron beam (EB), etc. In the present specification, “light” means actinic rays or radiation.

In the present specification, “exposure to light” is intended to encompass not only exposure to an emission line spectrum of a mercury lamp, far-ultraviolet rays typified by excimer laser light, X-rays, EUV light, etc. but also image drawing using an electron beam or a particle beam such as an ion beam.

In the present specification, “to” is used to mean that numerical values before and after the “to” are used as the lower limit and the upper limit.

In the present specification, no limitation is imposed on the bonding direction of a divalent group, unless otherwise specified. For example, when Y in a compound represented by formula “X—Y—Z” is —COO—, Y may be —CO—O— or may be —O—CO—. This compound may be “X—CO—O—Z” or may be “X—O—CO—Z.”

In the present specification, the weight average molecular weight (Mw), number average molecular weight (Mn), and dispersity (referred to also as the molecular weight distribution) (Mw/Mn) of a resin are defined as polystyrene-equivalent values determined by GPC (Gel Permeation Chromatography) measurement (solvent: tetrahydrofuran, flow rate (injection amount of a sample): 10 μL, columns: TSK gel Multipore HXL-M manufactured by TOSOH Corporation, column temperature: 40° C., flow velocity: 1.0 mL/minute, detector: differential refractive index detector) using a GPC apparatus (HLC-8120GPC manufactured by TOSOH Corporation).

In the present specification, the acid dissociation constant (pKa) is the pKa in an aqueous solution and is specifically a value determined by computation using the following software package 1 based on a Hammett substituent constant and a database of known literature values. All pKa values in the present specification are values determined by computation using this software package.

Software package 1: Advanced Chemistry Development (ACD/Labs) Software V 8.14 for Solaris (1994-2007 ACD/Labs).

The pKa can also be determined by a molecular orbital calculation method. In one specific example of this method, H⁺ dissociation free energy in an aqueous solution is computed based on a thermodynamic cycle to compute the pKa. As for the method for computing the H⁺ dissociation free energy, the density functional theory (DFT), for example, can be used for the computation. Various other methods have been reported in literature etc., but the computation method is not limited thereto. There are a plurality of software applications capable of performing the DFT, and one example is Gaussian 16.

In the present specification, the pKa is a value determined by computation using the software package 1 based on the Hammett substituent constant and the database of known literature values as described above. When the pKa cannot be computed using this method, a value obtained using Gaussian 16 based on the DFT (density functional theory) is used. In the present specification, the pKa is a “value in an aqueous solution” as described above. When the pKa in an aqueous solution cannot be computed, the “pKa in a dimethyl sulfoxide (DMSO) solution” is used.

In the present specification, a halogen atom is, for example, a fluorine atom, a chlorine atom, a bromine atom, or an iodine atom.

In the present specification, solids mean components forming a resist film and do not include a solvent. Any component included in a resist film is regarded as a solid even when it is in a liquid form.

### [Actinic Ray-Sensitive or Radiation-Sensitive Resin Composition]

The actinic ray-sensitive or radiation-sensitive resin composition (hereinafter referred to also as the “resist composition”) of the invention contains an onium salt represented by formula (1) described later (this onium salt is hereinafter referred to as a “specific onium salt”), an acid-decomposable resin, and a solvent.

Even when the above-described resist composition of the invention stored for a long time is used to form a pattern, the pattern formed can still have a shape profile comparable to that of a pattern formed using the actinic ray-sensitive or radiation-sensitive resin composition immediately after its preparation. Specifically, even after long-term storage, the resist composition can maintain the ability to form a pattern having a good shape profile.

The detailed reason for this is unclear. However, the inventors infer that the reason is as follows.

The inventors have found the following. When a resist composition containing, as a photoacid generator, the compound (compound Ba-1) disclosed in WO2020/158313A is stored for a long time, the structural decomposition of the anion moieties of the compound Ba-1 may occur, but only to a very small extent, and/or the compound Ba-1 and another component of the resist composition such as an acid-decomposable resin may form aggregates. The inventors infer that, when the resist composition stored for a long time is formed into a resist film (actinic ray-sensitive or radiation-sensitive resin composition film), the oxygen concentration distribution in the film differs from the oxygen concentration distribution in the film formed using the resist composition immediately after its preparation because of the decomposition and/or aggregation described above and this makes it difficult to maintain the ability to form a pattern having a good shape profile.

The inventors have recently conducted studies based on the above findings and found the following. With the resist composition of the invention containing the specific onium salt, the structural decomposition of the anion moieties and/or the formation of aggregates of the resist composition and other components of the resist composition such as an acid-decomposable resin can be prevented. Therefore, even when the resist composition stored for a long time is used to form a pattern, the pattern formed can have a good shape profile comparable to that formed using the resist composition immediately after its preparation.

In the following description, when the ability to form a pattern having a good shape profile is more effectively maintained even when the resist composition stored for a long time is used for the pattern formation, the phrase “the effects of the invention are further enhanced” is used.

First, the components contained in the resist composition will be described.

### [Specific Onium Salt]

The resist composition contains the onium salt (specific onium salt) represented by formula (1).

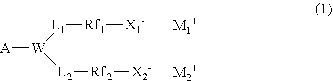

In formula (1), W represents a trivalent group having a nitrogen atom.

A represents a group that is bonded to the nitrogen atom contained in W and is dissociable under the action of acid or light. When A is dissociated under the action of acid or light, a primary amino group containing the nitrogen atom or a secondary amino group containing the nitrogen atom is generated.

L₁ and L₂ each independently represent *—O—**, *—CO—O—**, *—SO₂—**, *—O—CO—O—**, or *—O—SO₂—**. * represents a bonding position to W, and ** represents a bonding position to Rf₁ or Rf₂.

Rf₁ and Rf₂ each independently represent a divalent organic group having a fluorine atom.

X₁⁻ and X₂⁻ each independently represent *—SO₃⁻, *—SO₂—N⁻—Y, or a group represented by formula (2). * represents a bonding position, and Y represents an electron-withdrawing group. M₁⁺ and M₂⁺ each independently represent an organic cation.

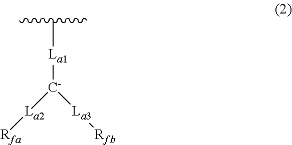

In formula (2), Lₐ₁, Lₐ₂, and Lₐ₃ each independently represent —CO— or —SO₂—.

R_{fa} and R_{fb} each independently represent a fluorinated alkyl group. The wavy line represents a bonding position to Rf₁ or Rf₂.

In formula (1), W represents a trivalent group having a nitrogen atom.

The nitrogen atom contained in W is preferably a nitrogen atom having an unshared electron pair not contributing to π-conjugation. The nitrogen atom having an unshared electron pair not contributing to π-conjugation is, for example, a nitrogen atom having a partial structure represented by any of the formulas shown below.

The dissociable group represented by A can be dissociated under the action of acid or light. In the residue from which the dissociable group represented by A has been dissociated, a hydrogen atom can be added in place of A to the nitrogen atom to which A was bonded. Specifically, when A is dissociated under the action of acid or light, a primary amino group including the nitrogen atom in W is generated (for example, when R_{w1} in formula (W2) described later is a hydrogen atom, a hydrogen atom is added in place of A to a bonding position to A represented by * under the action of acid or light, and a primary amino group is thereby generated), or a secondary amino group including the nitrogen atom is generated (for example, in the cases of formulas (W1), (W3), and (W4) described later and in the case where R_{w1} in formula (W2) is an alkyl group, a hydrogen atom is added in place of A to a bonding position to A represented by * under the action of acid or light, and a secondary amino group is thereby generated).

[symbol] Unshared Electron Pair

No particular limitation is imposed on the trivalent group having a nitrogen atom and represented by W. The trivalent group is preferably represented by, for example, one of formulas (W1) to (W4).

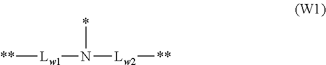

In formula (W1), L_{W1} and L_{W2} each independently represent a divalent linking group.

No particular limitation is imposed on the divalent linking groups represented by L_{W1} and L_{W2}. The divalent linking groups are each —CO—, —NR—, —O—, —S—, —SO—, —SO₂—, a linear or branched alkylene group (having preferably 1 to 10 carbon atoms and more preferably 1 to 6 carbon atoms), a cycloalkylene group (having preferably 3 to 15 carbon atoms and more preferably 6 to 10 carbon atoms), an alkenylene group (having preferably 2 to 10 carbon atoms and more preferably 2 to 6 carbon atoms), a divalent aliphatic heterocyclic group (preferably a 5- to 10-membered ring, more preferably a 5- to 7-membered ring, and still more preferably a 5- to 6-membered ring), a divalent aromatic heterocyclic group (preferably a 5- to 10-membered ring, more preferably a 5- to 7-membered ring, and still more preferably a 5- to 6-membered ring), a divalent aromatic hydrocarbon ring group (preferably a 6- to 10-membered ring and more preferably a 6-membered ring, such as a benzene ring group), or a divalent linking group formed by combining a plurality of groups selected from the group consisting of the above groups. R is a hydrogen atom or a monovalent organic group. No particular limitation is imposed on the monovalent organic group. The monovalent organic group is, for example, preferably an alkyl group (having preferably 1 to 6 carbon atoms).

The alkylene group, the cycloalkylene group, the alkenylene group, the divalent aliphatic heterocyclic group, the divalent aromatic heterocyclic group, and the divalent aromatic hydrocarbon ring group may each have a substituent. Examples of the substituent include halogen atoms (the substituent is preferably a fluorine atom).

The divalent linking groups represented by L_{W1} and L_{W2} are each particularly preferably a linear or branched alkylene group.

In formula (W1), * represents a bonding position to A shown in formula (1), and ** represents a bonding position to L₁ or L₂.

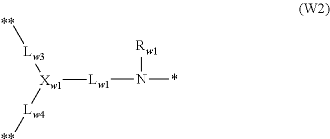

In formula (W2), L_{W3} and L_{W4} each independently represent a single bond or an alkylene group optionally containing at least one of —S— or —O—.

The alkylene group is preferably a linear or branched alkylene group and more preferably a linear alkylene group.

The number of carbon atoms in the alkylene group is preferably 1 to 10, more preferably 1 to 6, and still more preferably 1 to 3.

When the alkylene group contains at least one of —S— or —O—, an atom of the alkylene group that is on the side toward a bonding position to L₁ or L₂ (**) is preferably a carbon atom. In other words, it is preferable that the atom of the alkylene group that is on the side toward the bonding position to L₁ or L₂ (**) is not a sulfur atom (—S—) and an oxygen atom (—O—).

Examples of the alkylene groups optionally having at least one of —S— or —O— and represented by L_{W3} and L_{W4} include —CH₂—, —CH₂CH₂—, —CH₂CH₂CH₂—, —CH₂—S—, and —CH₂—O—.

L_{W5} represents a single bond or a divalent linking group.

Examples of the divalent linking group represented by L_{W5} are the same as those of the divalent linking groups represented by L_{W1} and L_{W2} in formula (W1).

The divalent linking group represented by L_{W5} is preferably —CO—, —O—, a linear or branched alkylene group (having preferably 1 to 10 carbon atoms and more preferably 1 to 6 carbon atoms), a cycloalkylene group (having preferably 3 to 15 carbon atoms and more preferably 6 to 10 carbon atoms), a divalent aromatic hydrocarbon ring group (preferably a 6- to 10-membered ring and more preferably a 6-membered ring such as a benzene ring group), or a divalent linking group formed by combining a plurality of groups selected from the group consisting of the above groups or is preferably —CO—, —O—, or a group represented by L_{WA}-Ar_{WA}-L_{WB}-. L_{WA} and L_{WB} each independently represent —CO—, —O—, a linear or branched alkylene group (having preferably 1 to 10 carbon atoms and more preferably 1 to 6 carbon atoms), or a divalent linking group formed by combining a plurality of groups selected from the group consisting of the above groups. Ar_{WA} represents a cycloalkylene group or a divalent aromatic hydrocarbon ring group.

R_{W1} represents a hydrogen atom or an alkyl group.

The alkyl group represented by R_{W1} is preferably a linear or branched alkyl group. The number of carbon atoms is preferably 1 to 6.

X_{W1} represents a trivalent aromatic ring group or a trivalent aliphatic ring group.

The number of ring member atoms of the aromatic ring in the trivalent aromatic ring group represented by X_{W1} is preferably 6 to 20, more preferably 6 to 10, and still more preferably 6.

The aromatic ring may be either monocyclic or polycyclic.

The aromatic ring is an aromatic hydrocarbon ring or an aromatic heterocyclic ring and is preferably an aromatic hydrocarbon ring.

The number of heteroatoms present as ring member atoms in the aromatic heterocyclic ring is, for example, 1 to 10. Examples of the heteroatom include a nitrogen atom, a sulfur atom, and an oxygen atom.

Specific examples of the aromatic ring include a benzene ring and a naphthalene ring.

The number of ring member atoms of the aliphatic ring included in the trivalent aliphatic ring group represented by X_{W1} is preferably 6 to 20, more preferably 6 to 15, and still more preferably 6 to 12.

The aliphatic ring may be either monocyclic or polycyclic.

The aliphatic ring is an aliphatic hydrocarbon ring or an aliphatic heterocyclic ring and is preferably an aliphatic hydrocarbon ring.

The number of heteroatoms present as ring member atoms in the aliphatic heterocyclic ring is, for example, 1 to 10. Examples of the heteroatom include a nitrogen atom, a sulfur atom, and an oxygen atom.

Specific examples of the aliphatic ring include a cyclohexane ring and an adamantane ring.

The trivalent aromatic ring group and the trivalent aliphatic ring group represented by X_{W1} may each further have a substituent. Examples of the substituent include halogen atoms.

In formula (W2), * represents a bonding position to A shown in formula (1), and ** represents a bonding position to L₁ or L₂ shown in formula (1).

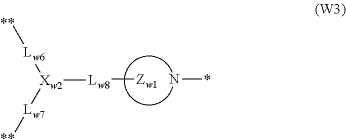

In formula (W3), L_{W6} and L_{W7} each independently represent a single bond or an alkylene group optionally containing at least one of —S— or —O—.

Examples of the alkylene groups optionally containing at least one of —S— or —O— and represented by L_{W6} and L_{W7} are the same as those of the alkylene groups optionally containing at least one of —S— or —O— and represented by L_{W3} and L_{W4} in formula (W2), and their preferred modes are also the same as those of L_{W3} and L_{W4}.

In formula (W3), L_{W8} represents a single bond or a divalent linking group.

Examples of the divalent linking group represented by L_{W8} are the same as those of the divalent linking groups represented by L_{W1} and L_{W2} in formula (W1).

The divalent linking group represented by L_{W8} is preferably —CO—, —O—, a linear or branched alkylene group (having preferably 1 to 10 carbon atoms and more preferably 1 to 6 carbon atoms), a cycloalkylene group (having preferably 3 to 15 carbon atoms and more preferably 6 to 10 carbon atoms), a divalent aromatic hydrocarbon ring group (preferably a 6- to 10-membered ring and more preferably a 6-membered ring such as a benzene ring group), or a divalent linking group formed by combining a plurality of groups selected from the group consisting of the above groups and is preferably —CO—, —O—, or a group represented by -L_{WA}-Ar_{WA}-L_{WB}-. L_{WA} and L_{WB} each independently represent —CO—, —O—, a linear or branched alkylene group (having preferably 1 to 10 carbon atoms and more preferably 1 to 6 carbon atoms), or a divalent linking group formed by combining a plurality of groups selected from the group consisting of the above groups. Ar_{WA} represents a cycloalkylene group or a divalent aromatic hydrocarbon ring group.

X_{W2} represents a trivalent aromatic ring group or a trivalent aliphatic ring group.

Examples of the trivalent aromatic ring group and the trivalent aliphatic ring group represented by X_{W2} are the same as those of the trivalent aromatic ring group and the trivalent aliphatic ring group represented by X_{W1} in (W2), and their preferred modes are also the same as those of X_{W1}.

Z_{W1} represents a ring containing a nitrogen atom (corresponding to the nitrogen atom shown in formula (W3)) as a ring member atom.

This ring may have, as a ring member atom, a heteroatom other than the nitrogen atom shown in formula (W3). Examples of the heteroatom include a nitrogen atom, a sulfur atom, and an oxygen atom. The number of heteroatoms other than the nitrogen atom shown in formula (W3) is preferably 0 to 5 and more preferably 0 to 2.

The number of ring member atoms of the ring represented by Z_{W1} is preferably 5 to 20, more preferably 5 to 15, still more preferably 6 to 10, and particularly preferably 6.

The ring represented by Z_{W1} may or may not have aromaticity. Specifically, the ring represented by Z_{W1} may be either a nitrogen-containing aromatic ring or a nitrogen-containing aliphatic ring.

The ring represented by Z_{W1} may be either monocyclic or polycyclic.

Examples of the ring represented by Z_{W1} include: nitrogen-containing aromatic rings such as an imidazole ring, a pyrazole ring, an oxazole ring, a thiazole ring, a pyridine ring, a pyridazine ring, a pyrimidine ring, a pyrazine ring, an indole ring, a quinoline ring, an isoquinoline ring, a quinazoline ring, and an acridine ring; and nitrogen-containing aliphatic rings such as a piperidine ring, a pyrroline ring, a pyrrolidine ring, an imidazoline ring, an imidazolidine ring, a pyrazoline ring, a pyrazolidine ring, a piperazine ring, and a morpholine ring.

The ring represented by Z_{W1} may further have a substituent. Examples of the substituent include halogen atoms.

In formula (W3), * represents a bonding position to A shown in formula (1), and ** represents a bonding position to L₁ or L₂ shown in formula (1).

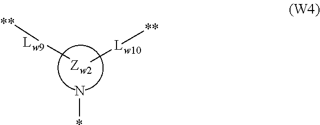

In formula (W4), L_{W9} and L_{W10} each independently represent a single bond or a divalent linking group.

Examples of the divalent linking groups represented by L_{W9} and L_{W10} are the same as those of the divalent linking groups represented by L_{W1} and L_{W2} in formula (W1), and their preferred modes are also the same as those of L_{W1} and L_{W2}.

Z_{W2} represents a ring containing a nitrogen atom (corresponding to the nitrogen atom shown in formula (W4)) as a ring member atom.

This ring may have, as a ring member atom, a heteroatom other that the nitrogen atom shown in formula (W4). Examples of the heteroatom include a nitrogen atom, a sulfur atom, and an oxygen atom. The number of heteroatoms other than the nitrogen atom shown in formula (W4) is preferably 0 to 5 and more preferably 0 to 2.

The number of ring member atoms of the ring represented by Z_{W2} is preferably 5 to 20, more preferably 5 to 15, still more preferably 6 to 10, and particularly preferably 6.

The ring represented by Z_{W2} may or may not have aromaticity. Specifically, the ring represented by Z_{W2} may be either a nitrogen-containing aromatic ring or a nitrogen-containing aliphatic ring.

The ring represented by Z_{W2} may be either monocyclic or polycyclic.

Specific examples of the ring represented by Z_{W2} include the nitrogen-containing aromatic rings and the nitrogen-containing aliphatic rings shown as the specific examples of the ring represented by Z_{W1} in formula (W3).

The ring represented by Z_{W2} may further have a substituent. Examples of the substituent include halogen atoms.

In formula (W4), * represents a bonding position to A shown in formula (1), and ** represents a bonding position to L₁ or L₂ shown in formula (1).

In formula (1), A represents a group that is bonded to the nitrogen atom contained in W and is dissociable under the action of acid or light.

When A is dissociated under the action of acid or light, a primary amino group containing the nitrogen atom contained in W or a secondary amino group containing the nitrogen atom is generated.

The phrase “dissociated under the action of acid or light” is intended to mean the breakage of the bond between A and the nitrogen atom contained in W under the action of acid or light and intended to encompass, for example, decomposition under the action of acid or light. The bond between A and W is preferably a covalent bond.

No particular limitation is imposed on A so long as it is a group bonded to the nitrogen atom contained in W and dissociable under the action of acid or light. Examples of A include: well-known protecting groups for amines (groups that are dissociable under the action of acid such as a Boc (t-butoxycarbonyl) group (which are hereinafter referred to also as “acid-dissociable groups”)); and groups that are dissociable under the action of light such as a 4-nitrobenzyloxycarbonyl group (which are hereinafter referred to also as photo-dissociable groups). An acid-decomposable group (such as a group represented by formula (Y3)) described later that can be contained in the acid-decomposable resin can also be used.

Specific examples of the acid-dissociable group represented by A include a group represented by formula (3).

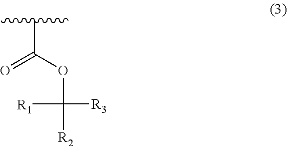

In formula (3), R₁, R₂, and R₃ each independently represent an organic group.

The organic groups represented by R₁ to R₃ are each preferably an alkyl group, an alkenyl group, or an aryl group.

The organic groups represented by R₁ to R₃ are each preferably a linear or branched alkyl group and more preferably a linear alkyl group because the effects of the invention are further enhanced.

The alkyl groups represented by R₁ to R₃ may each be a linear, branched, or cyclic alkyl group and are each preferably a linear or branched alkyl group and more preferably a linear alkyl group.

The number of carbon atoms in each of the linear or branched alkyl groups represented by R₁ to R₃ is preferably 1 to 10, more preferably 1 to 5, and still more preferably 1 to 3.

Specific examples of the linear or branched alkyl groups represented by R₁ to R₃ include a methyl group, an ethyl group, a n-propyl group, an isopropyl group, a n-butyl group, an isobutyl group, and a t-butyl group.

The cyclic alkyl groups (cycloalkyl groups) represented by R₁ to R₃ may each be either monocyclic or polycyclic.

The number of carbon atoms in each of the cycloalkyl groups represented by R₁ to R₃ is preferably 6 to 15 and more preferably 6 to 10.

Specific examples of the cycloalkyl groups represented by R₁ to R₃ include: monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

The alkenyl groups represented by R₁ to R₃ are each preferably a vinyl group.

The aryl groups represented by R₁ to R₃ are each preferably an aryl group having 6 to 10 carbon atoms, and examples thereof include a phenyl group, a naphthyl group, and an anthryl group.

In formula (3), two selected from the group consisting of R₁, R₂, and R₃ may be bonded together to form a ring.

This ring may be either monocyclic or polycyclic.

The ring is preferably a cycloalkyl group and more preferably a 5- to 6-membered monocyclic cycloalkyl group.

Specific examples of the ring include: monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

In formula (3), the wavy line represents a bonding position to the nitrogen atom contained in W.

Specific examples of the photo-dissociable group represented by A include a group represented by formula (4).

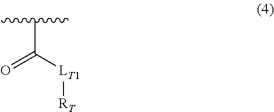

In formula (4), L_{T1} represents —CH═CH— or —O-L_{T11}-.

L_{T11} represents a linear or branched alkylene group having 1 to 6 carbon atoms.

The alkylene group represented by L_{T11} is preferably —CH₂— or —CH₂(CH₃)—.

R_{T} represents an anthracene ring group (such as a 9-anthryl group), an anthraquinone ring group (such as an anthraquinon-2-yl group), a phenyl group, an o-hydroxyphenyl group, or an o-nitrophenyl group.

In formula (4), the wavy line represents a bonding position to the nitrogen atom contained in W.

A is preferably an acid-dissociable group and more preferably the group represented by formula (3) because the effects of the invention are further enhanced.

In formula (1), L₁ and L₂ each independently represent *—O—**, *—CO—O—**, *—SO₂—**, *—O—CO—O—**, or *—O—SO₂—**.

In particular, L₁ and L₂ are each preferably *—SO₂—** or *—O—SO₂—** because the effects of the invention are further enhanced.

* represents a bonding position to W, and ** represents a bonding position to Rf₁ or Rf₂.

In formula (1), Rf₁ and Rf₂ each independently represent a divalent organic group having a fluorine atom.

No particular limitation is imposed on the divalent organic groups represented by Rf₁ and Rf₂ and each having a fluorine atom, and examples thereof include alkylene groups having at least one fluorine atom as a substituent and aromatic ring groups having at least one fluorine atom as a substituent.

The alkylene group having at least one fluorine atom as a substituent may be linear, branched, or cyclic, preferably linear or branched, and more preferably linear.

The number of carbon atoms in the alkylene group is preferably 1 to 12, more preferably 1 to 10, still more preferably 1 to 6, and most preferably 1 to 4.

The alkylene group having at least one fluorine atom as a substituent is particularly preferably a perfluoroalkylene group.

Specific examples of the alkylene group having at least one fluorine atom as a substituent include —CF₂—, —CF₂CF₂—, —CF₂CF₂CF₂—, —CF₂CF₂CF₂CF₂—, —CH₂CHF—, —CH₂CF₂—, —CH₂CF₂CF₂—, —C(CF₃)₂CH₂—, and —CHCF₃—CHCF₃—.

The aromatic ring included in the aromatic ring group having at least one fluorine atom as a substituent is preferably an aromatic hydrocarbon ring and more preferably a 6- to 10-membered aromatic hydrocarbon ring.

Specific examples of the aromatic ring group having at least one fluorine atom as a substituent include phenylene groups having a fluorine atom as a substituent.

When the phenylene group has a fluorine atom as a substituent, no particular limitation is imposed on the number of fluorine atoms. The number of fluorine atoms is preferably 1 to 4, more preferably 2 to 4, and still more preferably 2 or 3.

The divalent organic groups represented by Rf₁ and Rf₂ and having a fluorine atom are each preferably a perfluoroalkylene group or a phenylene group having a fluorine atom as a substituent (a fluorinated phenylene group) because the effects of the invention are further enhanced.

In formula (1), X₁⁻ and X₂⁻ each independently represent *—SO₃⁻, *—SO₂—N⁻—Y, or the group represented by formula (2).

In particular, X₁⁻ and X₂⁻ are each preferably *—SO₃⁻ because the effects of the invention are further enhanced.

* represents a bonding position. Y represents an electron-withdrawing group.

In the present specification, whether the substituent represented by Y is an electron-withdrawing group is determined using the value of the acid dissociation constant pKa of a carboxylic acid group that is computed using, as a model compound, a benzoic acid having Y as a substituent at the para position. When the substituent represented by Y is an electron-withdrawing group, the value of the acid dissociation constant pKa of the carboxylic acid group that is computed using, as a model compound, the benzoic acid having Y as a substituent at the para position is 3.8 or less. Specifically, when, for example, the substituent is an —SO₂—CF₃ group, the value of the acid dissociation constant pKa of the carboxylic acid group in the model compound obtained by substituting the —SO₂—CF₃ group into Y in the following formula (X) is used to determine whether the —SO₂—CF₃ group is an electron-withdrawing group. The method for measuring the acid dissociation constant pKa is as described above.

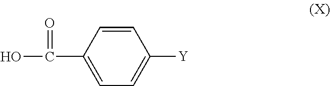

The electron-withdrawing group represented by Y is particularly preferably a group in which the value of the acid dissociation constant pKa of the carboxylic acid group is 3.5 or less. No particular limitation is imposed on the lower limit of the acid dissociation constant pKa, and the acid dissociation constant pKa is, for example, preferably 1.0 or more.

Specific examples of the electron-withdrawing group include: groups including a S═O bond (e.g., groups including a bond such as —SO— or —SO₂—); alkyl groups substituted with at least one halogen atom (which are hereinafter referred to also as “halogenated alkyl groups”); and aryl groups substituted with at least one halogen atom (which are hereinafter referred to also as “halogenated aromatic ring groups”). In particular, the electron-withdrawing group is preferably —SO—R^{X}, —SO₂—R^{X}, a halogenated alkyl group, or a halogenated aromatic ring group, more preferably —SO₂—R^{X}, a halogenated alkyl group, or a halogenated aromatic ring group, and still more preferably —SO₂—R^{X} or a halogenated aromatic ring group because the effects of the invention are further enhanced.

R^{X} represents a hydrogen atom or a substituent.

No particular limitation is imposed on the substituent represented by R^{X}, and R^{X} is preferably an alkyl group or an aromatic ring group.

The number of carbon atoms in the alkyl group is preferably 1 to 20, more preferably 1 to 10, and still more preferably 1 to 6.

The alkyl group may be linear, branched, or cyclic.

The alkyl group may further have a substituent. In particular, the substituent is preferably a halogen atom (preferably a fluorine atom). When the alkyl group has a halogen atom as a substituent, some of the hydrogen atoms may be replaced with halogen atoms, or all the hydrogen atoms may be replaced with halogen atoms.

The number of ring member atoms of the aromatic ring included in the aromatic ring group is preferably 6 to 20, more preferably 6 to 10, and still more preferably 6.

The aromatic ring may be either monocyclic or polycyclic.

Examples of the aromatic ring include aromatic hydrocarbon rings and aromatic heterocyclic rings. In particular, the aromatic ring is preferably an aromatic hydrocarbon ring.

The number of heteroatoms included in the aromatic heterocyclic ring as ring member atoms is, for example, 1 to 10. Examples of the heteroatom include a nitrogen atom, a sulfur atom, and an oxygen atom.

Specific examples of the aromatic ring include a benzene ring and a naphthalene ring.

The aromatic ring group may further have a substituent. The substituent is preferably a halogen atom (preferably a fluorine atom).

The halogenated alkyl group is preferably a linear or branched alkyl group substituted with at least one halogen atom and having 1 to 20 carbon atoms (preferably 1 to 10 carbon atoms and more preferably 1 to 6 carbon atoms). In the halogenated alkyl group, some of the hydrogen atoms may be replaced with halogen atoms, or all the hydrogen atoms may be replaced with halogen atoms.

The halogenated aromatic ring group is more preferably an aryl group substituted with at least one halogen atom and having 6 to 15 ring member atoms (preferably 6 to 10 ring member atoms). Examples of the halogenated aromatic ring group include a phenyl group substituted with a halogen atom and a naphthyl group substituted with a halogen atom.

The halogenated alkyl group and the halogenated aromatic ring group may each have a substituent other than halogen atoms.

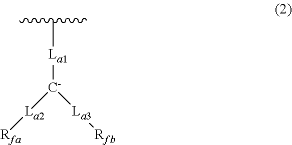

In formula (2), Lₐ₁, Lₐ₂, and Lₐ₃ each independently represent —CO— or —SO₂—.

In formula (2), R_{fa} and R_{fb} each independently represent a fluorinated alkyl group.

The fluorinated alkyl groups represented by R_{fa} and R_{fb} are each preferably a linear or branched alkyl group substituted with at least one fluorine atom and having 1 to 20 carbon atoms (preferably 1 to 10 carbon atoms and more preferably 1 to 6 carbon atoms). In the fluorinated alkyl groups, some of the hydrogen atoms may be replaced with fluorine atoms, and all the hydrogen atoms may be replaced with fluorine atoms (i.e., the fluorinated alkyl groups may each be a perfluoroalkyl group).

In formula (2), the wavy line represents a bonding position to Rf₁ or Rf₂.

In formula (1), M₁⁺ and M₂⁺ each independently represent an organic cation.

Preferred modes of the organic cations represented by M₁⁺ and M₂⁺ in formula (1) will be described in detail.

The organic cations represented by M₁⁺ and M₂⁺ are each independently preferably an organic cation represented by formula (ZaI) (a cation (ZaI)) or an organic cation represented by formula (ZaII) (a cation (ZaII)).

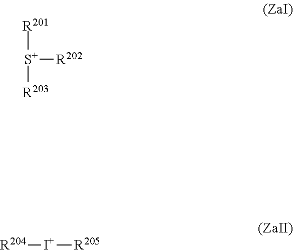

In formula (ZaI),

R²⁰¹, R²⁰², and R²⁰³ each independently represent an organic group.

The number of carbon atoms in each of the organic groups used as R²⁰¹, R²⁰², and R²⁰³ is generally 1 to 30 and preferably 1 to 20. Two selected from the group consisting of R²⁰¹ to R²⁰³ may be bonded together to form a ring structure, and the ring may contain an oxygen atom, a sulfur atom, an ester group, an amido group, or a carbonyl group. Examples of the group formed from two selected from the group consisting of R²⁰¹ to R²⁰³ that are bonded together include alkylene groups (such as a butylene group and a pentylene group) and —CH₂—CH₂—O—CH₂—CH₂—.

Preferred examples of the form of the organic cation in formula (ZaI) include a cation (ZaI-1), a cation (ZaI-2), an organic cation (cation (ZaI-3b)) represented by formula (ZaI-3b), and an organic cation (cation (ZaI-4b)) represented by formula (ZaI-4b) that will be described later.

First, the cation (ZaI-1) will be described.

The cation (ZaI-1) is an arylsulfonium cation in which at least one of R²⁰¹, R²⁰², or R²⁰³ in formula (ZaI) is an aryl group.

In the arylsulfonium cation, each of R₂₀₁ to R₂₀₃ may be an aryl group. Alternatively, some of R₂₀₁ to R₂₀₃ may be an aryl group, and the rest may be an alkyl group or a cycloalkyl group.

Alternatively, one of R²⁰¹, R²⁰², or R²⁰³ may be an aryl group, and the remaining two of R²⁰¹ to R²⁰³ may be bonded together to form a ring structure. The ring may contain an oxygen atom, a sulfur atom, an ester group, an amido group, or a carbonyl group. Examples of the group formed by bonding two selected from the group consisting of R²⁰¹ to R²⁰³ together include alkylene groups in which at least one methylene group is replaced by an oxygen atom, a sulfur atom, an ester group, an amido group, and/or a carbonyl group (such as a butylene group, a pentylene group, and —CH₂—CH₂—O—CH₂—CH₂—).

Examples of the arylsulfonium cation include triarylsulfonium cations, diarylalkylsulfonium cations, aryldialkylsulfonium cations, diarylcycloalkylsulfonium cations, and aryldicycloalkylsulfonium cations.

Each aryl group included in the arylsulfonium cation is preferably a phenyl group or a naphthyl group and is more preferably a phenyl group. The aryl group may have a heterocyclic structure having an oxygen atom, a nitrogen atom, a sulfur atom, etc. Examples of the heterocyclic structure include a pyrrole residue, a furan residue, a thiophene residue, an indole residue, a benzofuran residue, and a benzothiophene residue. When the arylsulfonium cation has two or more aryl groups, the two or more aryl groups may be the same or different.

The alkyl group or the cycloalkyl group optionally contained in the arylsulfonium cation is preferably a linear alkyl group having 1 to 15 carbon atoms, a branched alkyl group having 3 to 15 carbon atoms, or a cycloalkyl group having 3 to 15 carbon atoms and more preferably, for example, a methyl group, an ethyl group, a propyl group, a n-butyl group, a sec-butyl group, a t-butyl group, a cyclopropyl group, a cyclobutyl group, or a cyclohexyl group.

The aryl, alkyl, and cycloalkyl groups represented by R²⁰¹ to R²⁰³ may each independently have a substituent, and the substituent is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom (for example, a fluorine atom or an iodine atom), a hydroxy group, a carboxy group, an ester group, a sulfinyl group, a sulfonyl group, an alkylthio group, a phenylthio group, etc.

Each substituent may have a substituent if possible. For example, the alkyl group may have a halogen atom as a substituent and therefore may be a halogenated alkyl group such as a trifluoromethyl group.

Next, the cation (ZaI-2) will be described.

The cation (ZaI-2) is a cation in which R²⁰¹ to R²⁰³ in formula (ZaI) each independently represent an organic group having no aromatic ring.

The number of carbon atoms in each of the organic groups having no aromatic ring and represented by R²⁰¹ to R²⁰³ is generally 1 to 30 and preferably 1 to 20.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

Examples of the alkyl and cycloalkyl groups represented by R²⁰¹ to R²⁰³ include: linear alkyl groups having 1 to 10 carbon atoms and branched alkyl groups having 3 to 10 carbon atoms (such as a methyl group, an ethyl group, a propyl group, a butyl group, and a pentyl group); and cycloalkyl groups having 3 to 10 carbon atoms (such as a cyclopentyl group, a cyclohexyl group, and a norbornyl group).

R²⁰¹ to R²⁰³ may each be further substituted with a halogen atom (such as a fluorine atom or an iodine atom), an alkoxy group (having, for example, 1 to 5 carbon atoms), a hydroxy group, a cyano group, or a nitro group.

Next, the cation (ZaI-3b) will be described.

The cation (ZaI-3b) is a cation represented by the following formula (ZaI-3b).

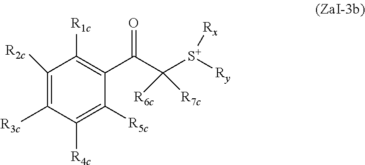

In formula (ZaI-3b),

R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom (such as a fluorine atom or an iodine atom), a hydroxy group, a nitro group, an alkylthio group, or an arylthio group.

R_{6c} and R_{7c} each independently represent a hydrogen atom, an alkyl group (such as a t-butyl group), a cycloalkyl group, a halogen atom (such as a fluorine atom or an iodine atom), a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

A combination of two or more selected from the group consisting of R_{1c} to R_{5c}, a pair of R_{5c} and R_{6c}, a pair of R_{6c} and R_{7c}, a pair of R_{5c} and Rₓ, and a pair of Rₓ and R_{y} may each be bonded together to form a ring. These rings may each independently contain an oxygen atom, a sulfur atom, a ketone group, an ester bond, or an amide bond.

Each ring may be an aromatic or non-aromatic hydrocarbon ring, an aromatic or non-aromatic heterocyclic ring, or a polycyclic condensed ring formed by combining two or more of the above rings. The ring may be a 3- to 10-membered ring and is preferably a 4- to 8-membered ring and more preferably a 5- or 6-membered ring.

Examples of the groups formed by bonding two or more selected from the group consisting of R_{1c} to R_{5c}, bonding R_{6c} and R_{7c}, and bonding Rₓ and R_{y} include alkylene groups such as a butylene group and a pentylene group. A methylene group in the alkylene group may be replaced with a heteroatom such as an oxygen atom.

The group formed by bonding R_{5c} and R_{6c} and the group formed by bonding R_{5c} and Rₓ are each preferably a single bond or an alkylene group. Examples of the alkylene group include a methylene group and an ethylene group.

Next, the cation (ZaI-4b) will be described.

The cation (ZaI-4b) is a cation represented by the following formula (ZaI-4b).

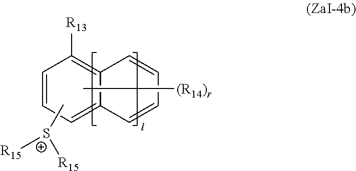

In formula (ZaI-4b),

l represents an integer of 0 to 2.

r represents an integer of 0 to 8.

R₁₃ represents a hydrogen atom, a halogen atom (such as a fluorine atom or an iodine atom), a hydroxy group, an alkyl group, a halogenated alkyl group, an alkoxy group, a carboxy group, an alkoxycarbonyl group, or a group having a cycloalkyl group (a cycloalkyl group itself or a group including a cycloalkyl group as a part thereof).

R₁₄ represents a hydroxy group, a halogen atom (such as a fluorine atom or an iodine atom), an alkyl group, a halogenated alkyl group, an alkoxy group, an alkoxycarbonyl group, an alkylcarbonyl group, an alkylsulfonyl group, a cycloalkylsulfonyl group, or a group having a cycloalkyl group (a cycloalkyl group itself or a group including a cycloalkyl group as a part thereof).

R₁₅'s each independently represent an alkyl group, a cycloalkyl group, or a naphthyl group. The two R₁₅'s may be bonded together to form a ring. When the two R₁₅'s are bonded together to form a ring, the skeleton of the ring may contain a heteroatom such as an oxygen atom or a nitrogen atom. In one preferred mode, the two R₁₅'s are each an alkylene group and are bonded together to form a ring structure.

In formula (ZaI-4b), the alkyl group represented by each of R₁₃, R₁₄, and R₁₅ is preferably a linear or branched alkyl group. Preferably, the number of carbon atoms in the alkyl group is 1 to 10. Each alkyl group is more preferably a methyl group, an ethyl group, a n-butyl group, a t-butyl group, etc.

Next, formula (ZaII) will be described.

In formula (ZaII), R²⁰⁴ and R²⁰⁵ each independently represent an aryl group, an alkyl group, or a cycloalkyl group.

The aryl groups represented by R²⁰⁴ and R²⁰⁵ are each preferably a phenyl group or a naphthyl group and more preferably a phenyl group. The aryl groups represented by R²⁰⁴ and R²⁰⁵ may each be an aryl group having a heterocycle having an oxygen atom, a nitrogen atom, or a sulfur atom. Examples of the skeleton of the aryl group having a heterocycle include pyrrole, furan, thiophene, indole, benzofuran, and benzothiophene.

The alkyl or cycloalkyl group represented by each of R²⁰⁴ and R²⁰⁵ is preferably a linear alkyl group having 1 to 10 carbon atoms or a branched alkyl group having 3 to 10 carbon atoms (such as a methyl group, an ethyl group, a propyl group, a butyl group, or a pentyl group) or is preferably a cycloalkyl group having 3 to 10 carbon atoms (such as a cyclopentyl group, a cyclohexyl group, or a norbornyl group).

The aryl, alkyl, and cycloalkyl groups represented by R²⁰⁴ and R²⁰⁵ may each independently have a substituent. Examples of the optional substituents in the aryl, alkyl, and cycloalkyl groups represented by R²⁰⁴ and R²⁰⁵ include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms (such as a fluorine atom and an iodine atom), a hydroxy group, and a phenylthio group.

Preferably, at least one of the organic cations represented by M₁⁺ and M₂⁺ has a halogen atom because the effects of the invention are further enhanced. The halogen atom is preferably a fluorine atom or an iodine atom.

Preferably, the specific onium salt satisfies at least one (preferably at least two and more preferably all three) of the following requirements X1 to X3 because the effects of the invention are further enhanced.

Requirement X1: The group that is represented by A in the specific onium salt, bonded to the nitrogen atom contained in W, and is dissociable under the action of acid or light is the group represented by formula (3).

Requirement X2: At least one of the organic cations represented by M₁⁺ and M₂⁺ in the specific onium salt has a halogen atom.

Requirement X3: Portions of the specific onium salt corresponding to “the moiety represented by -L₁-R_{f1}—X₁⁻” and “the moiety represented by -L₂-Rf₂—X₂⁻” each have a structure represented by formula (F1) or formula (F2).

-L_{A1}-perfluoroalkylene group-SO₃⁻ Formula (F1)

In formula (F1), L_{A1} represents *—SO₂—** or *—O—SO₂—**.

-L_{A2}-fluorinated phenylene group-SO₃⁻ Formula (F2)

In formula (F2), L_{A2} is the same as L₁ in formula (1), and its preferred modes are the same as those of L₁.

The molecular weight of the specific onium salt is preferably 100 to 3,000, more preferably 200 to 2,500, and still more preferably 500 to 2,500.

The lower limit of the content of the specific onium salt in the resist composition with respect to the total amount of the solids in the composition is preferably 1% by mass or more, more preferably 5% by mass or more, and still more preferably 10% by mass or more. The upper limit of the content of the specific onium salt with respect to the total amount of the solids in the composition is preferably 80% by mass or less, more preferably 70% by mass or less, and still more preferably 60% by mass or less.

One specific onium salt may be used alone, or two or more specific onium salts may be used. When two or more specific onium salts are used, it is preferable that the total content of the specific onium salts is within the preferred ranges described above.

The specific onium salt can be synthesized by a well-known method.

Specific examples of the specific onium salt are shown below. However, the invention is not limited these examples.

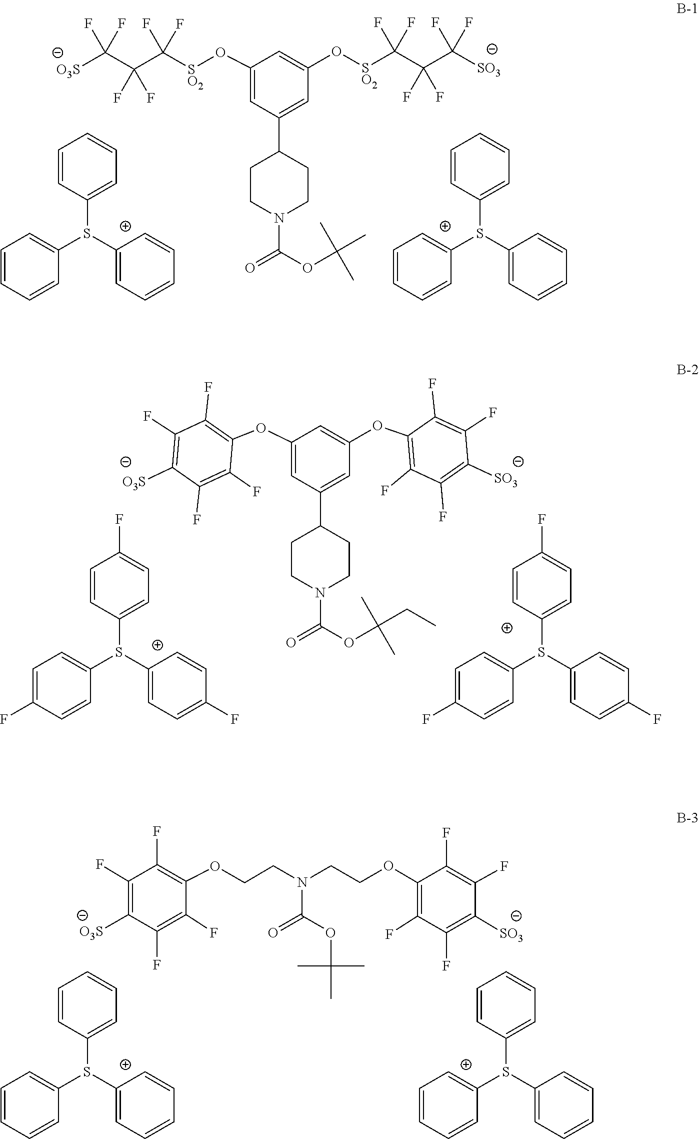

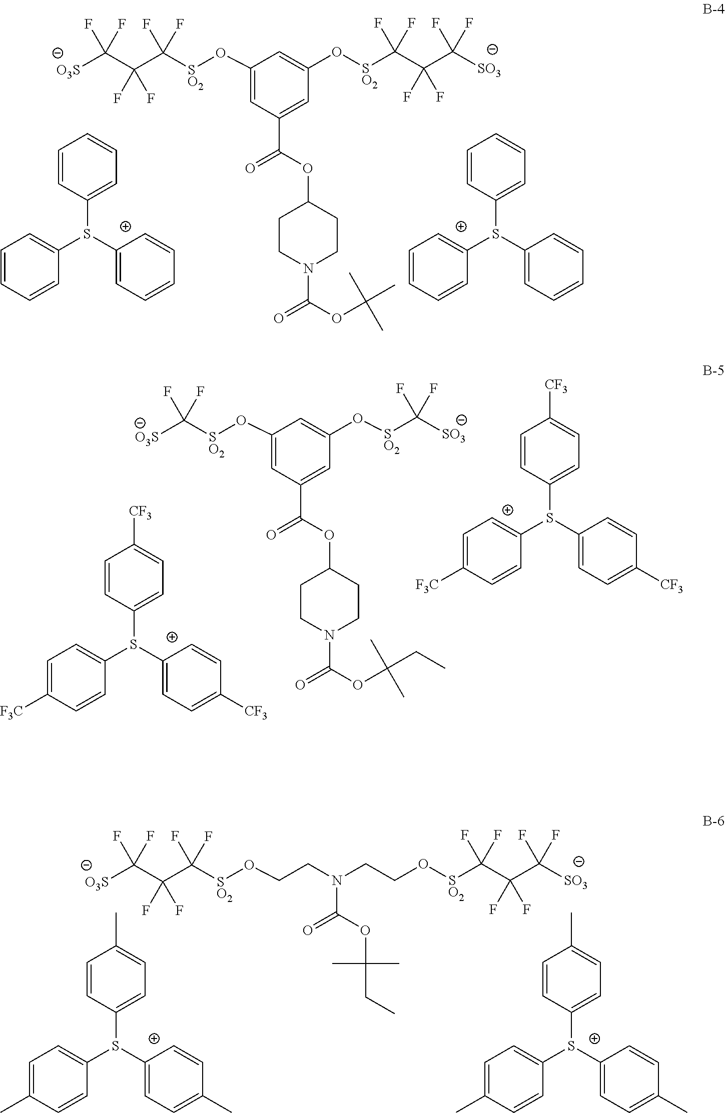

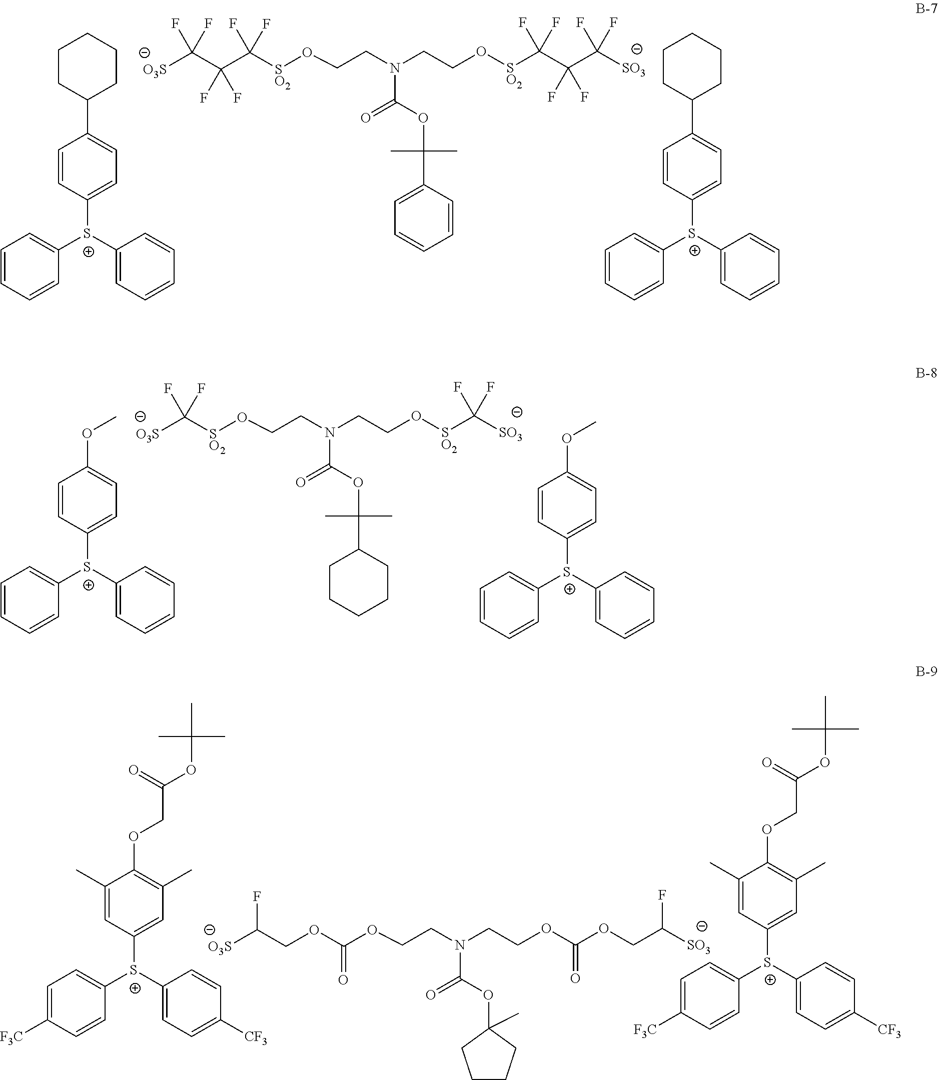

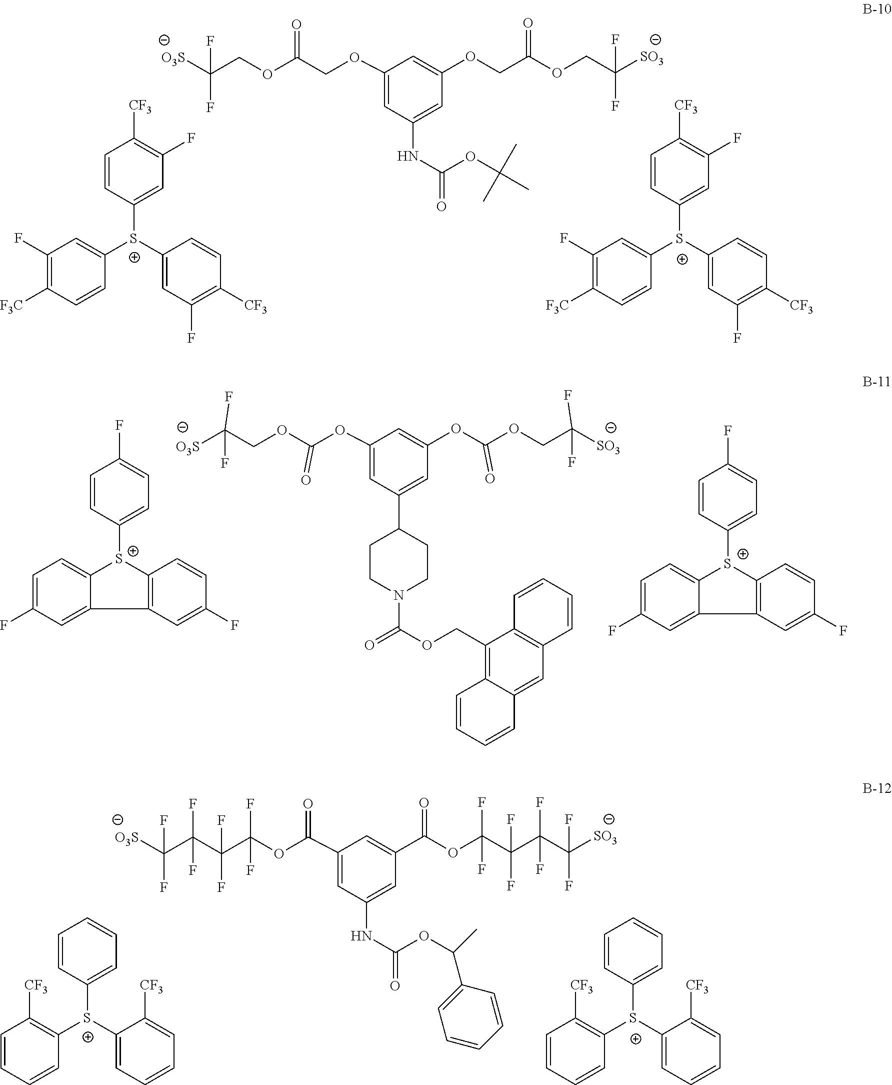

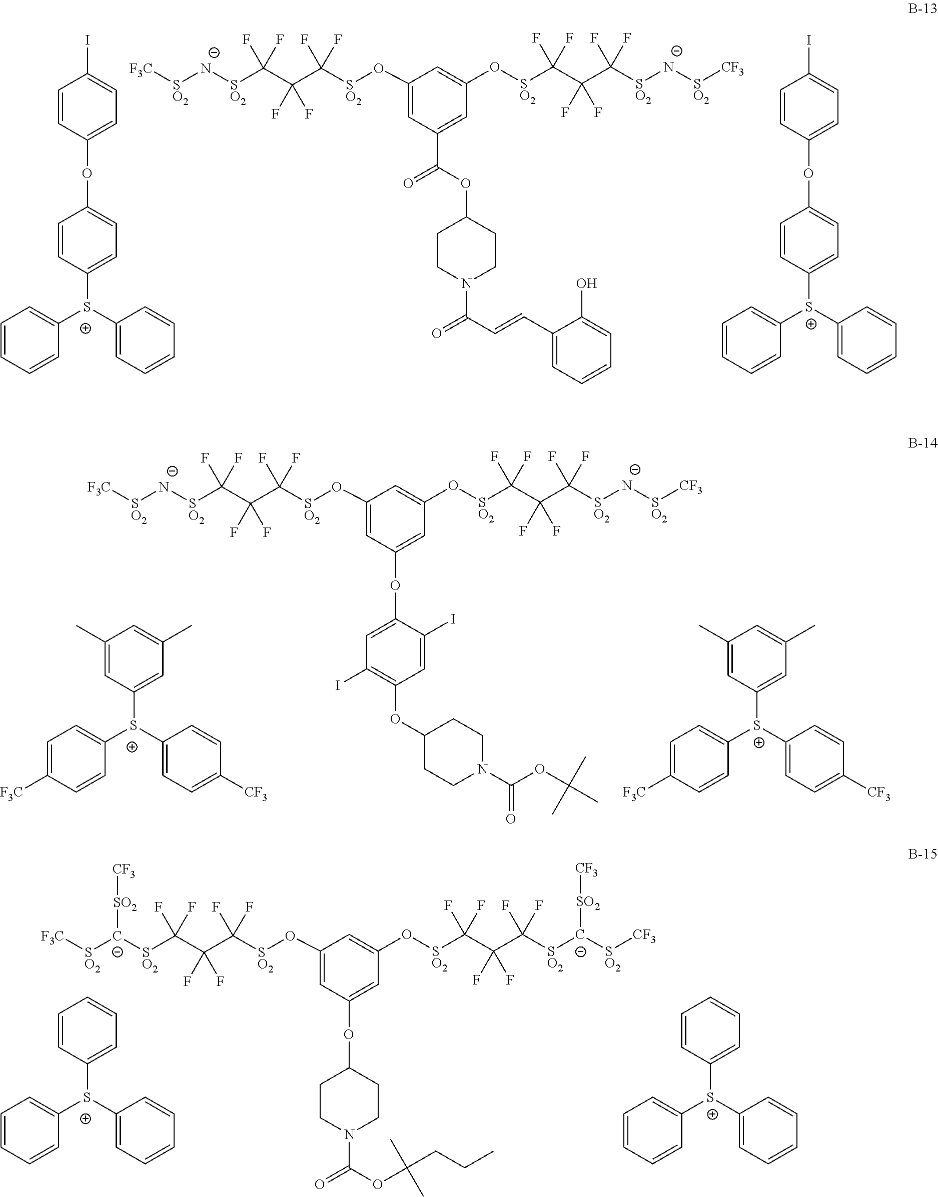

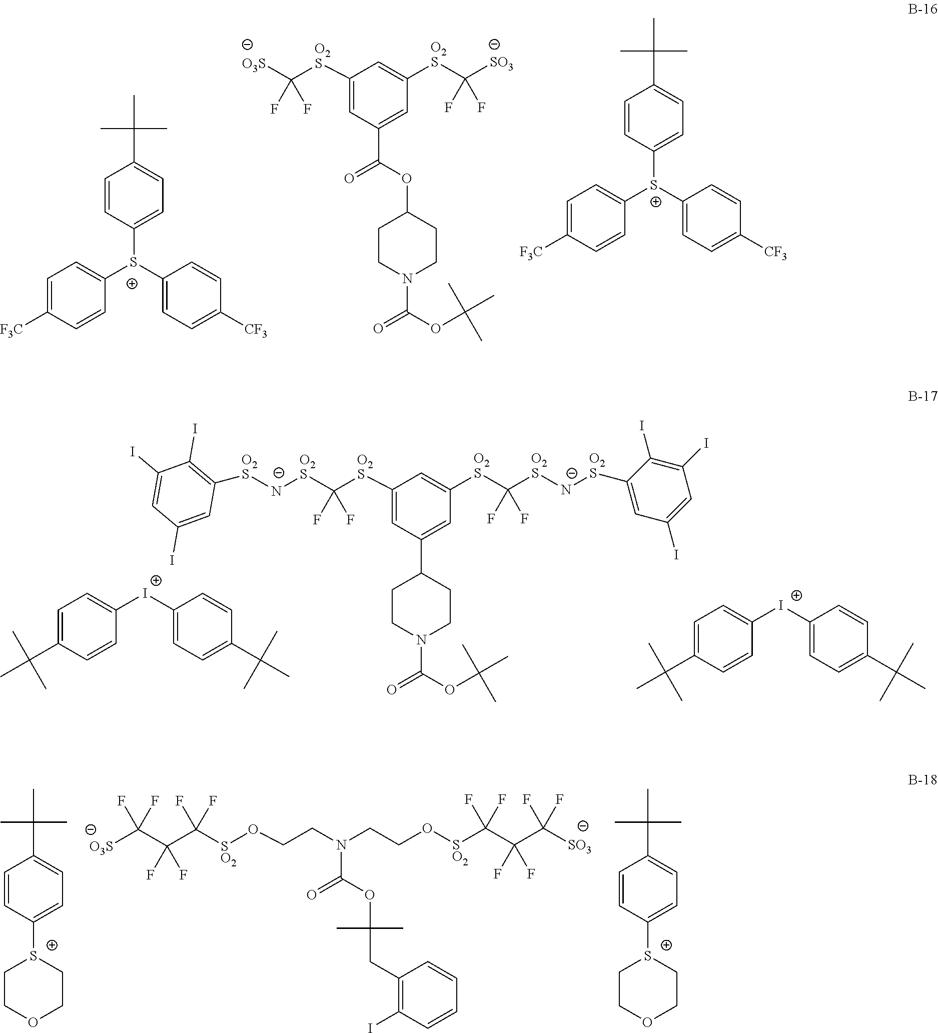

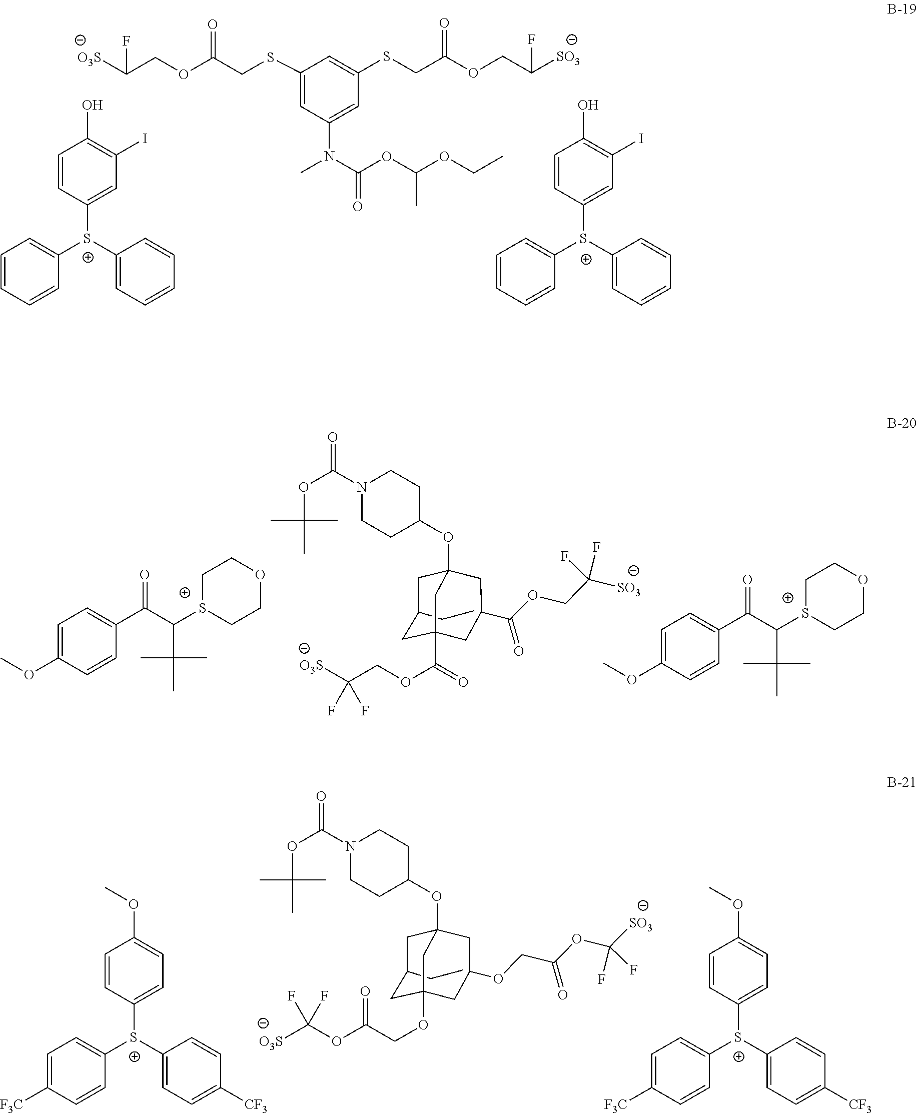

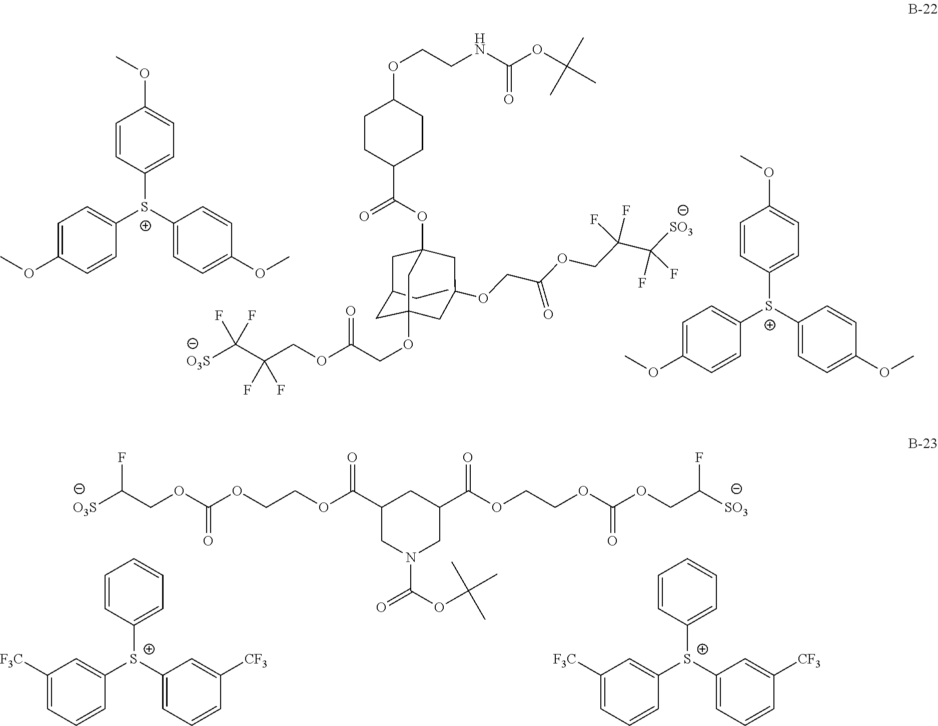

### [Acid-Decomposable Resin (Resin (A))]

The resist composition contains an acid-decomposable resin (hereinafter referred to also as a “resin (A)”).

The acid-decomposable resin is a resin that is decomposed under the action of acid and thereby increased in polarity. Specifically, when a pattern is formed using the acid-decomposable resin, it is typical that a positive-type pattern is preferably formed when the developer used is an alkali developer and that a negative-type pattern is preferably formed when the developer used is an organic-based developer.

Generally, the resin (A) includes a group that is decomposed under the action of acid and thereby increased in polarity (this group is hereinafter referred to also as an “acid-decomposable group”) and includes preferably a repeating unit having the acid-decomposable group.

### <Repeating Unit Having Acid-Decomposable Group>

Preferably, the acid-decomposable group has a structure in which a polar group is protected by a dissociable group that is dissociable under the action of acid. In other words, the acid-decomposable group means a group that is decomposed under the action of acid to generate a polar group.

Preferably, the resin (A) includes a repeating unit having the acid-decomposable group. When the resin (A) includes the repeating unit having the acid-decomposable group, the polarity increases under the action of acid. In this case, the degree of solubility in an alkali developer increases, and the degree of solubility in an organic solvent decreases.

The acid-decomposable group will next be described, and then the repeating unit having the acid-decomposable group will be described.

### (Acid-Decomposable Group)

The acid-decomposable group is a group that is decomposed under the action of acid to generate a polar group. Preferably, the acid-decomposable group has a structure in which the polar group is protected by a dissociable group that is dissociable under the action of acid. The acid-decomposable group can be decomposed under the action of acid to generate the polar group.

The polar group is preferably an alkali-soluble group, and examples thereof include: acidic groups such as a carboxy group, phenolic hydroxy groups, fluorinated alcohol groups, sulfonic acid groups, phosphoric acid groups, sulfonamido groups, sulfonylimido groups, (alkylsulfonyl)(alkylcarbonyl)methylene groups, (alkylsulfonyl)(alkylcarbonyl)imido groups, bis(alkylcarbonyl)methylene groups, bis(alkylcarbonyl)imido groups, bis(alkylsulfonyl)methylene groups, bis(alkylsulfonyl)imido groups, tris(alkylcarbonyl)methylene groups, and tris(alkylsulfonyl)methylene groups; and alcoholic hydroxyl groups.

In particular, the polar group is preferably a carboxy group, a phenolic hydroxy group, a fluorinated alcohol group (preferably a hexafluoroisopropanol group), or a sulfonic acid group.

Examples of the dissociable group that is dissociable under the action of acid include groups represented by formulas (Y1) to (Y4).

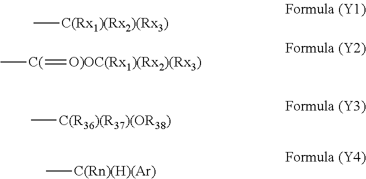

In formulas (Y1) and (Y2), Rx₁ to Rx₃ each independently represent a linear or branched alkyl group, a cycloalkyl group, an alkenyl group, or an aryl group. Two selected from the group consisting of Rx₁ to Rx₃ may be bonded together to form a ring.

When all of Rx₁ to Rx₃ are each a linear or branched alkyl group, it is preferable that at least two selected from the group consisting of Rx₁ to Rx₃ are each a methyl group.

In particular, Rx₁ to Rx₃ are each preferably a linear or branched alkyl group and more preferably a linear alkyl group.

The linear or branched alkyl groups represented by Rx₁ to Rx₃ are each preferably a linear alkyl group.

The number of carbon atoms in each of the linear or branched alkyl groups represented by Rx₁ to Rx₃ is preferably 1 to 10, more preferably 1 to 5, and still more preferably 1 to 3.

Specific examples of the linear or branched alkyl groups represented by Rx₁ to Rx₃ include a methyl group, an ethyl group, a n-propyl group, an isopropyl group, a n-butyl group, an isobutyl group, and a t-butyl group.

The cycloalkyl groups represented by Rx₁ to Rx₃ may each be either monocyclic or polycyclic.

The number of carbon atoms in each of the cycloalkyl groups represented by Rx₁ to Rx₃ is preferably 6 to 15 and more preferably 6 to 10.

Specific examples of the cycloalkyl groups represented by Rx₁ to Rx₃ include: monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

The alkenyl groups represented by Rx₁ to Rx₃ are each preferably a vinyl group.

The aryl groups represented by Rx₁ to Rx₃ are each preferably an aryl group having 6 to 10 carbon atoms, and examples thereof include a phenyl group, a naphthyl group, and an anthryl group.

Two selected from the group consisting of Rx₁ to Rx₃ may be bonded together to form a ring.

The ring may be either monocyclic or polycyclic.

The ring is preferably a cycloalkyl group and more preferably a 5- to 6-membered monocyclic cycloalkyl group.

Specific examples of the ring include: monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

For example, one methylene group included in the ring in the cycloalkyl group formed by bonding two selected from the group consisting of Rx₁ to Rx₃ may be replaced with a heteroatom such as an oxygen atom, a group having a heteroatom such as a carbonyl group, or a vinylidene group. In any of these cycloalkyl groups, at least one ethylene group included in the cycloalkane ring may be replaced with a vinylene group.

In the group represented by formula (Y1) or formula (Y2), it is preferable that, for example, Rx₁ is a methyl group or an ethyl group and that Rx₂ and Rx₃ are bonded together to form the cycloalkyl group described above.

When the resist composition is, for example, a resist composition for EUV exposure, it is also preferable that the linear or branched alkyl, cycloalkyl, alkenyl, and aryl groups represented by Rx₁ to Rx₃ and the ring formed by bonding two selected from the group consisting of Rx₁ to Rx₃ each further have a fluorine atom or an iodine atom as a substituent.

In formula (Y3), R₃₆ to R₃₈ each independently represent a hydrogen atom or a monovalent organic group. R₃₇ and R₃₈ may be bonded together to form a ring.

It is also preferable that R₃₆ is a hydrogen atom.

Examples of the monovalent organic group include linear or branched alkyl groups, cycloalkyl groups, aryl groups, aralkyl groups, and alkenyl groups.

In the linear or branched alkyl groups, the cycloalkyl groups, the aryl groups, and the aralkyl groups, at least one methylene group may be replaced with a group selected from the group consisting of heteroatoms such as an oxygen atom and atomic groups having a heteroatom such as a carbonyl group. Specifically, the linear or branched alkyl groups, the cycloalkyl groups, the aryl groups, and the aralkyl group may each include a group selected from the group consisting of heteroatoms such as an oxygen atom and atomic groups having a heteroatom such as a carbonyl group.

In the repeating unit having the acid-decomposable group that will be described later, R₃₈ may be bonded to another substituent included in the main chain of the repeating unit to form a ring. The group formed by bonding R₃₈ and another substituent included in the main chain of the repeating unit is preferably an alkylene group such as a methylene group.

When the resist composition is, for example, a resist composition for EUV exposure, it is also preferable that the monovalent organic groups represented by R₃₆ to R₃₈ and the group formed by bonding R₃₇ and R₃₈ together each further have a fluorine atom or an iodine atom as a substituent.

Formula (Y3) is preferably a group represented by the following formula (Y3-1).

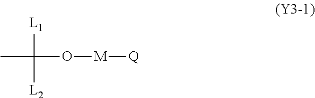

L₁ and L₂ each independently represent a hydrogen atom, a linear or branched alkyl group, a cycloalkyl group, an aryl group, or a group formed by combining any of them (for example, a group formed by combining a linear or branched alkyl group and an aryl group).

M represents a single bond or a divalent linking group.

Q represents a linear or branched alkyl group optionally including a heteroatom, a cycloalkyl group optionally including a heteroatom, an aryl group optionally including a heteroatom, an amino group, an ammonium group, a mercapto group, a cyano group, an aldehyde group, or a group formed by combining any of them (for example, a group formed by combining a linear or branched alkyl group and a cycloalkyl group).

In the linear or branched alkyl group and the cycloalkyl group, one methylene group, for example, may be replaced with a group selected from the group consisting of heteroatoms such as an oxygen atom and atomic groups having a heteroatom such as a carbonyl group.

It is preferable that one of L₁ or L₂ is a hydrogen atom and that the other is a linear or branched alkyl group, a cycloalkyl group, an aryl group, or a group formed by combining an alkylene group and an aryl group.

At least two selected from the group consisting of Q, M, and L₁ may be bonded together to form a ring (preferably a 5-membered or 6-membered ring).

From the viewpoint of obtaining a finer pattern, L₂ is preferably a secondary or tertiary alkyl group and more preferably a tertiary alkyl group. Examples of the secondary alkyl group include an isopropyl group, a cyclohexyl group, and a norbornyl group, and examples of the tertiary alkyl group include a tert-butyl group and an adamantane group. In these modes, since the Tg (glass transition temperature) and activation energy of the resin (A) including the repeating unit having the acid-decomposable group that will be described later are high, high film hardness is obtained, and the occurrence of pattern bridging can be reduced.

When the resist composition is, for example, a resist composition for EUV exposure, it is also preferable that the linear or branched alkyl groups, cycloalkyl groups, and aryl groups represented by L₁ and L₂ and groups formed by combining any of these groups each further have a fluorine atom or an iodine atom as a substituent. It is also preferable that, in the linear or branched alkyl groups, the cycloalkyl groups, the aryl groups, and the aralkyl groups, one methylene group may be replaced with a group selected from the group consisting of heteroatoms such as an oxygen atom and atomic groups having a heteroatom such as a carbonyl group.

When the resist composition is, for example, a resist composition for EUV exposure, it is also preferable that, in the linear or branched alkyl group optionally having a heteroatom, the cycloalkyl group optionally having a heteroatom, the aryl group optionally having a heteroatom, the amino group, the ammonium group, the mercapto group, the cyano group, and the aldehyde group that are each represented by Q and groups formed by combining any of these groups, the heteroatom is selected from the group consisting of a fluorine atom, an iodine atom, and an oxygen atom.

In formula (Y4), Ar represents an aromatic ring group. Rn represents a linear or branched alkyl group, a cycloalkyl group, or an aryl group. Rn and Ar may be bonded together to form a non-aromatic ring. Ar is more preferably an aryl group.

When the resist composition is, for example, a resist composition for EUV exposure, it is also preferable that the aromatic ring group represented by Ar and the linear or branched alkyl, cycloalkyl, or aryl group represented by Rn each have a fluorine atom or an iodine atom as a substituent.

When, in the dissociable group protecting the polar group, a non-aromatic ring is bonded directly to the polar group (or its residue), it is also preferable that a ring member atom of the non-aromatic ring that is adjacent to the ring member atom directly bonded to the polar group (or its residue) does not have a halogen atom such as a fluorine atom as a substituent because the acid decomposability is further improved.

The dissociable group dissociable under the action of acid may also be a 2-cyclopentenyl group having a substituent (such as an alkyl group) such as a 3-methyl-2-cyclopentenyl group or a cyclohexyl group having a substituent (such as an alkyl group) such as a 1,1,4,4-tetramethylcyclohexyl group.

### (Repeating Unit Containing Acid-Decomposable Group)

Next, the acid-decomposable group-containing repeating unit that can be included in the resin (A) will be described.

In addition to the repeating unit having the above-described acid-decomposable group, the acid-decomposable group-containing repeating unit is also preferably a repeating unit represented by the following formula (A).

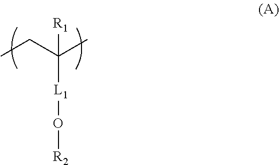

L₁ represents a divalent linking group optionally having a fluorine atom or an iodine atom. R₁ represents a hydrogen atom, a fluorine atom, an iodine atom, an alkyl group optionally having a fluorine atom or an iodine atom, or an aryl group optionally having a fluorine atom or an iodine atom. R₂ represents a dissociable group that is dissociable under the action of acid and optionally has a fluorine atom or an iodine atom. Preferably, at least one of L₁, R₁, or R₂ has a fluorine atom or an iodine atom.

L₁ represents a divalent linking group optionally having a fluorine atom or an iodine atom. Examples of the divalent linking group optionally having a fluorine atom or an iodine atom include —CO—, —O—, —S—, —SO—, —SO₂—, hydrocarbon groups optionally having a fluorine atom or an iodine atom (such as linear or branched alkylene groups, cycloalkylene groups, alkenylene groups, and arylene groups), and linking groups formed by linking a plurality of groups selected from the above groups. In particular, L₁ is preferably —CO—, an arylene group, or -arylene group-fluorine or iodine atom-containing linear or branched alkylene group- and more preferably —CO— or -arylene group-fluorine or iodine atom-containing linear or branched alkylene group-.

The arylene group is preferably a phenylene group.

No particular limitation is imposed on the number of carbon atoms in the linear or branched alkylene group. The number of carbon atoms is preferably 1 to 10 and more preferably 1 to 3.

No particular limitation is imposed on the total number of fluorine and iodine atoms contained in the fluorine or iodine atom-containing linear or branched alkylene group. The total number of fluorine and iodine atoms is preferably 2 or more, more preferably 2 to 10, and still more preferably 3 to 6.

R₁ represents a hydrogen atom, a fluorine atom, an iodine atom, a linear or branched alkyl group optionally having a fluorine atom or an iodine atom, or an aryl group optionally having a fluorine atom or an iodine atom.

No particular limitation is imposed on the number of carbon atoms in the linear or branched alkyl group. The number of carbon atoms is preferably 1 to 10 and more preferably 1 to 3.

No particular limitation is imposed on the total number of fluorine and iodine atoms contained in the fluorine or iodine atom-containing linear or branched alkyl group. The total number of fluorine and iodine atoms is preferably 1 or more, more preferably 1 to 5, and still more preferably 1 to 3.

The fluorine or iodine atom-containing linear or branched alkyl group may include a heteroatom such as an oxygen atom other than the halogen atom.

R₂ represents a dissociable group that is dissociable under the action of acid and optionally has a fluorine atom or an iodine atom. Examples of the dissociable group optionally having a fluorine atom or an iodine atom include the dissociable groups represented by formula (Y1) to (Y4) above and the dissociable groups represented by formula (Y1) to (Y4) and having a fluorine atom or an iodine atom, and preferred modes of the dissociable group are also the same as those of these groups.

It is also preferable that the acid-decomposable group-containing repeating unit is a repeating unit represented by formula (AI).

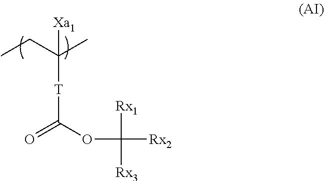

In formula (AI),

Xa₁ represents a hydrogen atom or an alkyl group optionally having a substituent.

T represents a single bond or a divalent linking group.

Rx₁ to Rx₃ each independently represent a linear or branched alkyl group, a cycloalkyl group, an alkenyl group, or an aryl group. Two selected from the group consisting of Rx₁ to Rx₃ may be bonded together to form a ring.

When all of Rx₁ to Rx₃ are each a linear or branched alkyl group, it is preferable that at least two selected from the group consisting of Rx₁ to Rx₃ are each a methyl group.

In particular, Rx₁ to Rx₃ are each preferably a linear or branched alkyl group and more preferably a linear alkyl group.

Examples of the alkyl group optionally having a substituent and represented by Xa₁ include a methyl group and a group represented by —CH₂—R₁₁. R₁₁ represents a halogen atom (such as a fluorine atom), a hydroxy group, or a monovalent organic group, and examples thereof include alkyl groups having 5 or less carbon atoms and optionally substituted with a halogen atom, acyl groups having 5 or less carbon atoms and optionally substituted with a halogen atom, and alkoxy groups having 5 or less carbon atoms and optionally substituted with a halogen atom. R₁₁ is preferably an alkyl group having 3 or less carbon atoms and more preferably a methyl group. Xa₁ is preferably a hydrogen atom, a methyl group, a trifluoromethyl group, or a hydroxymethyl group.

Examples of the divalent linking group represented by T include alkylene groups, aromatic ring groups, a —COO-Rt- group, and an —O-Rt- group. In these formulas, Rt represents a linear or branched alkylene group or a cycloalkylene group.

T is preferably a single bond or a —COO-Rt- group. When T represents a —COO-Rt- group, Rt is preferably an alkylene group having 1 to 5 carbon atoms and more preferably —CH₂—, —(CH₂)₂—, or —(CH₂)₃—.

The linear or branched alkyl groups represented by Rx₁ to Rx₃ are each preferably a linear alkyl group.

The number of carbon atoms in each of the linear or branched alkyl groups represented by Rx₁ to Rx₃ is preferably 1 to 10, more preferably 1 to 5, and still more preferably 1 to 3.

Specific examples of the linear or branched alkyl groups represented by Rx₁ to Rx₃ include a methyl group, an ethyl group, a n-propyl group, an isopropyl group, a n-butyl group, an isobutyl group, and a t-butyl group.

The cycloalkyl groups represented by Rx₁ to Rx₃ may each be either monocyclic or polycyclic.

The number of carbon atoms in each of the cycloalkyl groups represented by Rx₁ to Rx₃ is preferably 6 to 15 and more preferably 6 to 10.

Specific examples of the cycloalkyl groups represented by Rx₁ to Rx₃ include: monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

The alkenyl groups represented by Rx₁ to Rx₃ are each preferably a vinyl group.

The aryl groups represented by Rx₁ to Rx₃ are each preferably an aryl group having 6 to 10 carbon atoms, and examples thereof include a phenyl group, a naphthyl group, and an anthryl group.

Two selected from the group consisting of Rx₁ to Rx₃ may be bonded together to form a ring.

This ring may be either monocyclic or polycyclic.

The ring is preferably a cycloalkyl group and more preferably a 5- to 6-membered monocyclic cycloalkyl group.

Specific examples of the ring include monocyclic cycloalkyl groups such as a cyclopentyl group and a cyclohexyl group; and polycyclic cycloalkyl groups such as a norbornyl group, a tetracyclodecanyl group, a tetracyclododecanyl group, and an adamantyl group.

In the cycloalkyl group formed by bonding two selected from the group consisting of Rx₁ to Rx₃, for example, one methylene group included in the ring may be replaced with a heteroatom such as an oxygen atom, a group having a heteroatom such as a carbonyl group, or a vinylidene group. In each cycloalkyl group, at least one ethylene group included in the cycloalkane ring may be replaced with a vinylene group.

In the repeating unit represented by formula (AI), it is preferable that, for example, Rx₁ is a methyl group or an ethyl group and that Rx₂ and Rx₃ are bonded together to form the cycloalkyl group described above.

When any of the above-described groups has a substituent, examples of the substituent include alkyl groups (having 1 to 4 carbon atoms), halogen atoms, a hydroxy group, alkoxy groups (having 1 to 4 carbon atoms), a carboxy group, and alkoxycarbonyl groups (having 2 to 6 carbon atoms).

The repeating unit represented by formula (AI) is preferably an acid-decomposable tertiary alkyl (meth)acrylate-based repeating unit (a repeating unit in which Xa₁ represents a hydrogen atom or a methyl group and T represents a single bond).

Specific examples of the acid-decomposable group-containing repeating unit are shown below, but the present invention is not limited thereto. In the formulas below, Xa₁ represents H, CH₃, CF₃, or CH₂OH, and Rxa and Rxb each represent a linear or branched alkyl group having 1 to 5 carbon atoms.

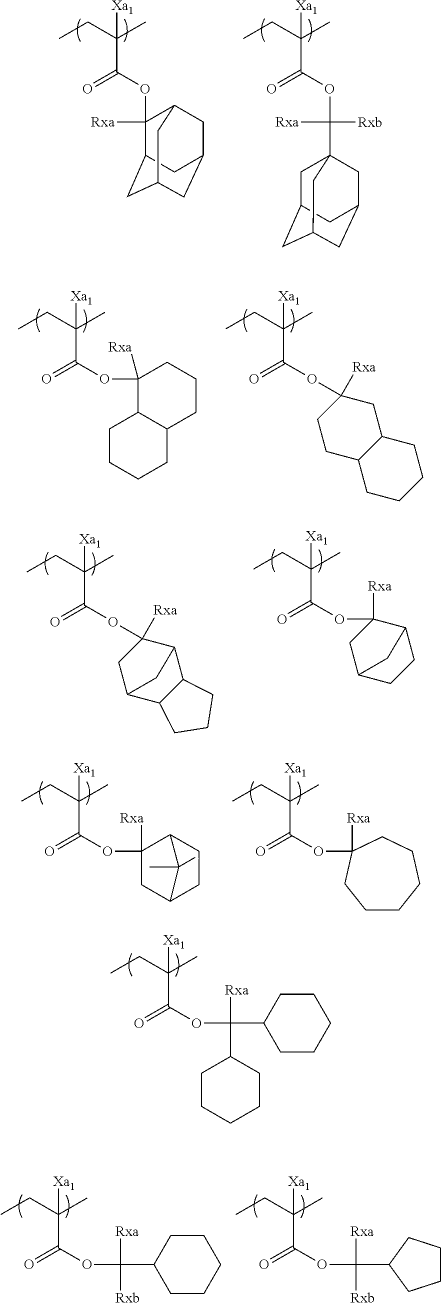

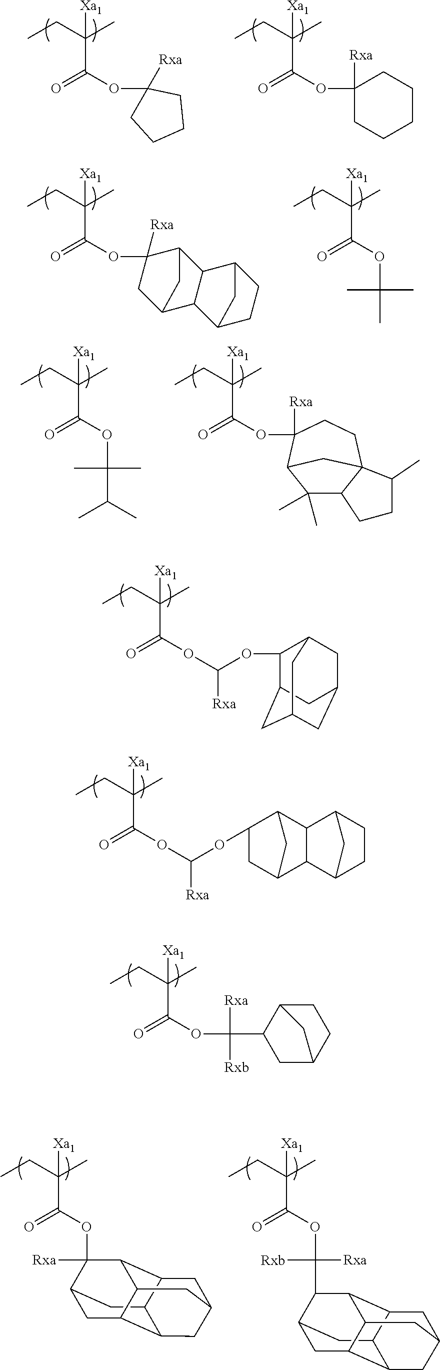

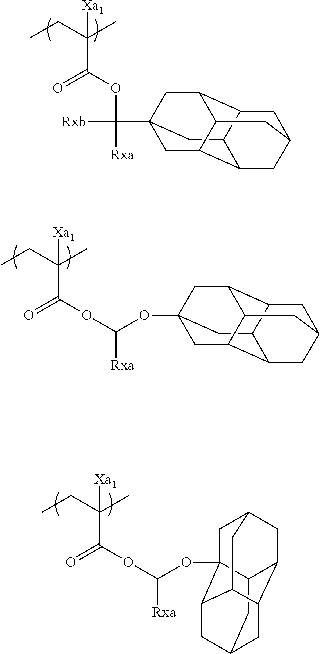

### (Repeating Unit Having Acid-Decomposable Group Including Unsaturated Bond)

It is also preferable that the resin (A) has, as the acid-decomposable group-containing repeating unit, a repeating unit having an acid-decomposable group including an unsaturated bond.

The repeating unit having an acid-decomposable group including an unsaturated bond is preferably a repeating unit represented by formula (B).

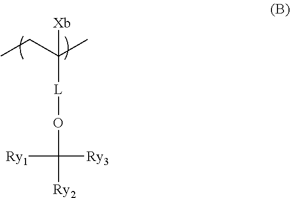

In formula (B),

Xb represents a hydrogen atom, a halogen atom, or an alkyl group optionally having a substituent.

L represents a single bond or a divalent linking group optionally having a substituent.

Ry₁ to Ry₃ each independently represent a hydrogen atom, a linear or branched alkyl group, a monocyclic or polycyclic cycloalkyl group, an alkenyl group, an alkynyl group, or a monocyclic or polycyclic aryl group. Two selected from the group consisting of Ry₁ to Ry₃ may be bonded together to form a monocyclic or polycyclic ring (such as a monocyclic or polycyclic cycloalkyl or cycloalkenyl group).

However, at least one of Ry₁, Ry₂, or Ry₃ represents an alkenyl group, an alkynyl group, a monocyclic or polycyclic cycloalkenyl group, or a monocyclic or polycyclic aryl group, or two selected from the group consisting of Ry₁ to Ry₃ are bonded together to form a monocyclic or polycyclic alicyclic ring (such as a monocyclic or polycyclic cycloalkyl or cycloalkenyl group). Two or more selected from the group consisting of Ry₁ to Ry₃ are not simultaneously hydrogen atoms. When one of Ry₁, Ry₂, or Ry₃ represents a hydrogen atom, the other two of Ry₁ to Ry₃ are bonded together to form a ring having at least one vinylene group in its ring structure, and at least one of the at least one vinylene group is adjacent to the carbon atom to which the hydrogen atom represented by the one of Ry₁, Ry₂, or Ry₃ is bonded.

The alkyl groups represented by Ry₁ to Ry₃ are each preferably an alkyl group having 1 to 4 carbon atoms such as a methyl group, an ethyl group, a n-propyl group, an isopropyl group, a n-butyl group, an isobutyl group, or a t-butyl group.

The cycloalkyl groups represented by Ry₁ to Ry₃ are each preferably a monocyclic cycloalkyl group such as a cyclopentyl group or a cyclohexyl group or a polycyclic cycloalkyl group such as a norbornyl group, a tetracyclodecanyl group, a tetracyclododecanyl group, or an adamantyl group.

The aryl groups represented by Ry₁ to Ry₃ are each preferably an aryl group having 6 to 15 carbon atoms and more preferably an aryl group having 6 to 10 carbon atoms, and examples thereof include a phenyl group, a naphthyl group, and an anthryl group.

The alkenyl groups represented by Ry₁ to Ry₃ are each preferably a vinyl group.

The alkynyl groups represented by Ry₁ to Ry₃ are each preferably an ethynyl group.

The cycloalkenyl groups represented by Ry₁ to Ry₃ are each preferably a structure including a monocyclic cycloalkyl group such as a cyclopentyl group or a cyclohexyl group with a double bond present in part of the monocyclic cycloalkyl group.

The cycloalkyl group formed by bonding two selected from the group consisting of Ry₁ to Ry₃ is preferably a monocyclic cycloalkyl group such as a cyclopentyl group or a cyclohexyl group and is also preferably a polycyclic cycloalkyl group such as a norbornyl group, a tetracyclodecanyl group, a tetracyclododecanyl group, or an adamantyl group. In particular, the cycloalkyl group is preferably a monocyclic cycloalkyl group having 5 to 6 carbon atoms.

In the cycloalkyl or cycloalkenyl group formed by bonding two selected from the group consisting of Ry₁ to Ry₃, for example, one methylene group included in the ring may be replaced with a heteroatom such as an oxygen atom, a group including a heteroatom such as a carbonyl group, an —SO₂— group, or an —SO₃— group, a vinylidene group, or a combination thereof. In the cycloalkyl or cycloalkenyl group, at least one ethylene group included in the cycloalkane or cycloalkenyl ring may be replaced with a vinylene group.

In one preferred mode of the combination of Ry₁ to Ry₃, for example, Ry₁ is a methyl group, an ethyl group, a vinyl group, an allyl group, or an aryl group, and Ry₂ and Ry₃ are bonded together to form the cycloalkyl or cycloalkenyl group described above. In another preferred mode, Ry₁ is a hydrogen atom, and Ry₂ and Ry₃ are bonded together to form a ring having at least one vinylene group in its ring structure. At least one of the at least one vinylene group is adjacent to the carbon atom to which the hydrogen atom represented by Ry₁ is bonded.

When Ry₁ to Ry₃ each further have a substituent, example of the substituent include alkyl groups (having 1 to 4 carbon atoms), halogen atoms, a hydroxy group, alkoxy groups (having 1 to 4 carbon atoms), a carboxy group, and alkoxycarbonyl groups (having 2 to 6 carbon atoms).

Examples of the alkyl group represented by Xb and optionally having a substituent include a methyl group and a group represented by —CH₂—R₁₁. R₁₁ represents a halogen atom (such as a fluorine atom), a hydroxy group, or a monovalent organic group, and examples thereof include alkyl groups having 5 or less carbon atoms and optionally substituted with a halogen atom, acyl groups having 5 or less carbon atoms and optionally substituted with a halogen atom, and alkoxy groups having 5 or less carbon atoms and optionally substituted with a halogen atom. R₁₁ is preferably an alkyl group having 3 or less carbon atoms and more preferably a methyl group. Xb is preferably a hydrogen atom, a fluorine atom, a methyl group, a trifluoromethyl group, or a hydroxymethyl group.

Examples of the divalent linking group represented by L include an -Rt- group, a —CO— group, a —COO-Rt- group, a —COO-Rt-CO— group, an -Rt-CO— group, and an —O-Rt- group. The divalent linking group is preferably an -Rt- group, a —CO— group, a —COO-Rt-CO— group, or an -Rt-CO— group. Rt represents a linear or branched alkylene group, a cycloalkylene group, or an aromatic ring group and is preferably an aromatic ring group. For example, the aromatic ring group may have a substituent such as a halogen atom, a hydroxy group, or an alkoxy group.

When any of the groups in formula (B) has a substituent, examples of the substituent include alkyl groups (having 1 to 4 carbon atoms), halogen atoms, a hydroxy group, alkoxy groups (having 1 to 4 carbon atoms), a carboxy group, and alkoxycarbonyl groups (having 2 to 6 carbon atoms).

The repeating unit represented by formula (B) is preferably an acid-decomposable (meth)acrylic acid tertiary ester-based repeating unit (a repeating unit in which Xb represents a hydrogen atom or a methyl group and L represents a —CO— group), an acid-decomposable hydroxystyrene tertiary alkyl ether-based repeating unit (a repeating unit in which Xb represents a hydrogen atom or a methyl group and L represents a phenyl group), or an acid-decomposable styrenecarboxylic acid tertiary ester-based repeating unit (a repeating unit in which Xb represents a hydrogen atom or a methyl group and L represents an -Rt-CO— group (Rt is an aromatic group)).

Specific examples of the repeating unit having an acid-decomposable group including an unsaturated bond include repeating units described in paragraphs [0067] to [0071] of WO2022/024928A.

In the resin (A), the content of the acid-decomposable group-containing repeating unit with respect to the total amount of the repeating units in the resin (A) is preferably 15% by mole or more, more preferably 20% by mole or more, and still more preferably 30% by mole or more. The upper limit of the content is preferably 90% by mole or less, more preferably 80% by mole or less, particularly preferably 70% by mole or less, and most preferably 60% by mole or less.

The resin (A) may include an additional repeating unit other than the repeating units described above.

The additional repeating unit is, for example, at least one repeating unit selected from the following group A.

Group A: The group consisting of the following repeating units (20) to (26).

(20) A repeating unit, described later, having an acid group.

(21) A repeating unit, described later, having no acid-decomposable group and no acid group but having a fluorine atom or an iodine atom.

(22) A repeating unit, described later, having a lactone group, a sultone group, or a carbonate group.

(23) A repeating unit, described later, having a photoacid generating group.

(24) A repeating unit, described later, represented by formula (V-1) or formula (V-2) below.

(25) A repeating unit for reducing the mobility of the main chain.

Repeating units represented by formulas (A) to (E) described later each correspond to (25) the repeating unit for reducing the mobility of the main chain.

(26) A repeating unit, described later, having an alicyclic hydrocarbon structure and exhibiting no acid decomposability.

The resin (A) has preferably an acid group and includes preferably a repeating unit having an acid group as described later. The definition of the acid group will be described later along with preferred modes of the repeating unit having an acid group.

When the resist composition is used as a resist composition for EUV exposure, it is preferable that the resin (A) has at least one repeating unit selected from the group A.

When the resist composition is used as a resist composition for EUV exposure, it is preferable that the resin (A) contains at least one of a fluorine atom or an iodine atom. When the resin (A) contains both a fluorine atom and an iodine atom, the resin (A) may include one type of repeating unit containing both a fluorine atom and an iodine atom or may contain two types of repeating units, i.e., a repeating unit having a fluorine atom and a repeating unit having an iodine atom.

When the resist composition is used as a resist composition for EUV exposure, it is also preferable that the resin (A) has a repeating unit having an aromatic group.

### <Repeating Unit Having Acid Group>

Preferably, the resin (A) has a repeating unit having an acid group.

The acid group is preferably an acid group having a pKa of 13 or less. The acid dissociation constant of the acid group is preferably 13 or less as described above, more preferably 3 to 13, and still more preferably 5 to 10.

When the resin (A) has the acid group with a pKa of 13 or less, no particular limitation is imposed on the content of the acid group in the resin (A), but the content is often 0.2 to 6.0 mmol/g. In particular, the content is preferably 0.8 to 6.0 mmol/g, more preferably 1.2 to 5.0 mmol/g, and still more preferably 1.6 to 4.0 mmol/g. When the content of the acid group is within the above range, development proceeds smoothly, and a pattern to be formed has a good shape profile, so that high resolution is achieved.

The acid group is preferably, for example, a carboxy group, a hydroxy group, a phenolic hydroxy group, a fluorinated alcohol group (preferably a hexafluoroisopropanol group), a sulfonic group, a sulfonamido group, or an isopropanol group and is more preferably a phenolic hydroxy group.

The phenolic hydroxy group means a hydroxy group bonded as a substituent to a ring member atom of an aromatic ring.

In the hexafluoroisopropanol group, one or more (preferably one to two) fluorine atoms may each be replaced with a group other than a fluorine atom (such as an alkoxycarbonyl group). The acid group is also preferably —C(CF₃)(OH)—CF₂— formed as described above. At least one fluorine atom may be replaced with a group other than a fluorine atom to form a ring including —C(CF₃)(OH)—CF₂—.

Preferably, the repeating unit having the acid group is a repeating unit different from the above-described repeating unit having the structure in which a polar group is protected by a dissociable group that is dissociable under the action of acid and from a repeating unit having a lactone group, a sultone group, or a carbonate group that is described later.

The repeating unit having the acid group may have a fluorine atom or an iodine atom.

The repeating unit having the acid group is preferably a repeating unit having a phenolic hydroxy group because the effects of the invention are further enhanced.

Examples of the repeating unit having a phenolic hydroxy group include a repeating unit represented by the following formula (1).

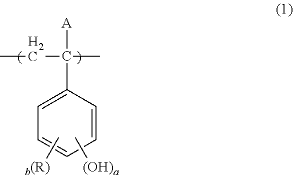

In formula (1),

A represents a hydrogen atom, an alkyl group, a cycloalkyl group, a halogen atom, or a cyano group.

R represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group. When a plurality of R's are present, they may be the same or different. When a plurality of R's are present, they may together form a ring. R is preferably a hydrogen atom.

a represents an integer of 1 to 3.

b represents an integer of 0 to (5−a).

Specific examples of the repeating unit having a phenolic hydroxy group include the following repeating units. In the following formulas, a represents 1 or 2.

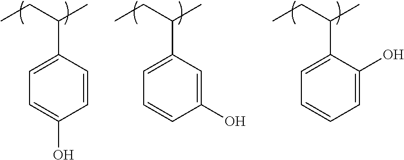

Other specific examples of the repeating unit having the acid group include repeating units described in paragraphs [0088] to [0089] and [0103] to [0110] of WO2022/024928A.

The content of the repeating unit having the acid group with respect to the total amount of the repeating units in the resin (A) is preferably 10% by mole or more and more preferably 15% by mole or more. The upper limit of the content with respect to the total amount of the repeating units in the resin (A) is preferably 70% by mole or less, more preferably 65% by mole or less, and still more preferably 60% by mole or less.

### <Repeating Unit Having No Acid-Decomposable Group and No Acid Group but Having Fluorine Atom or Iodine Atom>

The resin (A) may have, in addition to the above-described <repeating unit having the acid-decomposable group> and the above-described <repeating unit having the acid group>, a repeating unit having a fluorine atom or an iodine atom (this repeating unit is hereinafter referred to also as a unit X). Preferably, the <repeating unit having a fluorine atom or an iodine atom> differs from other types of repeating units belonging to the group A such as the <repeating unit having a lactone group, a sultone group, or a carbonate group> described later and the <repeating unit having a photoacid generating group> described later.

The unit X is preferably a repeating unit represented by formula (C).

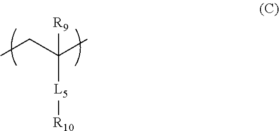

L₅ represents a single bond or an ester group.

R₉ represents a hydrogen atom or an alkyl group optionally having a fluorine atom or an iodine atom.

R₁₀ represents a hydrogen atom, an alkyl group optionally having a fluorine atom or an iodine atom, a cycloalkyl group optionally having a fluorine atom or an iodine atom, an aryl group optionally having a fluorine atom or an iodine atom, or a combination thereof.

Specific examples of the unit X are shown below.

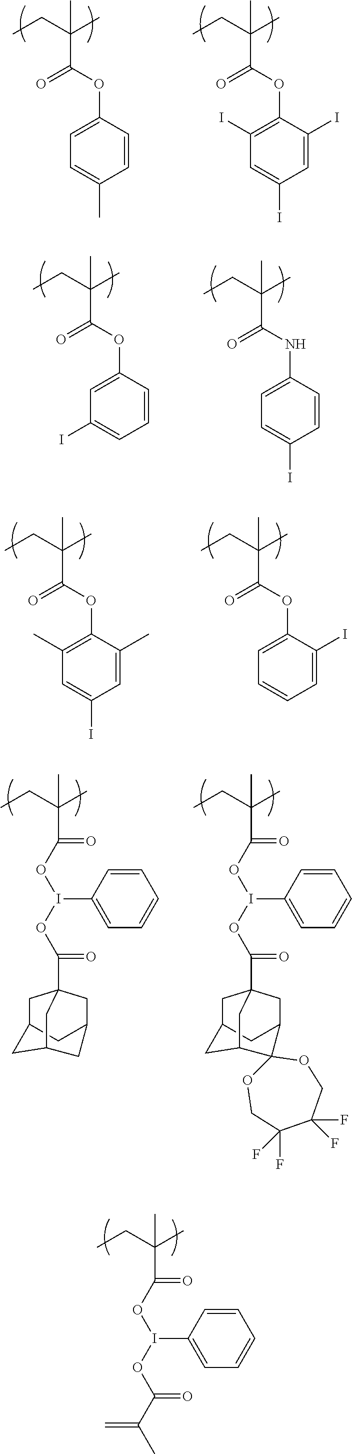

The content of the unit X with respect to the total amount of the repeating units in the resin (A) is preferably 0% by mole or more, more preferably 5% by mole or more, and still more preferably 10% by mole or more. The upper limit of the content of the unit X is preferably 50% by mole or less, more preferably 45% by mole or less, and still more preferably 40% by mole or less.

Among the repeating units in the resin (A), the total amount of repeating units including at least one of a fluorine atom or an iodine atom with respect to the total amount of the repeating units in the resin (A) is preferably 10% by mole or more, more preferably 20% by mole or more, still more preferably 30% by mole or more, and particularly preferably 40% by mole or more. No particular limitation is imposed on the upper limit of the total amount, but the amount is, for example, 100% by mole or less.

Examples of the repeating units including at least one of a fluorine atom or an iodine atom include a repeating unit having a fluorine atom or an iodine atom and having the acid-decomposable group, a repeating unit having a fluorine atom or an iodine atom and having the acid group, and a repeating unit having a fluorine atom or an iodine atom.

### <Repeating Unit Having Lactone Group, Sultone Group, or Carbonate Group>

The resin (A) may have a repeating unit having at least one selected from the group consisting of lactone groups, sultone groups, and carbonate groups (this repeating unit is hereafter referred to also as a “unit Y”).

It is also preferable that the unit Y does not have a hydroxy group and an acid group such as a hexafluoroisopropanol group.

The lactone or sultone group may be any lactone or sultone group so long as it has a lactone or sultone structure. The lactone or sultone structure is preferably a 5- to 7-membered lactone or sultone structure. In particular, a 5- to 7-membered lactone structure with another ring structure fused thereto to form a bicyclo or spiro structure or a 5- to 7-membered sultone structure with another ring structure fused thereto to form a bicyclo or spiro structure is more preferred.

Preferably, the resin (A) has a repeating unit having a lactone or sultone group formed by removing at least one hydrogen atom from a ring member atom of a lactone structure represented by any of the following formulas (LC1-1) to (LC1-21) or a sultone structure represented by any of the following formulas (SL1-1) to (SL1-3).

The lactone or sultone group may be bonded directly to the main chain. For example, a ring member atom of the lactone or sultone group may be included in the main chain of the resin (A).

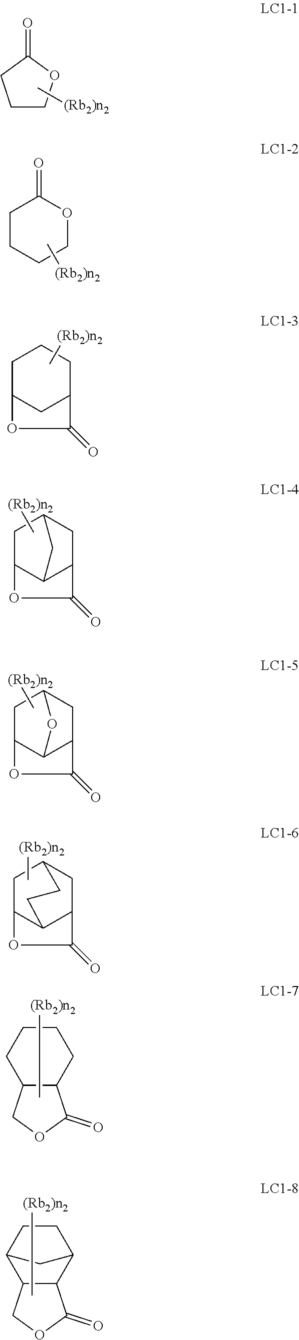

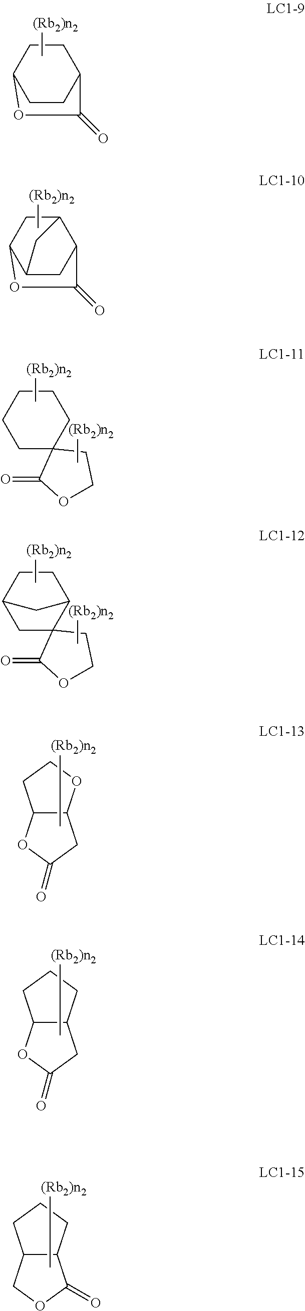

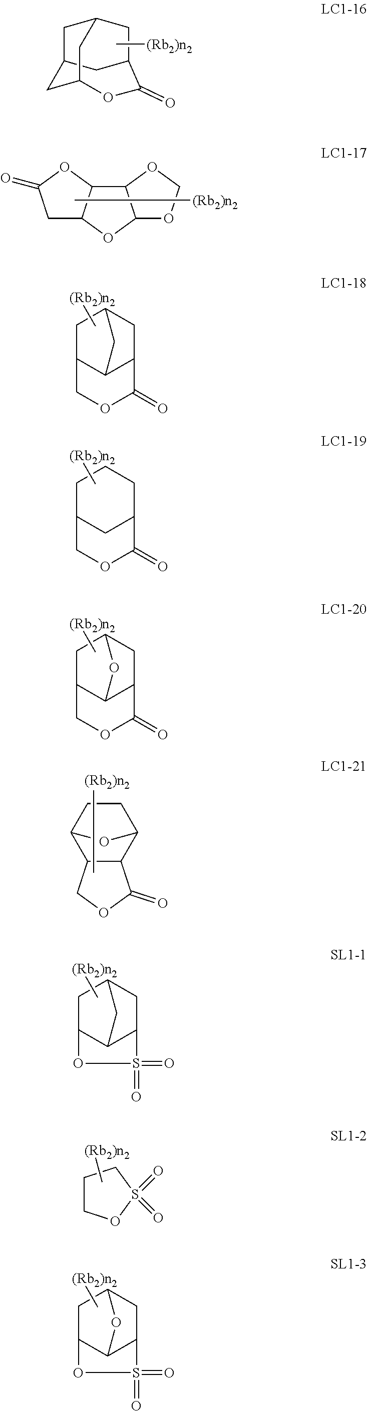

Each of the lactone and sultone structure moieties may have a substituent (Rb₂). Preferred examples of the substituent (Rb₂) include alkyl groups having 1 to 8 carbon atoms, cycloalkyl groups having 4 to 7 carbon atoms, alkoxy groups having 1 to 8 carbon atoms, alkoxycarbonyl groups having 1 to 8 carbon atoms, a carboxy group, halogen atoms, a cyano group, and acid-decomposable groups. n₂ represents an integer of 0 to 4. A plurality of Rb₂'s present when n₂ is 2 or more may be different from each other, and the plurality of Rb₂'s present may be bonded together to form a ring.

Examples of the repeating unit having a group having the lactone structure represented by any of formulas (LC1-1) to (LC1-21) or the sultone structure represented by any of formulas (SL1-1) to (SL1-3) include a repeating unit represented by the following formula (AI).

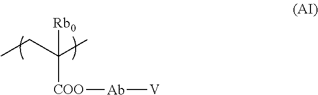

In formula (AI), Rb₀ represents a hydrogen atom, a halogen atom, or an alkyl group having 1 to 4 carbon atoms.

The alkyl group represented by Rb₀ may have a substituent, and preferred examples of the substituent include a hydroxy group and halogen atoms.

Examples of the halogen atom represented by Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxy group, or a divalent group formed by combining any of the above groups. In particular, Ab is preferably a single bond or a linking group represented by -Ab₁-CO₂—. Ab₁ is a linear or branched alkylene group or a monocyclic or polycyclic cycloalkylene group and is preferably a methylene group, an ethylene group, a cyclohexylene group, an adamantylene group, or a norbornylene group.

V represents a group formed by removing one hydrogen atom from a ring member atom in the lactone structure represented by any of formulas (LC1-1) to (LC1-21) or a group formed by removing one hydrogen atom from a ring member atom in the sultone structure represented by any of formulas (SL1-1) to (SL1-3).

When the repeating unit having the lactone or sultone group has optical isomers, any of the optical isomers may be used. One optical isomer may be used alone, or a mixture of a plurality of optical isomers may be used. When one optical isomer is mainly used, the optical purity (ee) thereof is preferably 90 or more and more preferably 95 or more.

The carbonate group is preferably a cyclic carbonate group.

Examples of the repeating unit having a cyclic carbonate group include repeating units described in paragraphs [0127] to [0133] of WO2022/024928A.

The content of the unit Y with respect to the total amount of the repeating units in the resin (A) is preferably 1% by mole or more, more preferably 5% by mole or more, and still more preferably 10% by mole or more. The upper limit of the content of the unit Y with respect to the total amount of the repeating units in the resin (A) is preferably 85% by mole or less, more preferably 80% by mole or less, still more preferably 70% by mole or less, and particularly preferably 60% by mole or less.

### <Repeating Unit Having Photoacid Generating Group>

The resin (A) may have a repeating unit that is different from those described above and has a group that generates an acid when irradiated with actinic rays or radiation (this group is hereinafter referred to also as a “photoacid generating group”).

Examples of this repeating unit include a repeating unit represented by the following formula (4).

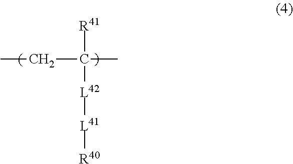

R⁴¹ represents a hydrogen atom or a methyl group. L⁴¹ represent a single bond or a divalent linking group. L⁴² represents a divalent linking group. R⁴⁰ represents a structural moiety that is decomposed when irradiated with actinic rays or radiation and thereby generates an acid on a side chain.

Examples of the repeating unit having the photoacid generating group are shown below.

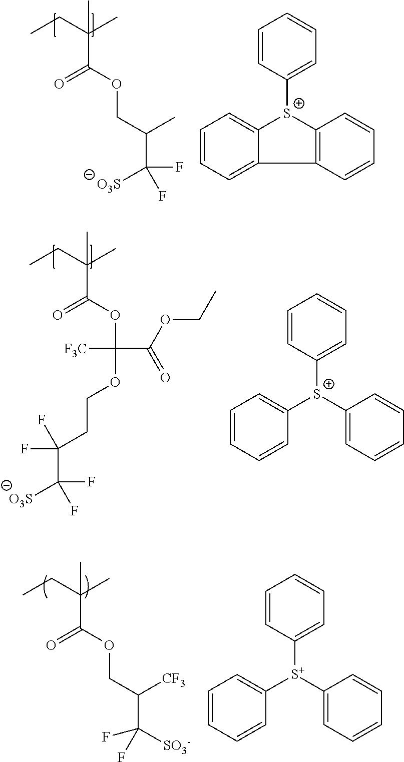

Other examples of the repeating unit represented by formula (4) include repeating units described in paragraphs [0094] to [0105] of JP2014-041327A and repeating units described in paragraph [0094] of WO2018/193954A.

The content of the repeating unit having the photoacid generating group with respect to the total amount of the repeating units in the resin (A) is preferably 1% by mole or more and more preferably 5% by mole or more. The upper limit of the content is preferably 40% by mole or less, more preferably 35% by mole or less, and still more preferably 30% by mole or less.

### <Repeating Unit Represented by Formula (V-1) or Formula (V-2)>

The resin (A) may have a repeating unit represented by formula (V-1) or (V-2) below.

Preferably, the repeating unit represented by the following formula (V-1) or (V-2) differs from the repeating units described above.

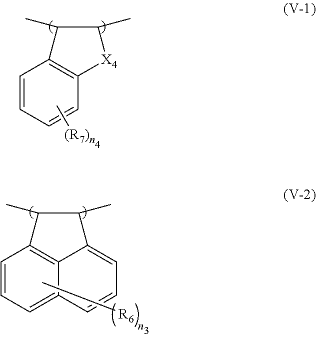

In these formulas,

R₆ and R₇ each independently represent a hydrogen atom, a hydroxy group, an alkyl group, an alkoxy group, an acyloxy group, a cyano group, a nitro group, an amino group, a halogen atom, an ester group (—OCOR or —COOR: R represents an alkyl group having 1 to 6 carbon atoms or a fluorinated alkyl group having 1 to 6 carbon atoms), or a carboxy group. The alkyl group is preferably a linear, branched, or cyclic alkyl group having 1 to 10 carbon atoms.

n₃ represents an integer of 0 to 6.

n₄ represents an integer of 0 to 4.

X₄ is a methylene group, an oxygen atom, or a sulfur atom.

Examples of the repeating unit represented by formula (V-1) or (V-2) are shown below.

Examples of the repeating unit represented by formula (V-1) or (V-2) include repeating units described in paragraph [0100] of WO2018/193954A.

### <Repeating Unit for Reducing Mobility of Main Chain>

The higher the glass transition temperature (Tg) of the resin (A), the better because excessive diffusion of the acid generated or pattern collapse during development can be prevented. The Tg is preferably higher than 90° C., more preferably higher than 100° C., still more preferably higher than 110° C., and particularly preferably higher than 125° C. The Tg is preferably 400° C. or lower and more preferably 350° C. or lower because the rate of dissolution in a developer is high.

In the present specification, the glass transition temperature (Tg) of a polymer such as the resin (A) (hereinafter referred to also as the “Tg of a repeating unit”) is computed by the following method. First, the Tg of each of the homopolymers formed from the respective repeating units included in the polymer is computed by the Bicerano method. Next, the mass ratios (%) of the repeating units with respect to the total mass of the repeating units in the polymer are computed. Next, the Tg of each repeating unit at the corresponding mass ratio is computed using the Fox formula (described, for example, in Materials Letters 62 (2008) 3152), and the computed Tg's are summed to obtain the Tg (° C.) of the polymer.

The Bicerano method is described in Prediction of polymer properties, Marcel Dekker Inc, New York (1993). The computation of Tg by the Bicerano method can be performed using software for estimating physical properties of a polymer, MDL Polymer (MDL Information Systems, Inc.).

To increase the Tg of the resin (A) (to increase the Tg to preferably higher than 90° C.), it is preferable to reduce the mobility of the main chain of the resin (A). Examples of a method for reducing the mobility of the main chain of the resin (A) include methods (a) to (e) described below.
(a) Introduction of a bulky substituent into the main chain.
(b) Introduction of a plurality of substituents into the main chain.
(c) Introduction of substituents that induce the interaction between molecules of the resin (A) into the vicinities of their main chains.
(d) Formation of the main chain having a ring structure.
(e) Linkage of a ring structure to the main chain

Preferably, the resin (A) has a repeating unit whose homopolymer has a Tg of 130° C. or higher.

No particular limitation is imposed on the type of repeating unit whose homopolymer has a Tg of 130° C. or higher, and any repeating unit can be used so long as the Tg of the homopolymer computed by the Bicerano method is 130° C. or higher. With repeating units represented by formulas (A) to (E) described below, homopolymers formed from the repeating units can have a Tg of 130° C. or higher, depending on the types of functional groups in the repeating units.

### (Repeating Unit Represented by Formula (a))

One specific example of means for achieving the method (a) is a method in which the repeating unit represented by formula (A) is introduced into the resin (A).

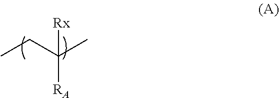

In formula (A), R_{A} represents a group having a polycyclic structure. Rx represents a hydrogen atom, a methyl group, or an ethyl group. The group having a polycyclic structure is a group having a plurality of ring structures, and the plurality of ring structures may or may not be fused.

Specific examples of the repeating unit represented by formula (A) include those described in paragraphs [0107] to [0119] of WO2018/193954A.

### (Repeating Unit Represented by Formula (B))

One specific example of means for achieving the method (b) is a method in which the repeating unit represented by formula (B) is introduced into the resin (A).

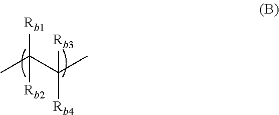

In formula (B), R_{b1} to R_{b4} each independently represent a hydrogen atom or an organic group, and at least two selected from the group consisting of R_{b1} to R_{b4} each represent an organic group.

When at least one of the organic groups is a group whose ring structure is linked directly to the main chain of the repeating unit, no particular limitation is imposed on the types of other organic groups.

When each of the organic groups is not a group whose ring structure is linked directly to the main chain of the repeating unit, at least two of the organic groups are each a substituent in which the number of constituent atoms excluding hydrogen atoms is 3 or more.

Specific examples of the repeating unit represented by formula (B) include those described in paragraphs [0113] to [0115] of WO2018/193954A.

### (Repeating Unit Represented by Formula (C)

One specific example of means for achieving the method (c) is a method in which the repeating unit represented by formula (C) is introduced into the resin (A).

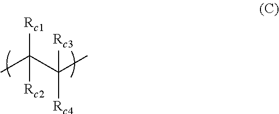

In formula (C), R_{c1} to R_{c4} each independently represent a hydrogen atom or an organic group, and at least one of R_{c1}, R_{c2}, R_{c3}, or R_{c4} is a group having a hydrogen-bonding hydrogen atom at a position within 3 atoms from a carbon atom in the main chain. In particular, it is preferable that the hydrogen-bonding hydrogen atom is present at a position within two atoms (at a position closer to the main chain) in order to induce the interaction between the main chains of molecules of the resin (A).

Specific examples of the repeating unit represented by formula (C) include those described in paragraphs [0119] to [0121] of WO2018/193954A.

### (Repeating Unit Represented by Formula (D))

One specific example of means for achieving the method (d) is a method in which the repeating unit represented by formula (D) is introduced into the resin (A).

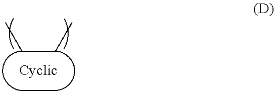

In formula D, “Cyclic” represents a group having a ring structure forming the main chain. No particular limitation is imposed on the number of atoms forming the ring.

Specific examples of the repeating unit represented by formula (D) include those described in paragraphs [0126] to [0127] of WO2018/193954A.

### (Repeating Unit Represented by Formula (E))

One specific example of means for achieving the method (e) is a method in which the repeating unit represented by formula (E) is introduced into the resin (A).

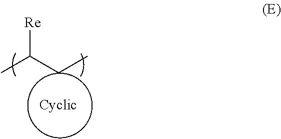

In formula (E), Re's each independently represent a hydrogen atom or an organic group. Examples of the organic group include alkyl groups, cycloalkyl groups, aryl groups, aralkyl groups, and alkenyl groups, each of which may have a substituent.

“Cyclic” is a cyclic group including a carbon atom included in the main chain. No particular limitation is imposed on the number of atoms included in the cyclic group.

Specific examples of the repeating unit represented by formula (E) include those described in paragraphs [0131] to [0133] of WO2018/193954A.

### <Repeating Unit Having Alicyclic Hydrocarbon Structure and Exhibiting No Acid Decomposability>

The resin (A) may have a repeating unit having an alicyclic hydrocarbon structure and exhibiting no acid decomposability. Examples of such a repeating unit include repeating units derived from 1-adamantyl (meth)acrylate, diamantyl (meth)acrylate, tricyclodecanyl (meth)acrylate, and cyclohexyl (meth)acrylate.

From the viewpoint of improving the adhesiveness to a substrate and the affinity for a developer, it is also preferable that the alicyclic hydrocarbon structure is substituted with a hydroxy group or a cyano group.

Specific examples of the repeating unit having the alicyclic hydrocarbon structure having a hydroxy group or a cyano group include repeating units described in paragraphs [0081] to [0084] of JP2014-098921A.

### <Additional Repeating Units>

The resin (A) may further have a repeating unit other than the repeating units described above.

For example, the resin (A) may have a repeating unit selected from the group consisting of a repeating unit having an oxathiane ring group, a repeating unit having an oxazolone ring group, a repeating unit having a dioxane ring group, and a repeating unit having a hydantoin ring group.

Examples of such a repeating unit are shown below.

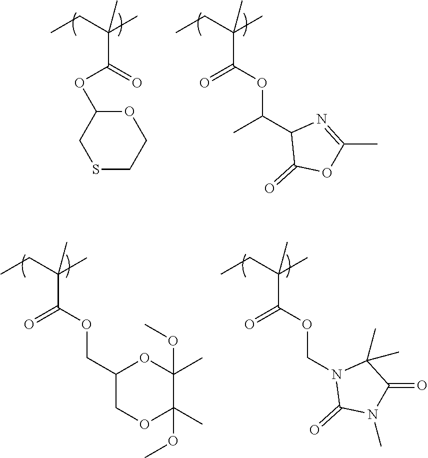

The resin (A) may have, in addition to the repeating units described above, various repeating units for the purpose of controlling dry etching resistance, suitability for a standard developer, adhesiveness to a substrate, a resist profile, resolving power, heat resistance, sensitivity, etc.

The resin (A) can be synthesized by a routine method (for example, radical polymerization).

The weight average molecular weight of the resin (A) that is determined as a polystyrene-equivalent value by the GPC method is preferably 30,000 or less, more preferably 1,000 to 30,000, still more preferably 3,000 to 30,000, and particularly preferably 5,000 to 15,000.

The dispersity (molecular weight distribution) of the resin (A) is preferably 1 to 5, more preferably 1 to 3, still more preferably 1.2 to 3.0, and particularly preferably 1.2 to 2.0. The smaller the dispersity, the better the resolution and the resist profile, and the smoother the side surfaces of the resist pattern, so that better roughness quality is obtained.

In the resist composition, the lower limit of the content of the resin (A) with respect to the total amount of the solids in the resist composition is preferably 35.0% by mass or more, more preferably 40.0% by mass or more, and still more preferably 45.0% by mass or more. The upper limit of the content of the resin (A) with respect to the total amount of the solids in the resist composition is preferably 99.9% by mass or less, more preferably 90.0% by mass or less, and still more preferably 80.0% by mass or less.

One resin (A) may be used alone, or a combination of two or more resins (A) may be used. When two or more resins (A) are used, it is preferable that the total content of the resins (A) is within the preferred range of the content.

### [Solvent]

The resist composition contains a solvent.

Preferably, the solvent includes at least one of (M1) propylene glycol monoalkyl ether carboxylate or (M2) at least one selected from the group consisting of propylene glycol monoalkyl ethers, lactates, acetates, alkoxypropionates, chain ketones, cyclic ketones, lactones (such as γ-butyrolactone), and alkylene carbonates. The solvent may further include a component other than the components (M1) and (M2).

The use of a combination of the above-described solvent and the above-described resin is preferred because the ease of application of the resist composition is improved and the number of development defects in a pattern is reduced. Since the solubility of the resin in the above solvent, the boiling point of the solvent, and its viscosity are well-balanced, unevenness of the thickness of a resist film, the occurrence of precipitation during spin coating, etc. can be reduced.

The details of the components (M1) and (M2) are described in paragraphs [0218] to [0226] of WO2020/004306A, the contents of which are incorporated herein.

When the solvent further includes a component other than the components (M1) and (M2), the content of the component other than the components (M1) and (M2) with respect to the total amount of the solvent is preferably 5 to 30% by mass.

The content of the solvent in the resist composition is determined such that the concentration of the solids is preferably 0.5 to 30% by mass and more preferably 1 to 20% by mass. In this case, the ease of application of the resist composition can be further improved.

### [Photoacid Generator (C)]

The resist composition may further contain a photoacid generator (C) in addition to the specific onium salt.

The photoacid generator (C) may be in the form of a low-molecular weight compound or may be in the form in which the photoacid generator (C) is incorporated into part of a polymer (e.g., the resin (A) described above). A combination of the form of a low-molecular-weight compound and the form in which the photoacid generator (C) is incorporated into part of a polymer (e.g., the resin (A) described above) may also be used.

When the photoacid generator (C) is in the form of a low-molecular weight compound, the molecular weight of the photoacid generator is preferably 3000 or less, more preferably 2000 or less, and still more preferably 1000 or less. No particular limitation is imposed on the lower limit of the molecular weight, but the molecular weight is preferably 100 or more.

When the photoacid generator (C) is in the form in which the photoacid generator (C) is incorporated into part of a polymer, the photoacid generator (C) may be incorporated into part of the resin (A) or into a resin different from the resin (A).

In the present specification, it is preferable that the photoacid generator (C) is in the form of a low-molecular weight compound.

### <Photoacid Generator PG1>

The photoacid generator (C) is, for example, a compound (onium salt) represented by “M⁺X⁻” and is preferably a compound that generates an organic acid upon exposure to light.

One exemplary preferred mode of the photoacid generator (C) is a compound (onium salt) that is represented by “M⁺X⁻” and generates an organic acid upon exposure to light (this compound is hereinafter referred to also as a “photoacid generator PG1.”

In the compound represented by “M⁺X⁻,” M⁺ represents an organic cation, and X⁻ represents an organic anion.

Examples of the organic acid include sulfonic acids (such as aliphatic sulfonic acids, aromatic sulfonic acids, and camphorsulfonic acid), carboxylic acids (such as aliphatic carboxylic acids, aromatic carboxylic acids, and aralkyl carboxylic acids), carbonylsulfonylimidic acid, bis(alkylsulfonyl)imidic acids, and tris(alkylsulfonyl)methide acids.

The photoacid generator PG1 will be described.

In the compound represented by “M⁺X⁻,” M⁺ represents an organic cation.

No particular limitation is imposed on the organic cation. The valence of the organic cation may be 1 or 2 or more.

The organic cation is the same as the organic cations represented by M₁⁺ and M₂⁺ in the compound (specific onium salt) represented by formula (1) described above, and its preferred modes are also the same.

In the compound represented by “M⁺X⁻,” X⁻ represents an organic anion.

No particular limitation is imposed on the organic anion, and examples thereof include monovalent organic anions and divalent and higher valent organic anions.

The organic anion is preferably an anion whose ability to cause a nucleophilic reaction is very low and is more preferably a non-nucleophilic anion.

Examples of the non-nucleophilic anion include sulfonate anions (such as aliphatic sulfonate anions, aromatic sulfonate anions, and a camphorsulfonate anion), carboxylate anions (such as aliphatic carboxylate anions, aromatic carboxylate anions, and aralkyl carboxylate anions), sulfonylimide anions, bis(alkylsulfonyl)imide anions, and tris(alkylsulfonyl)methide anions.

It is also preferable that the organic anion is, for example, an organic anion represented by the following formula (DA).

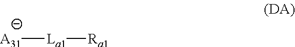

In formula (DA), A₃₁⁻ represents an anionic group. Rₐ₁ represents a hydrogen atom or a monovalent organic group. Lₐ₁ represents a single bond or a divalent linking group.

A₃₁⁻ represents an anionic group. No particular limitation is imposed on the anionic group represented by A₃₁⁻, but the anionic group represented by A₃₁⁻ is, for example, preferably a group selected from the group consisting of groups represented by formulas (B-1) to (B-14) and is more preferably a group represented by formula (B-1), formula (B-2), formula (B-3), formula (B-4), formula (B-5), formula (B-6), formula (B-10), formula (B-12), formula (B-13), or formula (B-14).

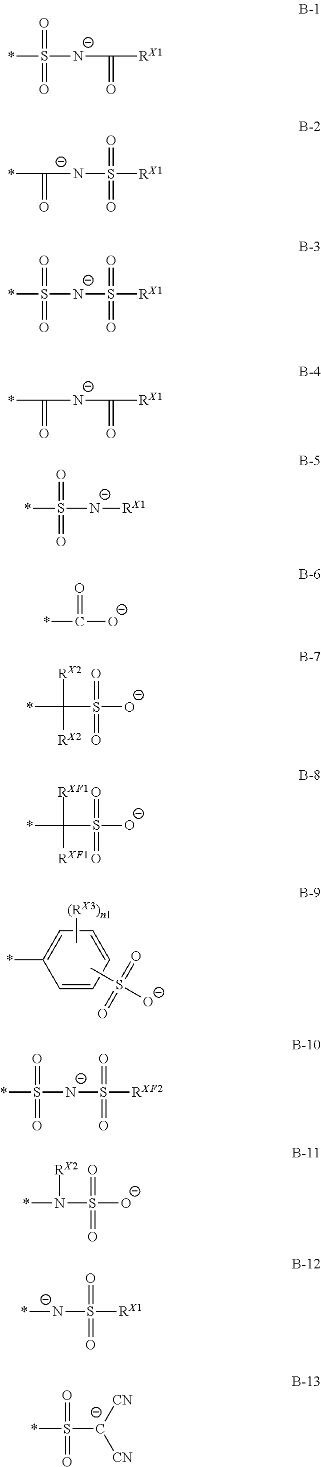

In formula (B-9), R^{X3} represents a hydrogen atom, a halogen atom, or a monovalent organic group. n1 represents an integer of 0 to 4. When n1 is an integer of 2 to 4, a plurality of R^{X3}'s may be the same or different.

In formula (B-10), R^{XF2} represents a fluorine atom or a perfluoroalkyl group.

A group bonded at the bonding position represented by * in formula (B-14) is preferably a phenylene group optionally having a substituent. Examples of the optional substituent on the phenylene group include halogen atoms.

In formulas (B-1) to (B-5) and (B-12), R^{X1}'s each independently represent a monovalent organic group.

R^{X1} is preferably an alkyl group (which may be either linear or branched and in which the number of carbon atoms is preferably 1 to 15), a cycloalkyl group (which may be either monocyclic or polycyclic and in which the number of carbon atom is preferably 3 to 20), or an aryl group (which may be either monocyclic or polycyclic and in which the number of carbon atom is preferably 6 to 20). The group represented by R^{X1} may have a substituent.

In formula (B-5), it is also preferable that an atom in R^{X1} that is bonded directly to N— is not the carbon atom in —CO— and the sulfur atom in —SO₂—.

The cycloalkyl group represented by R^{X1} may be either monocyclic or polycyclic.

Examples of the cycloalkyl group represented by R^{X1} include a norbornyl group and an adamantyl group.

No particular limitation is imposed on the optional substituent on the cycloalkyl group represented by R^{X1}. The optional substituent is preferably an alkyl group (which may be either linear or branched and in which the number of carbon atoms is preferably 1 to 5). At least one carbon atom serving as a ring member atom in the cycloalkyl group represented by R^{X1} may be replaced with a carbonyl carbon atom.

The number of carbon atoms in the alkyl group represented by R^{X1} is preferably 1 to 10 and more preferably 1 to 5.

No particular limitation is imposed on the optional substituent on the alkyl group represented by R^{X1}, but the substituent is, for example, preferably a cycloalkyl group, a fluorine atom, or a cyano group.

Examples of the cycloalkyl group serving as the substituent are the same as those of the cycloalkyl group described when R^{X1} is a cycloalkyl group.

When the alkyl group represented by R^{X1} has a fluorine atom as the substituent, the alkyl group may be a perfluoroalkyl group.

In the alkyl group represented by R^{X1}, at least one —CH₂— may be replaced with a carbonyl group.

The aryl group represented by R^{X1} is preferably a benzene ring group.

No particular limitation is imposed on the optional substituent on the aryl group represented by R^{X1}, but the substituent is preferably an alkyl group, a fluorine atom, or a cyano group. Examples of the alkyl group serving as the substituent are the same as those of the alkyl group described when R^{X1} is an alkyl group.

In formulas (B-7) and (B-11), R^{X2}'s each independently represent a hydrogen atom or a substituent other than a fluorine atom and a perfluoroalkyl group (such as an alkyl group containing no fluorine atom or a cycloalkyl group containing no fluorine atom). The two R^{X2}'s in formula (B-7) may be the same or different.

In formula (B-8), R^{XF1}'s each represent a hydrogen atom, a fluorine atom, or a perfluoroalkyl group. However, at least one of the plurality of R^{XF1}'s represents a fluorine atom or a perfluoroalkyl group. The two R^{XF1}'s in formula (B-8) may be the same or different. The number of carbon atoms in the perfluoroalkyl group represented by R^{XF1} is preferably 1 to 15, more preferably 1 to 10, and still more preferably 1 to 6.

In formula (B-9), R^{X3} represents a hydrogen atom, a halogen atom, or a monovalent organic group. Examples of the halogen atom represented by R^{X3} include a fluorine atom, a chlorine atom, a bromine atom, and an iodine atom, and the halogen atom is preferably a fluorine atom.

Examples of the monovalent organic group represented by R^{X3} are the same as those of the monovalent organic group described as R^{X1}.

n1 represents an integer of 0 to 4.

n1 is preferably an integer of 0 to 2 and is preferably 0 or 1. When n1 represents an integer of 2 to 4, the plurality of R^{X3}'s may be the same or different.

In formula (B-10), R^{XF2} represents a fluorine atom or a perfluoroalkyl group.

The number of carbon atoms in the perfluoroalkyl group represented by R^{XF2} is preferably 1 to 15, more preferably 1 to 10, and still more preferably 1 to 6.

In formula (DA), no particular limitation is imposed on the monovalent organic group represented by Rₐ₁, but the number of carbon atoms in the monovalent organic group is generally 1 to 30 and preferably 1 to 20.

Rₐ₁ is preferably an alkyl group, a cycloalkyl group, or an aryl group.

The alkyl group may be either linear or branched and is preferably an alkyl group having 1 to 20 carbon atoms, more preferably an alkyl group having 1 to 15 carbon atoms, and still more preferably an alkyl group having 1 to 10 carbon atoms.

The cycloalkyl group may be either monocyclic or polycyclic and is preferably a cycloalkyl group having 3 to 20 carbon atoms, more preferably a cycloalkyl group having 3 to 15 carbon atoms, and still more preferably a cycloalkyl group having 3 to 10 carbon atoms.

The aryl group may be either monocyclic or polycyclic and is preferably an aryl group having 6 to 20 carbon atoms, more preferably an aryl group having 6 to 15 carbon atoms, and still more preferably an aryl group having 6 to 10 carbon atoms.

The cycloalkyl group may contain a heteroatom as a ring member atom.

No particular limitation is imposed on the heteroatom, and examples of the heteroatom include a nitrogen atom and an oxygen atom.

The cycloalkyl group may contain a carbonyl bond (>C═O) as a ring member atom.

The alkyl group, the cycloalkyl group, and the aryl group may each further have a substituent.

No particular limitation is imposed on the divalent linking group represented by Lₐ₁, but the divalent linking group is an alkylene group, a cycloalkylene group, an aromatic group, —O—, —CO—, —SO—, —SO₂—, or a group formed by combining any of these groups.

The alkylene group may be either linear or branched, and the number of carbon atoms is preferably 1 to 20 and more preferably 1 to 10.

The cycloalkylene group may be either monocyclic or polycyclic, and the number of carbon atoms is preferably 3 to 20 and more preferably 3 to 10.

The aromatic group is a divalent aromatic group and is preferably an aromatic group having 6 to 20 carbon atoms and more preferably an aromatic group having 6 to 15 carbon atoms.

No particular limitation is imposed on the aromatic ring included in the aromatic group, and examples thereof include aromatic rings having 6 to 20 carbon atoms. Specific examples of the aromatic ring include a benzene ring, a naphthalene ring, an anthracene ring, and a thiophene ring. The aromatic ring included in the aromatic group is preferably a benzene ring or a naphthalene ring and more preferably a benzene ring.

The alkylene group, the cycloalkylene group, and the aromatic ring may each further have a substituent, and the substituent is preferably a halogen atom.

A₃₁⁻ and Rₐ₁ may be bonded together to form a ring.

The photoacid generator PG1 used is, for example, preferably any of the photoacid generators disclosed in paragraphs [0135] to [0171] of WO2018/193954A, paragraphs [0077] to [0116] of WO2020/066824A, and paragraphs [0018] to [0075] and [0334] to [0335] of WO2017/154345.

The molecular weight of the photoacid generator PG1 is preferably 3000 or less, more preferably 2000 or less, and still more preferably 1000 or less.

### <Photoacid Generator PG2>

Another preferred example of the photoacid generator (C) is the following compound (I) (hereinafter referred to also as a “photoacid generator PG2”). The photoacid generator PG2 is a compound that has two or more salt structure moieties described above and that generates a polyvalent organic acid when exposed to light.

The photoacid generator PG2 will be described.

### (Compound (I))

The compound (I) is a compound having at least one structural moiety X described below and at least one structural moiety Y described below and is a compound that generates an acid including a first acidic moiety described below and derived from the structural moiety X and a second acidic moiety described below and derived from the structural moiety Y when irradiated with actinic rays or radiation.

Structural moiety X: A structural moiety that includes an anionic moiety A₁⁻ and a cationic moiety M₁⁺ and forms the first acidic moiety represented by HA₁ when irradiated with actinic rays or radiation.

Structural moiety Y: A structural moiety that includes an anionic moiety A₂ and a cationic moiety M₂⁺ and forms the second acidic moiety represented by HA₂ when irradiated with actinic rays or radiation.

The compound (I) satisfies the following condition I.

Condition I: A compound PI formed by replacing each of the cationic moiety M₁⁺ in the structural moiety X in the compound (I) and the cationic moiety M₂⁺ in the structural moiety Y with H⁺ has an acid dissociation constant a1 derived from the acidic moiety represented by HA₁ formed by replacing the cationic moiety M₁⁺ in the structural moiety X with H⁺ and an acid dissociation constant a2 derived from the acidic moiety represented by HA₂ formed by replacing the cationic moiety M₂⁺ in the structural moiety Y with H⁺, and the acid dissociation constant a2 is larger than the acid dissociation constant a1.

In one mode of the compound (I), the compound (I) has two structural moieties X and one structural moiety Y.

When the compound (I) is, for example, a compound having two structural moieties X and one structural moiety Y (i.e., a compound that generates an acid having two first acidic moieties derived from the structural moieties X and one second acidic moiety derived from the structural moiety Y), the compound PI corresponds to a “compound having two HA₁'s and one HA₂.”

When the acid dissociation constants of the compound PI are determined, the acid dissociation constant when the compound PI becomes a “compound having one A₁⁻, one HA₁, and one HA₂,” and the acid dissociation constant when the “compound having one A₁⁻, one HA₁, and one HA₂” becomes a “compound having two A₁⁻'s and one HA₂” each correspond to the acid dissociation constant a1. Moreover, the acid dissociation constant when the “compound having two A₁⁻'s and one HA₂” becomes a “compound having two A₁⁻'s and A₂⁻” corresponds to the acid dissociation constant a2. Specifically, the compound PI has a plurality of acid dissociation constants derived from acidic moieties each represented by HA₁ formed by replacing cationic moieties M₁⁺ in the structural moieties X with H⁺. In this case, the acid dissociation constant a2 is larger than the largest one of the plurality of acid dissociation constants a1. Let aa be the acid dissociation constant when the compound PI becomes the “compound having one A₁⁻, one HA₁, and one HA₂,” and ab be the acid dissociation constant when the “compound having one A₁⁻, one HA₁, and one HA₂” becomes the “compound having two A₁⁻'s and one HA₂.” Then aa and ab satisfy the relation aa<ab.

The acid dissociation constants a1 and a2 are determined by the acid dissociation constant measurement method described above.

The compound PI corresponds to the acid generated when the compound (I) is irradiated with actinic rays or radiation.

In the compound PI, the difference (absolute difference) between the acid dissociation constant a1 (the maximum acid dissociation constant value when a plurality of acid dissociation constants a1 are present) and the acid dissociation constant a2 is preferably 0.1 or more, more preferably 0.5 or more, and still more preferably 1.0 or more. No particular limitation is imposed on the upper limit of the difference (absolute difference) between the acid dissociation constant a1 (the maximum acid dissociation constant value when a plurality of acid dissociation constants a1 are present) and the acid dissociation constant a2, but the upper limit is, for example, 16 or less.

In the compound PI, the acid dissociation constant a2 is preferably 20 or less and more preferably 15 or less. The lower limit of the acid dissociation constant a2 is preferably -4.0 or more.

In the compound PI, the acid dissociation constant a1 is preferably 2.0 or less and more preferably 0 or less. The lower limit of the acid dissociation constant a1 is preferably -20.0 or more.

When the compound (I) has two or more structural moieties X, the structural moieties X may be the same or different. Two or more A₁⁻'s may be the same or different, and two or more M₁⁺'s may be the same or different.

In the compound (I), A₁⁻ and A₂⁻ may be the same or different, and M₁⁺ and M₂⁺ may be the same or different. However, it is preferable that A₁⁻ and A₂⁻ are different from each other.

The anionic moiety A₁⁻ and the anionic moiety A₂⁻ are each a structural moiety including a negatively charged atom or atomic group and are each, for example, a structural moiety selected from the group consisting of formulas (AA-1) to (AA-3) and formulas (BB-1) to (BB-6) shown below.

The anionic moiety A₁⁻ is preferably a moiety capable of forming an acidic moiety having a small acid dissociation constant, more preferably a moiety represented by one of formulas (AA-1) to (AA-3), and still more preferably a moiety represented by one of formulas (AA-1) and (AA-3).

The anionic moiety A₂⁻ is preferably a moiety capable of forming an acidic moiety having a larger acid dissociation constant than the anionic moiety A₁⁻, more preferably a moiety represented by one of formulas (BB-1) to (BB-6), and still more preferably a moiety represented by one of formulas (BB-1) and (BB-4).

In formulas (AA-1) to (AA-3) and formulas (BB-1) to (BB-6) below, * represents a bonding position.

In formula (AA-2), R^{A} represents a monovalent organic group. No particular limitation is imposed on the monovalent organic group represented by R^{A}, and examples thereof include a cyano group, a trifluoromethyl group, and a methanesulfonyl group.

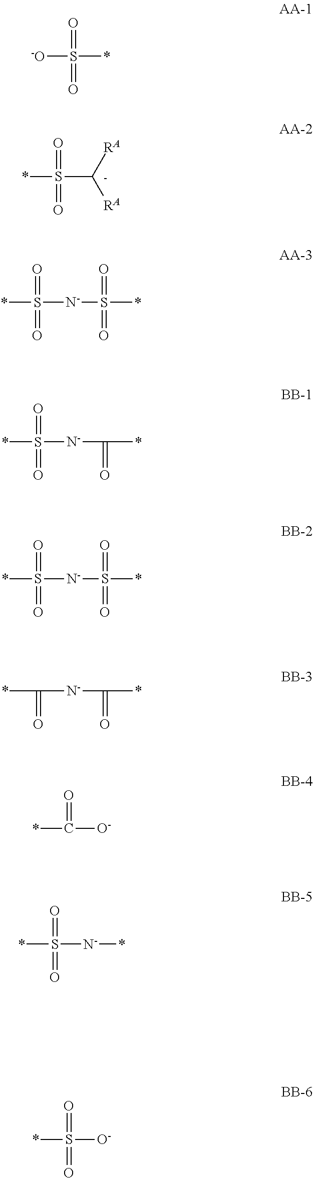

The cationic moiety M₁⁺ and the cationic moiety M₂⁺ are each a structural moiety including a positively charged atom or atomic group and are each, for example, a singly charged organic cation.

The organic cation is the same as the organic cations represented by M₁⁺ and M₂⁺ in the compound (specific onium salt) represented by formula (1) described above, and its preferred modes are also the same.

The molecular weight of the photoacid generator PG2 is preferably 100 to 10000, more preferably 100 to 2500, and still more preferably 100 to 1500.

The photoacid generator PG2 used may be any of the compounds exemplified in paragraphs [0023] to [0078] of WO2020/158313A.

Specific examples of the photoacid generator (C) are shown below, but the photoacid generator (C) is not limited thereto.

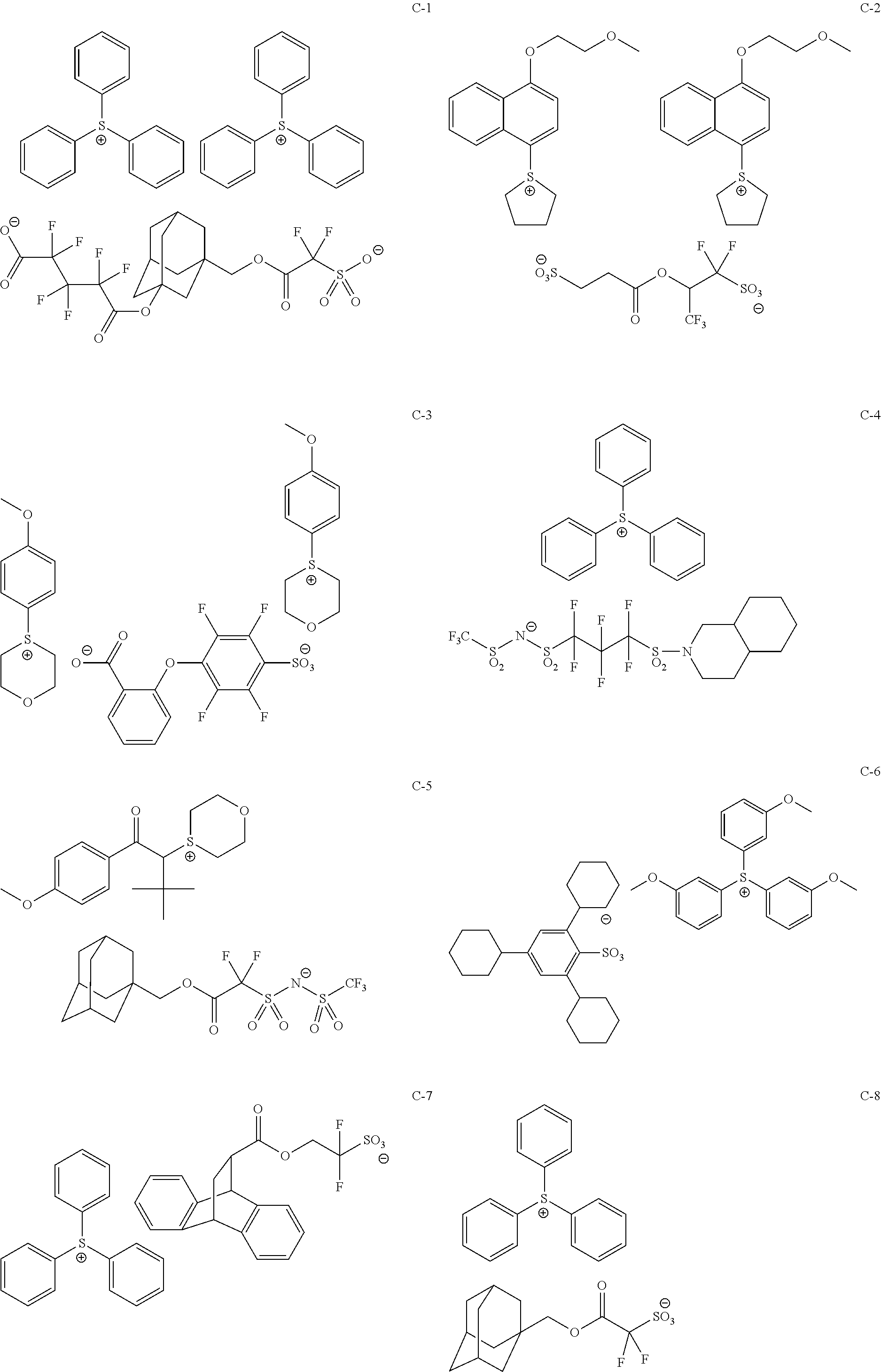

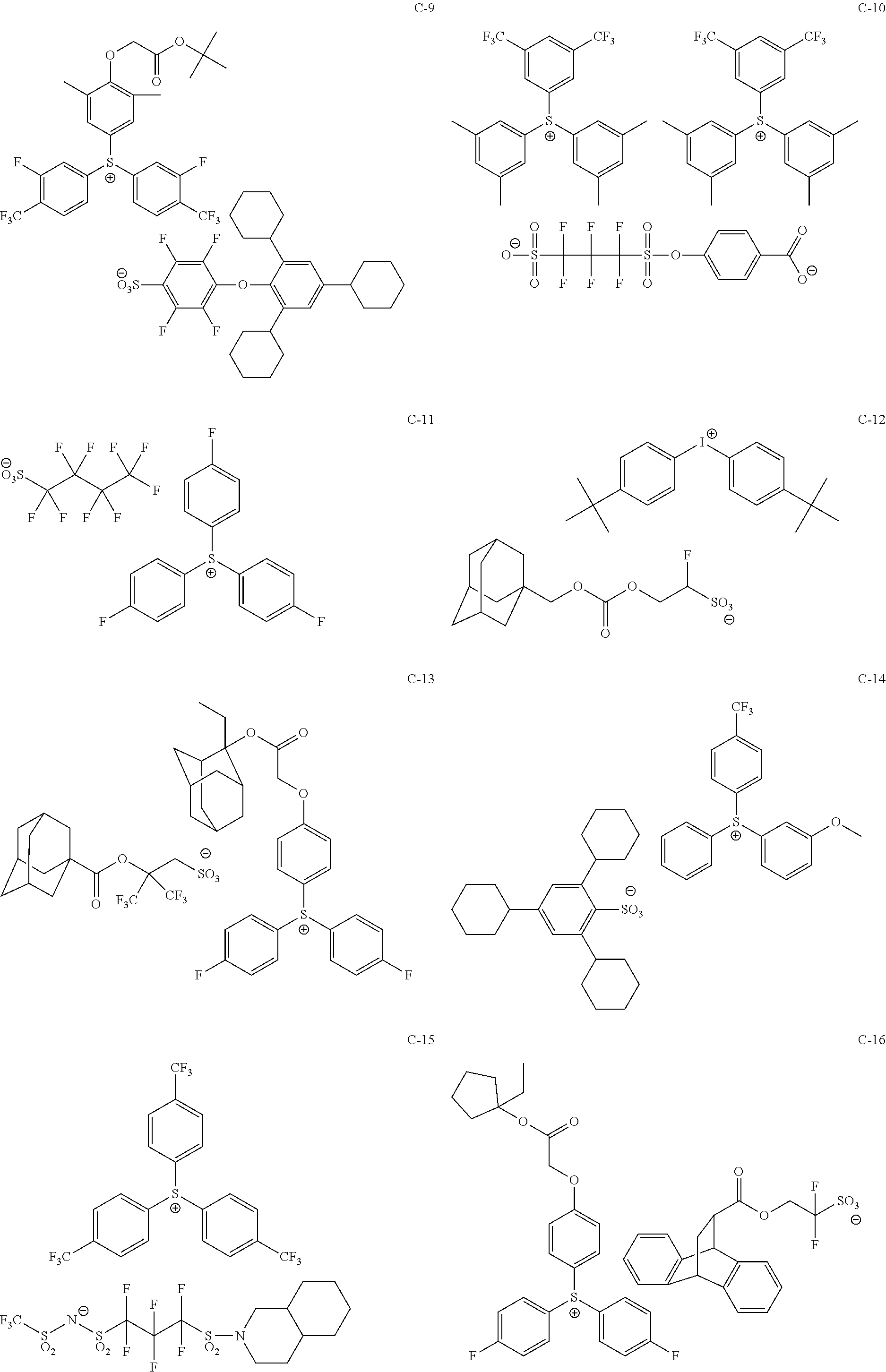

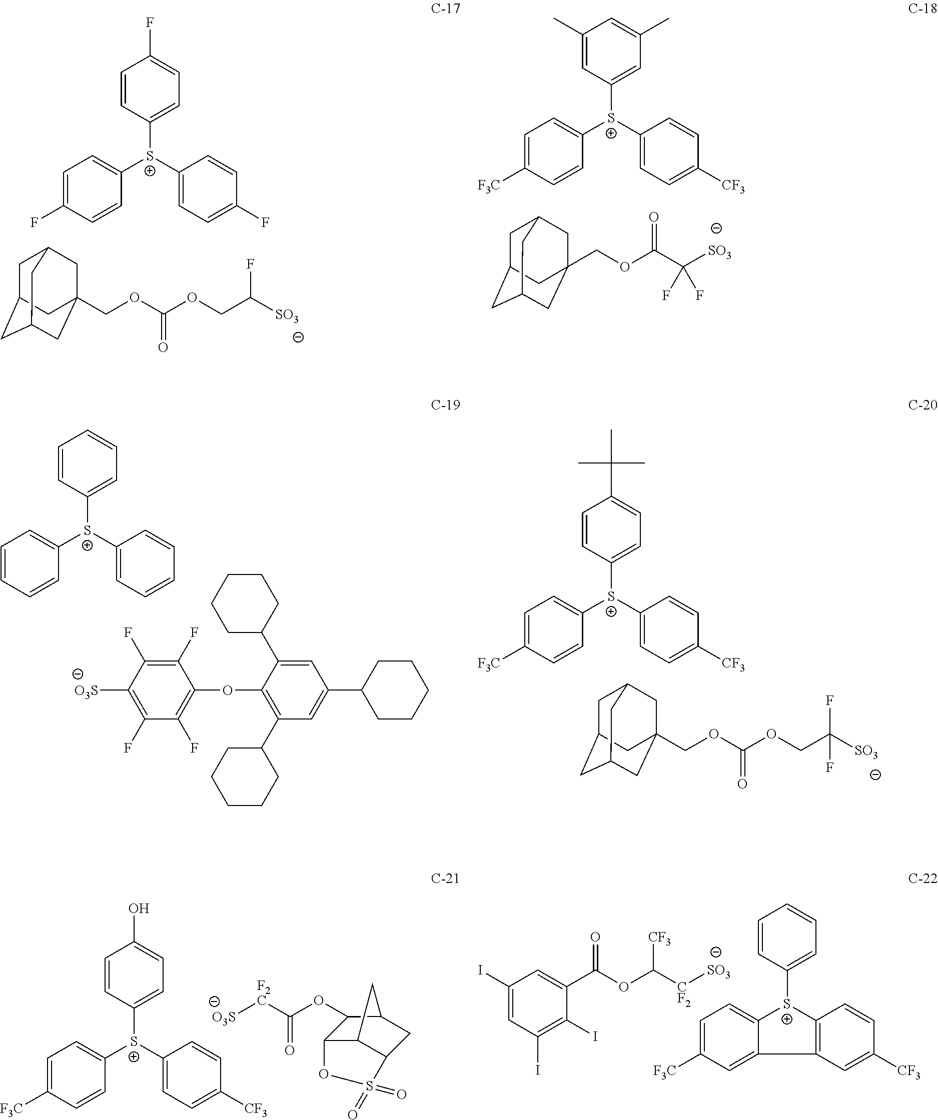

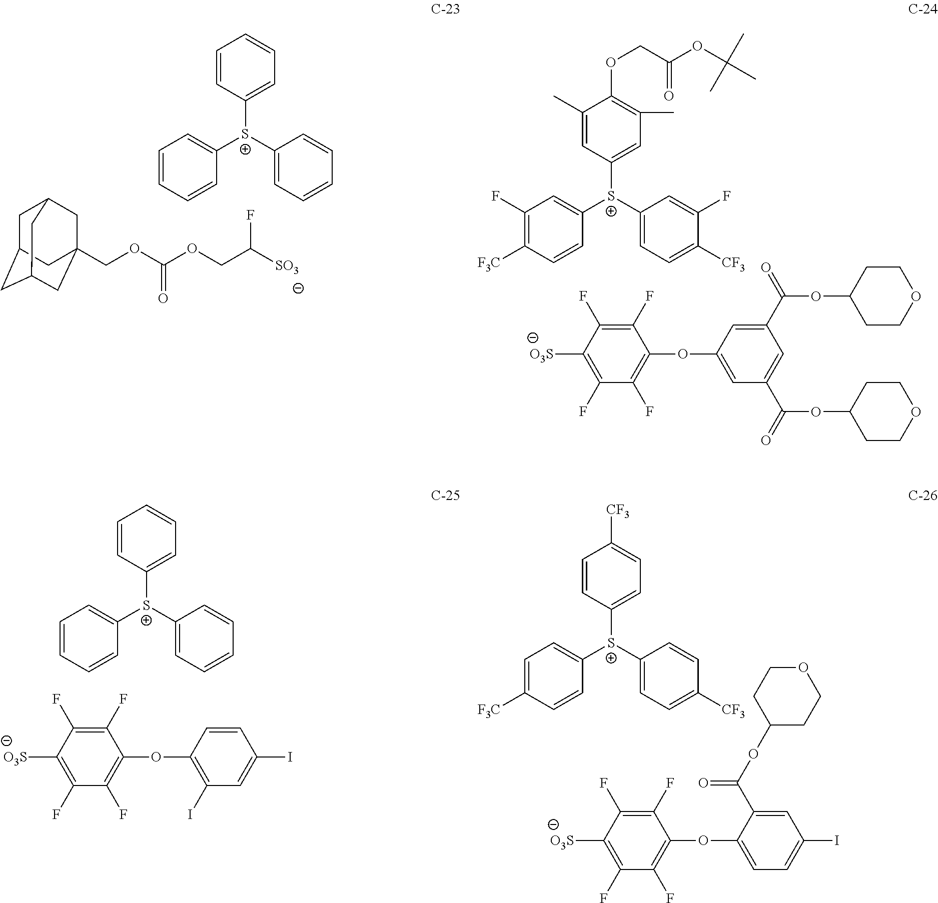

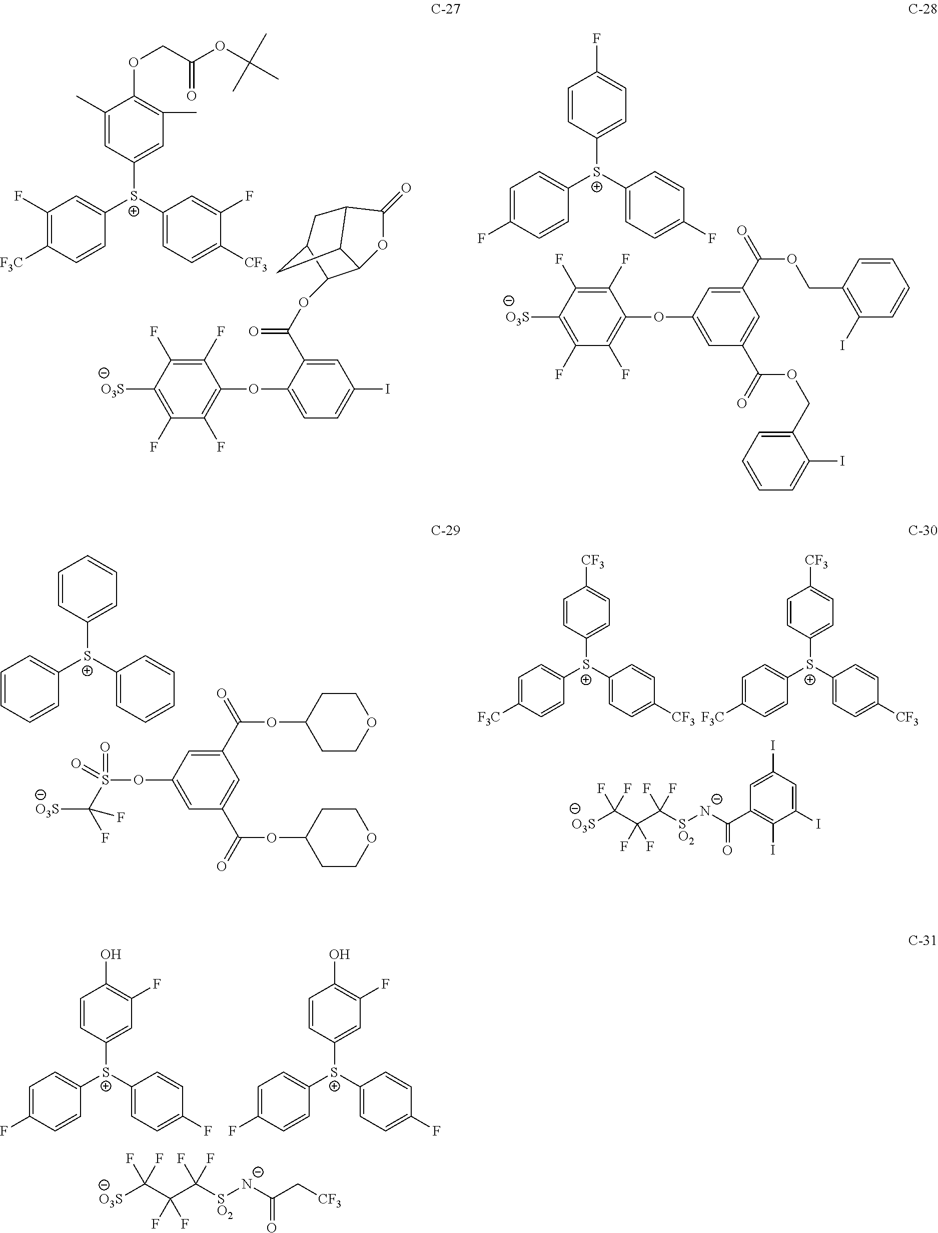

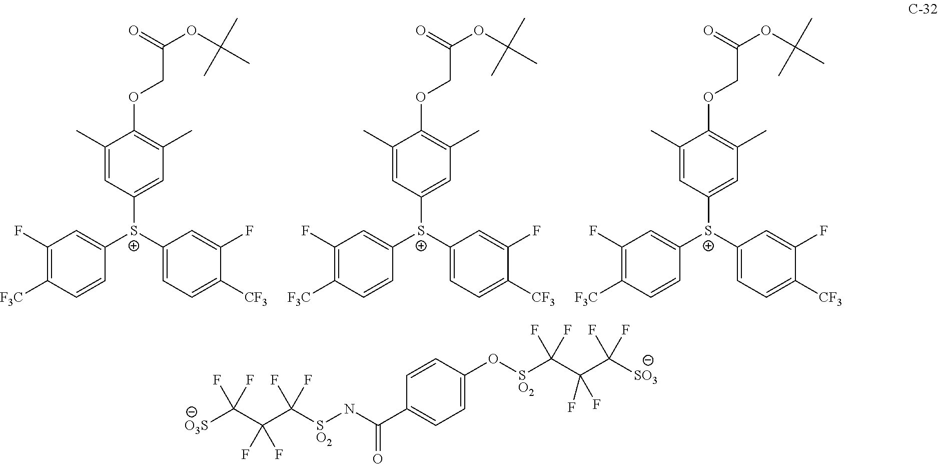

When the resist composition contains the photoacid generator (C), no particular limitation is imposed on the content of the photoacid generator (C). The content of the photoacid generator (C) with respect to the total amount of the solids in the resist composition is preferably 0.5% by mass or more and more preferably 1.0% by mass or more because the pattern to be formed can have a sharper rectangular cross-sectional shape. The content with respect to the total amount of the solids in the resist composition is preferably 25.0% by mass or less, more preferably 20.0% by mass or less, and still more preferably 15.0% by mass or less.

One photoacid generator (C) may be used alone, or two or more photoacid generators (C) may be used. When two or more photoacid generators (C) are used, it is preferable that the total content is within the preferred range of the content.

### [Acid Diffusion Control Agent (D)]

The resist composition may contain an acid diffusion control agent.

The acid diffusion control agent functions as a quencher that traps the acid generated from the photoacid generator etc. during exposure to light to thereby suppress the reaction of the acid-decomposable resin with an excess portion of the generated acid in unexposed portions.

No particular limitation is imposed on the acid diffusion control agent, and examples thereof include a basic compound (DA), a low-molecular weight compound (DB) having a nitrogen atom and having a group that is dissociable under the action of acid, and a compound (DC) whose acid diffusion control ability decreases or disappears when the compound (DC) is irradiated with actinic rays or radiation.

Examples of the compound (DC) include an onium salt compound (DD) that serves as a weak acid weaker than the photoacid generator and a basic compound (DE) whose basicity decreases or disappears upon irradiation with actinic rays or radiation.

Specific examples of the basic compound (DA) include those described in paragraphs [0132] to [0136] of WO2020/066824A, and specific examples of the basic compound (DE) whose basicity decreases or disappears upon irradiation with actinic rays or radiation include those described in paragraphs [0137] to [0155] of WO2020/066824A. Specific examples of the low-molecular weight compound (DB) having a nitrogen atom and having a group that is dissociable under the action of acid include those described in paragraphs [0156] to [0163] of WO2020/066824A, and specific examples of an onium salt compound that has a nitrogen atom in its cationic moiety include those described in paragraph [0164] of WO2020/066824A.

Specific examples of the onium salt compound (DD) that serves as a weak acid weaker than the photoacid generator include those described in paragraphs [0305] to [0314] of WO2020/158337A.

In addition to the compounds described above, for example, known compounds disclosed in paragraphs [0627] to [0664] of US2016/0070167A, paragraphs [0095] to [0187] of US2015/0004544A, paragraphs [0403] to [0423] of US2016/0237190A, and paragraphs [0259] to [0328] of US2016/0274458A can be preferably used as the acid diffusion control agent.

When the resist composition contains the acid diffusion control agent, the content of the acid diffusion control agent (the total content when a plurality of acid diffusion control agents are present) with respect to the total amount of the solids in the resist composition is preferably 0.1 to 20.0% by mass, more preferably 0.1 to 15.0% by mass, and still more preferably 1.0 to 15.0% by mass.

In the resist composition, one acid diffusion control agent may be used alone, or a combination of two or more may be used. When two or more acid diffusion control agents are used, it is preferable that the total content is within the above-described preferred range of the content.

### [Hydrophobic Resin (I)]

The resist composition may further contain a hydrophobic resin different from the resin (A).

Preferably, the hydrophobic resin is designed so as to segregate on the surface of a resist film. However, it is not always necessary that, unlike a surfactant, the hydrophobic resin have a hydrophilic group in its molecule and contribute to uniform mixing of polar and nonpolar substances.

The effects of the addition of the hydrophobic resin include control of the static and dynamic contact angles of water on the surface of the resist film and reduction of outgassing.

From the viewpoint of segregation of the hydrophobic resin in a surface layer of the film, the hydrophobic resin has preferably at least one of a fluorine atom, a silicon atom, or a CH₃ partial structure included in a side chain portion of the resin and has more preferably two or more of them. Preferably, the hydrophobic resin has a hydrocarbon group having 5 or more carbon atoms. Each of these groups may be present as a substituent on the main chain of the resin or its side chain.

Examples of the hydrophobic resin include compounds described in paragraphs [0275] to [0279] of WO2020/004306A.

When the resist composition contains the hydrophobic resin, the content of the hydrophobic resin with respect to the total amount of the solids in the resist composition is preferably 0.01 to 20.0% by mass and more preferably 0.1 to 15.0% by mass.

In the resist composition, one hydrophobic resin may be used alone, or a combination of two or more may be used. When two or more hydrophobic resins are used, it is preferable that the total content is within the above-described preferred range of the content.

### [Surfactant (E)]

The resist composition may contain a surfactant. When the surfactant is contained, the composition has better adhesiveness, and a pattern with fewer development defects can be formed.

The surfactant is preferably a fluorine-based surfactant and/or a silicon-based surfactant.

Examples of the fluorine-based surfactant and/or the silicon-based surfactant include surfactants disclosed in paragraphs [0218] and [0219] of WO2018/193954A.

One of these surfactants may be used alone, or two or more of them may be used.

When the resist composition contains the surfactant, the content of the surfactant with respect to the total amount of the solids in the resist composition is preferably 0.0001 to 2.0% by mass, more preferably 0.0005 to 1.0% by mass, and still more preferably 0.1 to 1.0% by mass. When two or more surfactants are used, it is preferable that the total content is within the above-described preferred range of the content.

### [Additional Additives]

The resist composition may further contain a dissolution inhibiting compound, a dye, a plasticizer, a photosensitizer, a light absorber, and/or a compound capable of increasing the solubility in a developer (such as a phenol compound having a molecular weight of 1000 or less or an alicyclic or aliphatic compound including a carboxy group).

The “dissolution inhibiting compound” is a compound that has a molecular weight of 3000 or less and is decomposed under the action of acid to cause the degree of solubility of the resist composition in an organic-based developer to decrease.

The resist composition in the present specification is preferably used as a photosensitive composition for EUV exposure.

The wavelength of the EUV light is 13.5 nm and is shorter than the wavelength of ArF light (wavelength: 193 nm) etc., and the number of incident photons is smaller when light exposure is performed at the same sensitivity. Therefore, the influence of “photon shot noise,” i.e., stochastic variations in the number of photons, is large, and this causes an increase in LER and bridge defects. One method to reduce the photon shot noise is to increase the exposure value to increase the number of incident photons, but there is a trade-off with the demand for higher sensitivity.

When the value of A determined by the following formula (1) is high, the efficiency of absorption of EUV light and electron beams by a resist film formed using the resist composition is high, and this is effective in reducing the photon shot noise. The value of A represents the efficiency of absorption of EUV light and electron beams by a resist film having a specific mass ratio.

$$A = ( [ H ] \times 0.04 + [ C ] \times 1.0 + [ N ] \times 2.1 + [ O ] \times 3.6 + [ F ] \times 5.6 + [ S ] \times 1.5 + [ I ] \times 39 \text{.5} ) / ( [ H ] \times 1 + [ C ] \times 12 + [ N ] \times 14 + [ O ] \times 16 + [ F ] \times 19 + [ S ] \times 32 + [ I ] \times 127 ) \qquad Formula ( 1 )$$

The value of A is preferably 0.120 or more. No particular limitation is imposed on the upper limit of the value of A. However, if the value of A is excessively large, the EUV light and electron beam transmittance of the resist film decreases, and the profile of an optical image in the resist film deteriorates, so that a good pattern shape is unlikely to be obtained. Therefore, the upper limit is preferably 0.240 or less and more preferably 0.220 or less.

In formula (1), [H] represents the molar ratio of hydrogen atoms derived from the total solids in the resist composition with respect to all the atoms in the total solids, and [C] represents the molar ratio of carbon atoms derived from the total solids in the resist composition with respect to all the atoms in the total solids. [N] represents the molar ratio of nitrogen atoms derived from the total solids in the resist composition with respect to all the atoms in the total solids, and [O] represents the molar ratio of oxygen atoms derived from the total solids in the resist composition with respect to all the atoms in the total solids. [F] represents the molar ratio of fluorine atoms derived from the total solids in the resist composition with respect to all the atoms in the total solids, and [S] represents the molar ratio of sulfur atoms derived from the total solids in the resist composition with respect to all the atoms in the total solids. [I] represents the molar ratio of iodine atoms derived from the total solids in the resist composition with respect to all the atoms in the total solids.

When, for example, the resist composition contains the specific onium salt, the acid-decomposable resin, the photoacid generator, the acid diffusion control agent, and the solvent, the specific onium salt, the acid-decomposable resin, the photoacid generator, and the acid diffusion control agent correspond to the solids. Specifically, all the atoms in the total solids correspond to the sum of all the atoms derived from the specific onium salt, all the atoms derived from the acid-decomposable resin, all the atoms derived from the photoacid generator, and all the atoms derived from the acid diffusion control agent.

For example, [H] represents the molar ratio of hydrogen atoms derived from the total solids with respect to all the atoms in the total solids. In the example described above, [H] represents the total molar ratio of the hydrogen atoms derived from the specific onium salt, the hydrogen atoms derived from the acid-decomposable resin, the hydrogen atoms derived from the photoacid generator, and the hydrogen atoms derived from the acid diffusion control agent with respect to the total amount of all the atoms derived from the specific onium salt, all the atoms derived from the acid-decomposable resin, all the atoms derived from the photoacid generator, and all the atoms derived from the acid diffusion control agent.

When the structures of the constituent components of the total solids in the resist composition and their contents are known, the value of A can be computed by computing the ratio of the numbers of atoms contained in the composition. Even when the constituent components are unknown, the ratio of the numbers of constituent atoms can be computed by subjecting a resist film obtained by evaporating the solvent component in the resist composition to an analytical method such as elemental analysis.

### [Resist Film and Pattern Forming Method]

No particular limitation is imposed on the procedure of a pattern forming method using the above-described resist composition, but it is preferable that the pattern forming method includes the following steps.
Step 1: The step of forming a resist film on a substrate using the resist composition.
Step 2: The step of exposing the resist film to light.
Step 3: The step of developing the exposed resist film using a developer.

The procedure of each of the steps will next be described in detail.

### <Step 1: Step of Forming Resist Film>

Step 1 is the step of forming a resist film on a substrate using the resist composition.

The definition of the resist composition is as described above.

Examples of the method for forming the resist film on the substrate using the resist composition include a method in which the resist composition is applied to the substrate.

Preferably, the resist composition is optionally filtered through a filter before the application as needed. The pore size of the filter is preferably 0.1 μm or less, more preferably 0.05 μm or less, and still more preferably 0.03 μm or less. The filter is preferably a polytetrafluoroethylene-made filter, a polyethylene-made filter, or a nylon-made filter.

The resist composition can be applied to a substrate (e.g., a silicon substrate or a silicon dioxide coating) used for production of an integrated circuit element using an appropriate application method using a spinner, a coater, etc. The application method is preferably spin coating using a spinner. The number or revolutions when the spin coating using a spinner is performed is preferably 1000 to 3000 rpm.

After the application of the resist composition, the substrate may be dried to form the resist film. If necessary, an undercoat film (an inorganic film, an organic film, or an antireflection film) may be formed as an underlayer of the resist film.

Examples of the drying method include a method in which the substrate is heated and dried. The heating may be performed using heating means included in an ordinary exposing device and/or an ordinary developing device or may be performed using a hot plate etc. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

No particular limitation is imposed on the film thickness of the resist film, but the film thickness is preferably 10 to 120 nm because a finer pattern can be formed with higher accuracy. In particular, when the resist film is exposed to EUV light, the film thickness of the resist film is more preferably 10 to 65 nm and still more preferably 15 to 50 nm. When ArF liquid immersion exposure is performed, the film thickness of the resist film is more preferably 10 to 120 nm and still more preferably 15 to 90 nm.

A topcoat may be formed on the resist film using a topcoat composition.

It is preferable that the topcoat composition is immiscible with the resist film and can be uniformly applied to the upper surface of the resist film. No particular limitation is imposed on the topcoat, and a well-known topcoat can be formed using a well-known method. For example, the topcoat can be formed using a method described in paragraphs [0072] to [0082] of JP2014-059543A.

It is preferable, for example, that a topcoat containing a basic compound described in JP2013-61648A is formed on the resist film. Specific examples of the basic compound that can be contained in the topcoat include basic compounds that can be contained in the resist composition.

It is also preferable that the topcoat contains a compound including at least one group or bond selected from the group consisting of an ether bond, a thioether bond, a hydroxy group, a thiol group, a carbonyl bond, and an ester bond.

### <Step 2: Exposure Step>

Step 2 is the step of exposing the resist film to light.

Examples of the light exposure method include a method in which the resist film formed is irradiated with actinic rays or radiation through a prescribed mask.

Examples of the actinic rays or radiation include infrared rays, visible rays, ultraviolet rays, far-ultraviolet rays, extreme ultraviolet rays, X rays, and electron beams. Far-ultraviolet rays having a wavelength of preferably 250 nm or shorter, more preferably 220 nm or shorter, and particularly preferably 1 to 200 nm are preferred. Specifically, KrF excimer laser light (248 nm), ArF excimer laser light (193 nm), F₂ excimer laser light (157 nm), EUV light (13.5 nm), X rays, and electron beams are particularly preferred.

It is preferable to perform baking (heating) after the light exposure but before development. The baking facilitates the reaction in the exposed portions, and the sensitivity and the pattern shape are further improved.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating may be performed using heating means included in an ordinary exposing device and/or an ordinary developing device or may be performed using a hot plate etc.

This step is referred to as post-exposure baking.

### <Step 3: Developing Step>

Step 3 is the step of developing the exposed resist film with a developer to form a pattern.

The developer may be an alkali developer or may be a developer containing an organic solvent (hereinafter referred to as an organic-based developer).

Examples of the developing method include: a method in which the substrate is dipped into a bath filled with the developer for a prescribed time (a dipping method); a method in which the developer is placed on the surface of the substrate so as to form a convex puddle due to surface tension and left to stand for a prescribed time to develop the resist film (a puddle method); a method in which the developer is sprayed onto the surface of the substrate (a spraying method); and a method in which the developer is continuously discharged from a developer discharging nozzle onto the substrate rotating at a constant speed while the developer discharging nozzle is scanned at a constant speed (a dynamic dispensing method).

The step of replacing the developer with another solvent to stop the development may be performed after the developing step.

No particular limitation is imposed on the developing time so long as the resin in unexposed portions is dissolved sufficiently, and the developing time is preferably 10 to 300 seconds and more preferably 20 to 120 seconds.

The temperature of the developer is preferably 0 to 50° C. and more preferably 15 to 35° C.

The alkali developer used is preferably an aqueous alkali solution containing an alkali. No particular limitation is imposed on the type of aqueous alkali solution. Examples of the aqueous alkali solution include aqueous alkali solutions containing quaternary ammonium salts typified by tetramethylammonium hydroxide, inorganic alkalis, primary amines, secondary amines, tertiary amines, alcohol amines, cyclic amines, etc. In particular, the alkali developer is preferably an aqueous solution of a quaternary ammonium salt typified by tetramethylammonium hydroxide (TMAH). An appropriate amount of an alcohol, a surfactant, etc. may be added to the alkali developer. The alkali concentration of the alkali developer is generally preferably 0.1% to 20% by mass. The pH of the alkali developer is generally more preferably 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A mixture of a plurality of solvents selected from the above solvents may be used, or the organic-based developer may be mixed with water or a solvent other that the above solvents. The content of water with respect to the total mass of the developer is preferably less than 50% by mass, more preferably less than 20% by mass, and still more preferably less than 10% by mass, and it is particularly preferable that the developer contains substantially no water.

The content of the organic solvent with respect to the total mass of the organic-based developer is preferably 50% by mass or more and 100% by mass of less, more preferably 80% by mass or more and 100% by mass or less, still more preferably 90% by mass or more and 100% by mass or less, and particularly preferably 95% by mass or more and 100% by mass or less.

### (Additional Steps)

Preferably, the above pattern forming method further includes the step of, after step 3, rinsing with a rinsing solution.

Examples of the rinsing solution used in the rinsing step after the step of developing using the alkali developer include pure water. An appropriate amount of a surfactant may be added to the pure water.

An appropriate amount of a surfactant may be added to the rinsing solution.

No particular limitation is imposed on the rinsing solution used for the rinsing step after the step of developing using the alkali developer so long as the rinsing solution does not dissolve the pattern, and a solution containing a general-purpose organic solvent can be used. Preferably, the rinsing solution used contains at least one organic solvent selected from the group consisting of hydrocarbon-based solvents, ketone-based solvents, ester-based solvents, alcohol-based solvents, amide-based solvents, and ether-based solvents.

No particular limitation is imposed on the method for the rinsing step, and examples thereof include: a method in which the rinsing solution is continuously discharged onto the substrate rotating at a constant speed (a spin coating method); a method in which the substrate is dipped into a bath filled with the rinsing solution for a prescribed time (a dipping method); and a method in which the rinsing solution is sprayed onto the surface of the substrate (a spraying method).

The pattern forming method may further include a heating (post-baking) step after the rinsing step. Through this step, the developer and the rinsing solution remaining between traces of the pattern and inside the pattern are removed by baking. Through this step, the resist pattern is annealed, and the effect of improving surface roughness of the pattern is obtained. The heating step after the rinsing step is performed at generally 40 to 250° C. (preferably 90 to 200° C.) for generally 10 seconds to 3 minutes (preferably 30 seconds to 120 seconds).

The pattern formed may be used as a mask to perform etching treatment on the substrate. Specifically, the pattern formed in step 3 may be used as a mask to process the substrate (or the underlayer film and the substrate) to thereby form a pattern on the substrate.

No particular limitation is imposed on the method for processing the substrate (or the underlayer film and the substrate). It is preferable that the pattern formed in step 3 is used as a mask and the substrate (or the underlayer film and the substrate) is dry-etched to form a pattern on the substrate. The dry etching is preferably oxygen plasma etching.

Preferably, the resist composition and various materials (such as the solvent, the developer, the rinsing solution, a composition for forming an antireflection film, and the composition for forming the topcoat) used in the pattern forming method in the present specification contain no impurities such as metals. The content of the impurities contained in each of these materials is preferably 1 ppm by mass or less, more preferably 10 ppb by mass or less, still more preferably 100 ppt by mass or less, particularly preferably 10 ppt by mass or less, and most preferably 1 ppt by mass or less. No particular limitation is imposed on the lower limit of the content of the impurities, and the content is preferably 0 ppt by mass or more. Examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing impurities such as metals from the above materials include filtration using a filter. The details of the filtration using a filter are described in paragraph [0321] of WO2020/004306A.

Examples of a method for reducing the amount of impurities such as metals contained in the above materials include: a method in which raw materials containing smaller amounts of metals are used as the raw materials forming the above materials; a method in which the raw materials forming the above materials are filtrated through a filter; and a method in which distillation is performed under the condition that contamination is reduced as much as possible, for example, by coating the inside of the device used with Teflon (registered trademark).

Besides the filtration using a filter, an adsorbent may be used to remove impurities. The filtration using a filter and the absorbent may be used in combination. The adsorbent used may be a well-known adsorbent, and examples of the adsorbent that can be used include inorganic-based adsorbents such as silica gel and zeolite and organic-based adsorbents such as activated carbon. To reduce the amount of impurities such as metals contained in the above materials, it is necessary to prevent the metal impurities from mixing during the production process. Whether the metal impurities have been sufficiently removed from the production device can be checked by measuring the content of metal components contained in a washing solution used to clean the production device. The content of the metal components contained in the washing solution after use is preferably 100 ppt (parts per trillion) by mass or less, more preferably 10 ppt by mass or less, and still more preferably 1 ppt by mass or less. No particular limitation is imposed on the lower limit of the content, and the content is preferably 0 ppt by mass or more.

An electroconductive compound may be added to an organic treatment solution such as the rinsing solution in order to prevent failure of chemical solution pipes and various parts (such as filters, O-rings, and tubes) due to electrostatic charges and subsequent electrostatic discharge. No particular limitation is imposed on the electroconductive compound, and examples thereof include methanol. No particular limitation is imposed on the amount of the electroconductive compound added. From the viewpoint of maintaining preferred development characteristics or rinsing characteristics, the amount of the electroconductive compound is preferably 10% by mass or less and more preferably 5% by mass or less. No particular limitation is imposed on the lower limit, and the amount of the electroconductive compound is preferably 0.01% by mass or more.

The chemical solution pipes used may be, for example, SUS (stainless steel) pipes or pipes coated with antistatic-treated polyethylene, antistatic-treated polypropylene, or an antistatic-treated fluorocarbon resin (such as polytetrafluoroethylene or a perfluoroalkoxy resin). Similarly, antistatic-treated polyethylene, antistatic-treated polypropylene, or an antistatic-treated fluorocarbon resin (such as polytetrafluoroethylene or a perfluoroalkoxy resin) may be used for the filters and the O-rings.

### [Method for Producing Electronic Device]

The present specification also relates to a method for producing an electronic device that includes the pattern forming method described above and to an electronic device produced by the production method.

In preferred modes of the electronic device in the present specification, the device is installed in electric and electronic devices (such as household electrical appliances and OA (Office Automation) devices, media-related devices, optical devices, and telecommunication devices).

### EXAMPLES

The present invention will next be described in more detail by way of Examples. Materials, amounts used, ratios, treatment details, treatment procedures, etc. shown in the following Examples can be appropriately changed so long as they do not depart from the gist of the invention. Therefore, the scope of the present invention should not be construed as limited to the following Examples.

### [Components of Resist Composition]

### [Resin A]

Resins A (resins A-1 to A-35) listed in Table 1 are shown below.

The resins A used were synthesized according to a method for synthesizing a resin A-1 described later (Synthesis Example 1).

Table 1 shows the types of repeating units described later, the composition (mol %) of each resin, and the weight average molecular weight (Mw) of each resin, and the dispersity (Mw/Mn) of each resin.

The weight average molecular weight (Mw) and dispersity (Mw/Mn) of each of the resins A-1 to A-35 were measured by GPC (carrier: tetrahydrofuran (THF)) (these are polystyrene-equivalent values). The compositions (mol %) of the resins were measured by ¹³C-NMR (nuclear magnetic resonance).

Table 1 is shown below.

TABLE 1

| | Structure of resin | | | | | | | | | |
|---|---|---|---|---|---|---|---|---|---|---|
| | Repeating unit 1 | | Repeating unit 2 | | Repeating unit 3 | | Repeating unit 4 | | | |
| | | Content | | Content | | Content | | Content | | Mw/ |
| | Type | (mol %) | Type | (mol %) | Type | (mol %) | Type | (mol %) | Mw | Mn |
| Resin A-1 | MB-10 | 50 | MA-16 | 50 | — | — | — | — | 8500 | 1.60 |
| Resin A-2 | MB-15 | 40 | MA-7 | 60 | — | — | — | — | 9000 | 1.70 |
| Resin A-3 | MB-7 | 30 | MB-14 | 10 | MA-6 | 60 | — | — | 7000 | 1.55 |
| Resin A-4 | MB-5 | 50 | MB-12 | 10 | MA-15 | 40 | — | — | 7500 | 1.55 |
| Resin A-5 | MB-3 | 20 | MB-20 | 40 | MA-4 | 40 | — | — | 7000 | 1.60 |
| Resin A-6 | MB-4 | 20 | MB-14 | 30 | MA-2 | 50 | — | — | 6500 | 1.63 |
| Resin A-7 | MB-6 | 30 | MB-19 | 10 | MA-3 | 60 | — | — | 9500 | 1.45 |
| Resin A-8 | MB-9 | 30 | MB-20 | 10 | MA-13 | 60 | — | — | 12000 | 1.65 |
| Resin A-9 | MB-4 | 20 | MB-19 | 20 | MA-2 | 60 | — | — | 6000 | 1.55 |
| Resin A-10 | MB-16 | 30 | MA-17 | 70 | — | — | — | — | 8000 | 1.40 |
| Resin A-11 | MB-4 | 30 | MB-31 | 30 | MA-4 | 40 | — | — | 6500 | 1.65 |
| Resin A-12 | MB-30 | 20 | MA-8 | 80 | — | — | — | — | 5500 | 1.65 |
| Resin A-13 | MB-13 | 50 | MA-10 | 50 | — | — | — | — | 15000 | 1.75 |
| Resin A-14 | MB-8 | 30 | MA-20 | 70 | — | — | — | — | 9000 | 1.60 |
| Resin A-15 | MB-18 | 30 | MB-29 | 30 | MA-14 | 40 | — | — | 8000 | 1.55 |
| Resin A-16 | MB-3 | 30 | MB-20 | 20 | MA-2 | 40 | MA-8 | 10 | 7500 | 1.70 |
| Resin A-17 | MB-1 | 30 | MB-26 | 30 | MA-11 | 40 | — | — | 18000 | 1.80 |
| Resin A-18 | MB-27 | 60 | MA-5 | 40 | — | — | — | — | 7500 | 1.65 |
| Resin A-19 | MB-17 | 30 | MB-24 | 10 | MA-19 | 60 | — | — | 8000 | 1.70 |
| Resin A-20 | MB-11 | 30 | MB-28 | 40 | MA-9 | 30 | — | — | 9500 | 1.80 |
| Resin A-21 | MB-3 | 20 | MB-20 | 10 | MB-32 | 10 | MA-2 | 60 | 10000 | 1.70 |
| Resin A-22 | MB-2 | 60 | MA-1 | 40 | — | — | — | — | 11000 | 1.65 |
| Resin A-23 | MB-21 | 50 | MA-12 | 50 | — | — | — | — | 6500 | 1.60 |
| Resin A-24 | MB-23 | 40 | MA-10 | 60 | — | — | — | — | 8000 | 1.55 |
| Resin A-25 | MB-1 | 20 | MB-19 | 20 | MA-2 | 60 | — | — | 8000 | 1.55 |
| Resin A-26 | MB-25 | 30 | MA-2 | 70 | — | — | — | — | 7500 | 1.60 |
| Resin A-27 | MB-3 | 40 | MA-3 | 60 | — | — | — | — | 9500 | 1.60 |
| Resin A-28 | MB-22 | 40 | MA-4 | 60 | — | — | — | — | 10000 | 1.70 |
| Resin A-29 | MB-3 | 30 | MB-33 | 20 | MA-2 | 50 | — | — | 6600 | 1.63 |
| Resin A-30 | MB-7 | 30 | MB-14 | 10 | MA-18 | 60 | — | — | 8100 | 1.65 |
| Resin A-31 | MB-1 | 20 | MB-19 | 20 | MA-21 | 60 | — | — | 6600 | 1.65 |
| Resin A-32 | MB-17 | 60 | MA-24 | 40 | — | — | — | — | 8200 | 1.71 |
| Resin A-33 | MB-4 | 20 | MB-19 | 20 | MA-23 | 60 | — | — | 6500 | 1.60 |
| Resin A-34 | MB-14 | 30 | MA-22 | 70 | — | — | — | — | 7200 | 1.58 |
| Resin A-35 | MB-19 | 25 | MB-34 | 25 | MA-2 | 50 | — | — | 8400 | 1.59 |

The structures of the repeating units MA-1 to MA-24 and MB-1 to MB-34 listed in Table 1 are shown below.

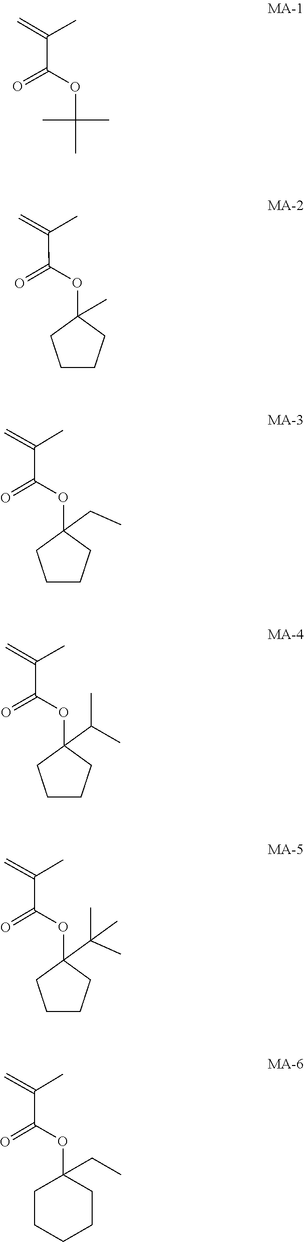

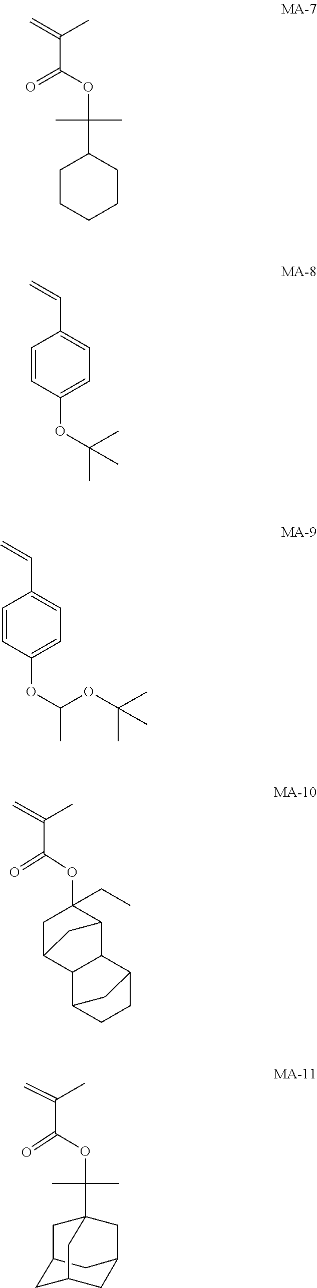

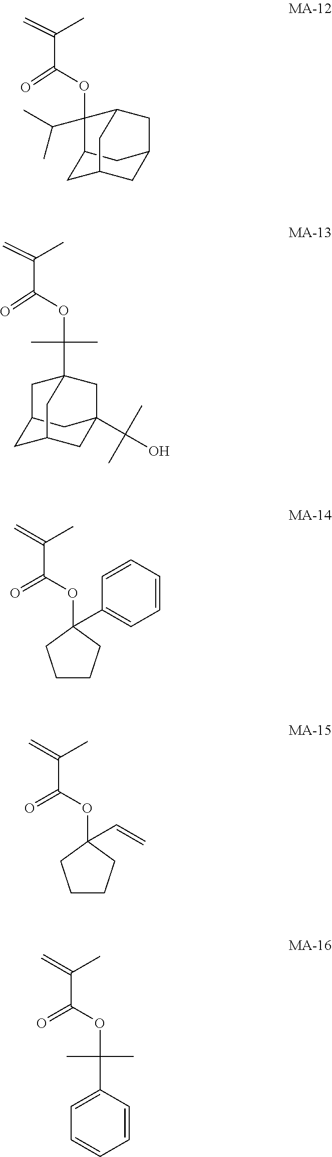

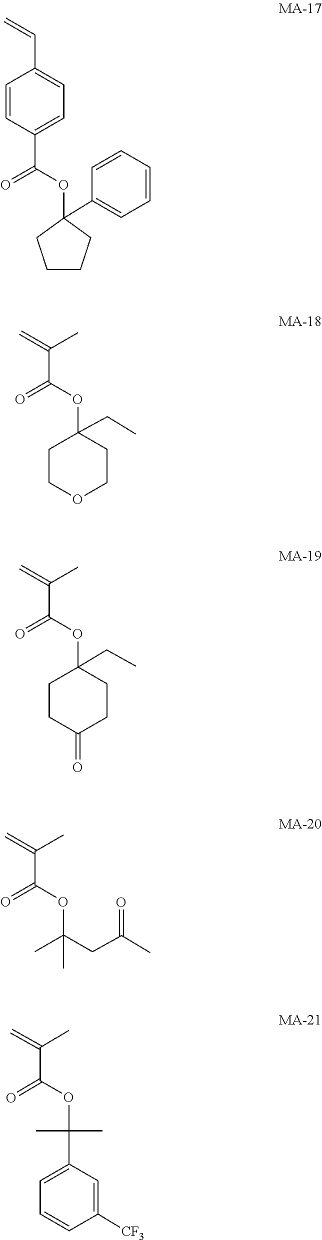

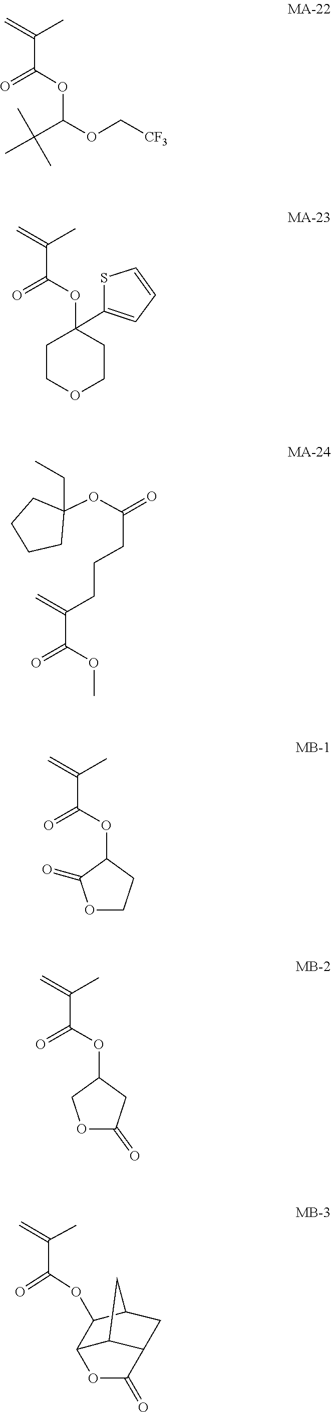

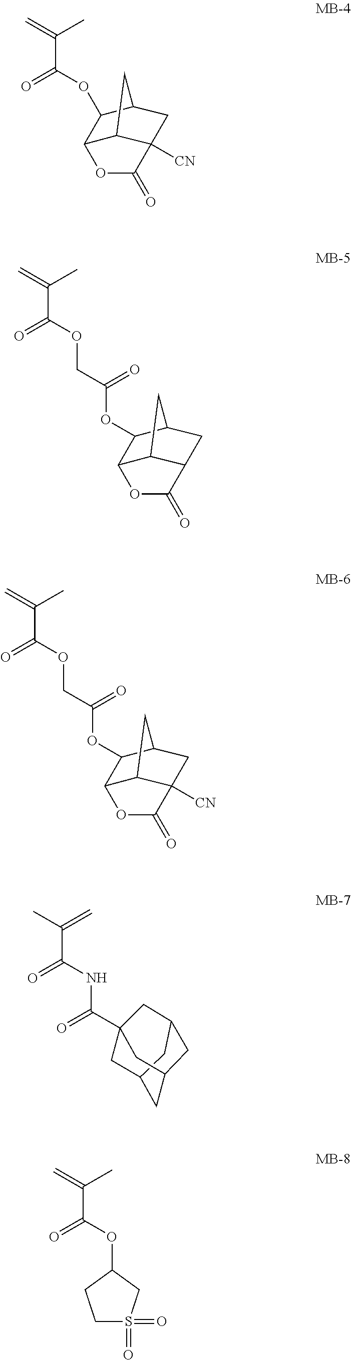

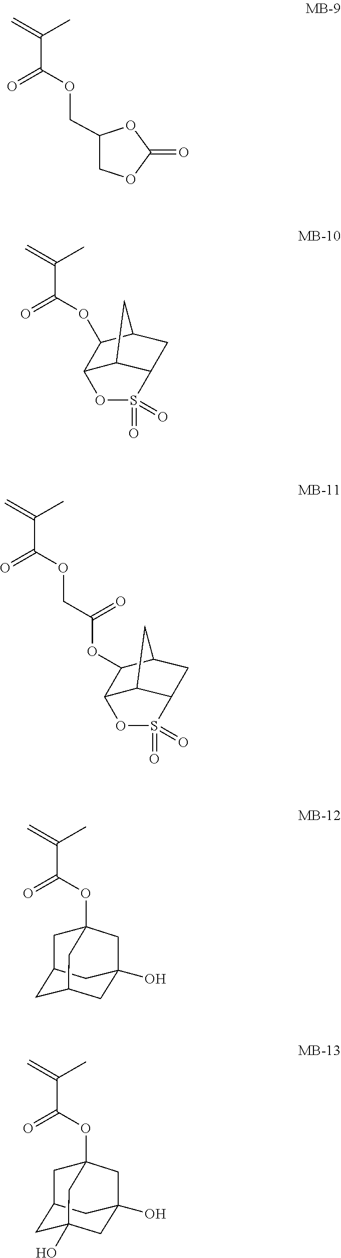

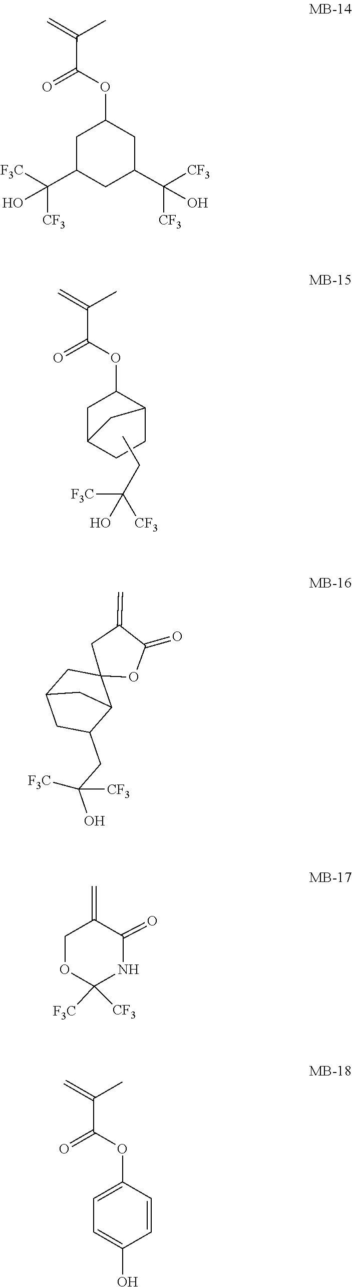

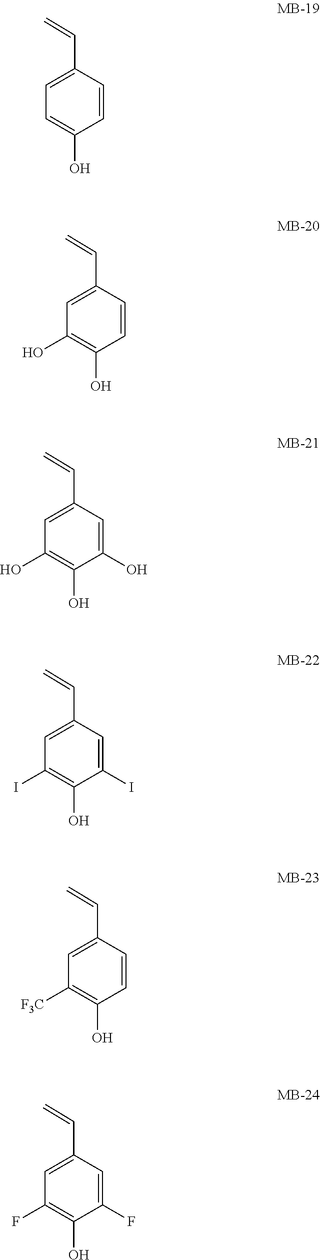

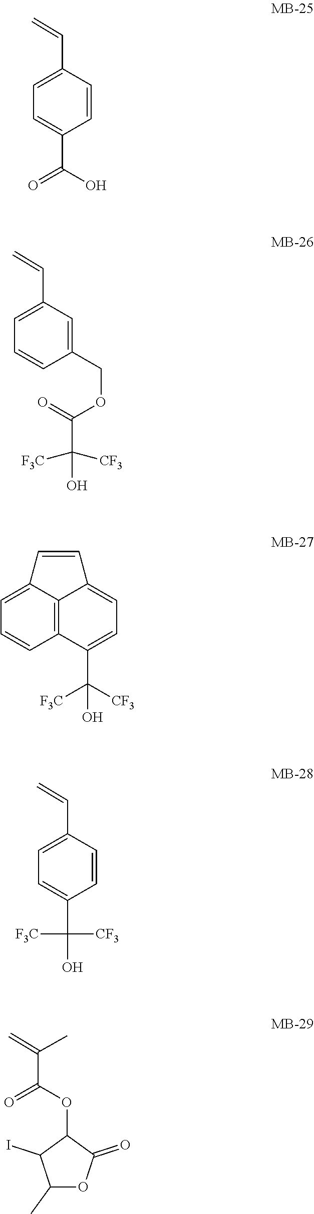

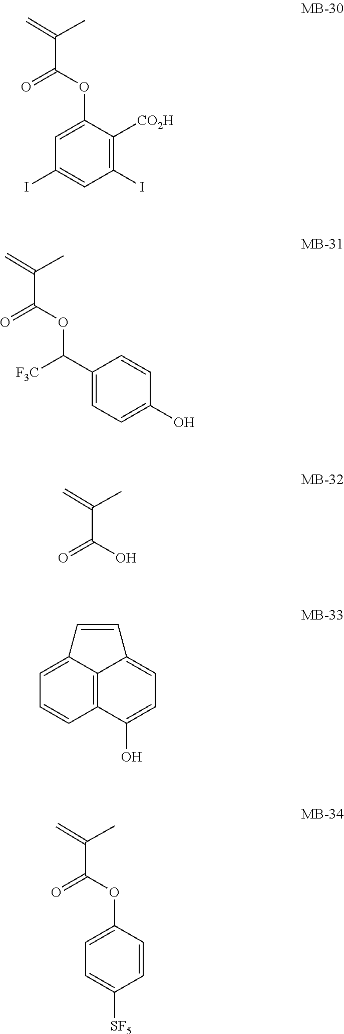

### Synthesis Example 1: Synthesis of Resin A-1

Propylene glycol monomethyl ether acetate (28 g) was heated to 80° C. in a nitrogen flow. While the solution was stirred, a solution mixture of a monomer represented by MA-16 (30 g), a monomer represented by MB-10 (38 g), propylene glycol monomethyl ether acetate (112 g), and dimethyl 2,2′-azobisisobutyrate [V-601 manufactured by FUJIFILM Wako Pure Chemical Corporation] (5.7 g) was added dropwise to the solution over 6 hours to thereby obtain a reaction solution. After completion of the dropwise addition, the reaction solution was further stirred at 80° C. for 2 hours. The resulting reaction solution was allowed to cool, and a large amount of a solvent mixture of heptane and ethyl acetate (heptane: ethyl acetate=9:1, mass ratio) was used to re-precipitate the resin, and the resulting solution was filtered. The solid obtained was vacuum-dried to thereby obtain 58 g of a resin A-1. The weight average molecular weight (Mw: polystyrene-equivalent value) of the obtained resin A-1 determined by GPC (carrier: tetrahydrofuran (THF)) was 8500, and the dispersity (Mw/Mn) was 1.60. The molar ratio of the repeating units measured by ¹³C-NMR (nuclear magnetic resonance) was 50/50.

The other resins (A) used in the Examples were synthesized using the same procedure as above.

### [Compounds B and Comparative Compound]

Compounds B (compounds B-1 to B-23) shown in Table 3 correspond to the compounds described above as the specific examples of the specific onium salt.

The structure of the comparative compound (compound Ba-1) shown in Table 3 is as follows.

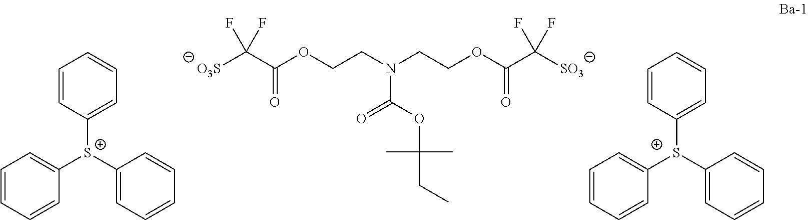

### Synthesis Example 2: Synthesis of Compound B-1

### <Synthesis of Compound B-1-c>

B-1-b (43 g) was dissolved in tetrahydrofuran (70 g), and the mixture was stirred at 0° C. in a nitrogen flow. Then cesium carbonate (15 g) was added to the mixture under stirring. While the resulting solution was stirred, a solution mixture of B-1-a (10 g) and tetrahydrofuran (100 g) was added dropwise at 0° C., and the resulting mixture was stirred at 25° C. for 24 hours. The obtained reaction solution was concentrated. Then ethyl acetate (300 g), hexane (300 g), and a saturated aqueous ammonium chloride solution (500 g) were added, and the organic layer was collected. The organic layer was washed 8 times with distilled water (400 g), concentrated, and subjected to column purification to thereby obtain B-1-c (9 g).

B-1-a used was synthesized by a method described in WO2016/202755A.

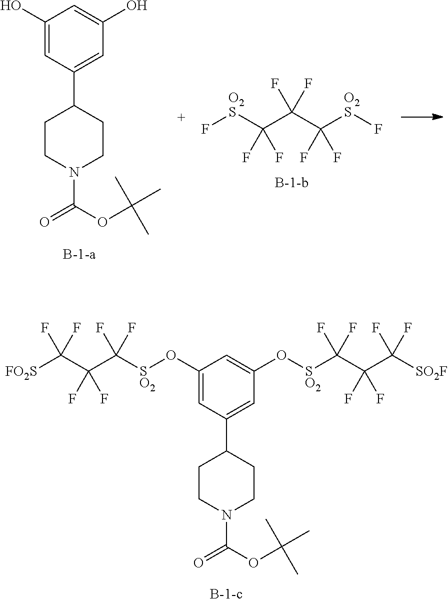

### <Synthesis of Compound B-1-d>

B-1-c (9 g) was dissolved in tetrahydrofuran (100 g), and the mixture was heated to 45° C. in a nitrogen flow. An aqueous solution prepared by dissolving sodium bicarbonate (5.1 g) in distilled water (80 g) was added to the mixture, and the resulting mixture was stirred at 45° C. for 24 hours. Tetrahydrofuran in the reaction solution was removed by evaporation, and the aqueous layer was washed three times with ethyl acetate (40 g). An appropriate amount of distilled water was added to adjust the concentration, and a 10% aqueous solution (94 g) containing B-1-d (9.4 g) was thereby obtained.

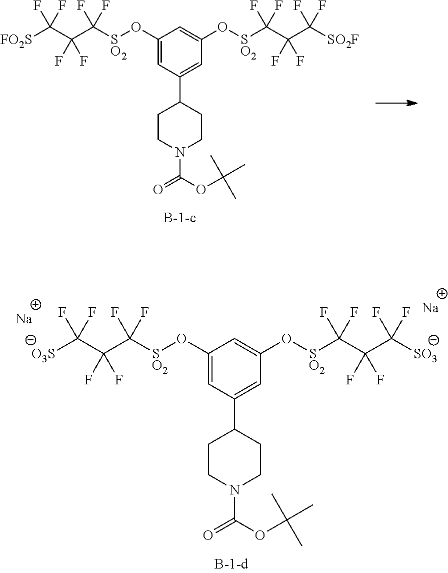

### <Synthesis of Compound B-1>

B-1-e (7.2 g) and methylene chloride (100 g) were added to the above-obtained 10% aqueous solution (94 g) containing B-1-d (9.4 g), and the mixture was stirred at 25° C. for 1 hour. The aqueous layer was removed, and then the organic layer was washed 5 times with distilled water (80 g). The solvent was removed from the organic layer by evaporation to thereby obtain B-1 (14 g).

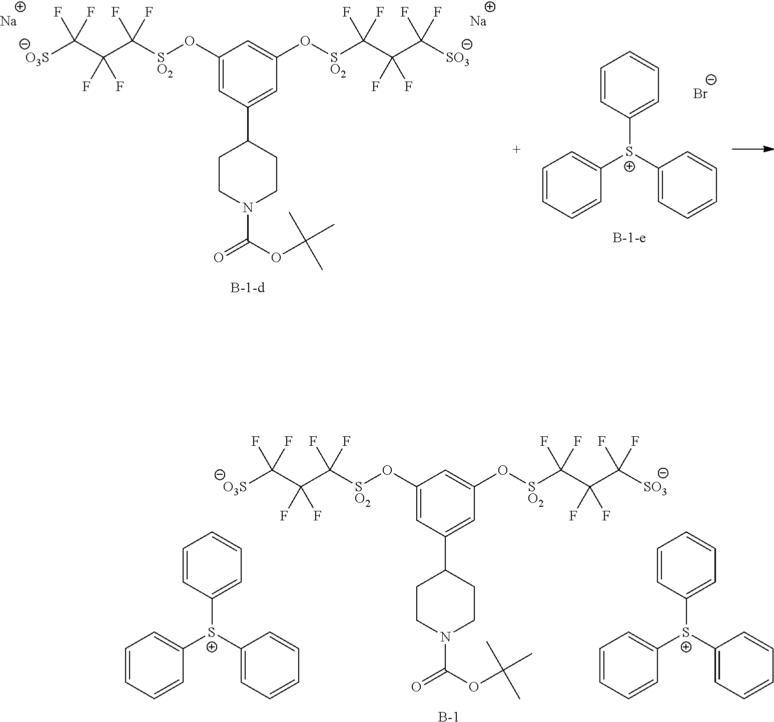

The obtained B-1 was subjected to ¹H-NMR measurement.

¹H NMR (400 MHz, DMSO-d6) δ 1.42 (s, 9H), 1.65-1.92 (m, 4H), 2.73-2.75 (m, 1H), 7.40-7.60 (m, 4H), 7.50-7.90 (m, 33H)

### <Synthesis of Compounds B-2 to B-23>

The compounds B-2 to B-23 were synthesized according to the above-described method for synthesizing the compound B-1.

The compounds B-13, B-14, and B-17 correspond to compounds in which the structures corresponding to “X₁⁻ and X2⁻” in formula (1) above are each *—SO₂—N⁻—Y.

The value of the acid dissociation constant pKa of the carboxylic acid group computed based on a compound in which the group corresponding to Y in the compounds B-13 and B-14 is applied to the formula (X) described above (this compound corresponds to the following compound) is 3.28.

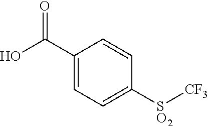 [SMILES: O=C(O)c1ccc(S(=O)(=O)C(F)(F)F)cc1]

The value of the acid dissociation constant pKa of the carboxylic acid group computed based on a compound in which the group corresponding to Y in the compound B-17 is applied to the formula (X) described above (this compound corresponds to the following compound) is 3.27.

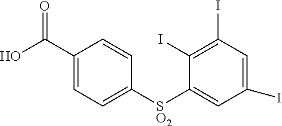 [SMILES: O=C(O)c1ccc(S(=O)(=O)c2cc(I)cc(I)c2I)cc1]

### [Photoacid Generators C]

Photoacid generators C (compounds C-1 to C-32) listed in Table 3 correspond to the compounds described above as the specific examples of the photoacid generator (C).

### [Acid Diffusion Control Agents]

### <Photodegradable Quenchers D]

The structures of photodegradable quenchers D (compounds D-1 to D-21) listed in Table 3 are shown below.

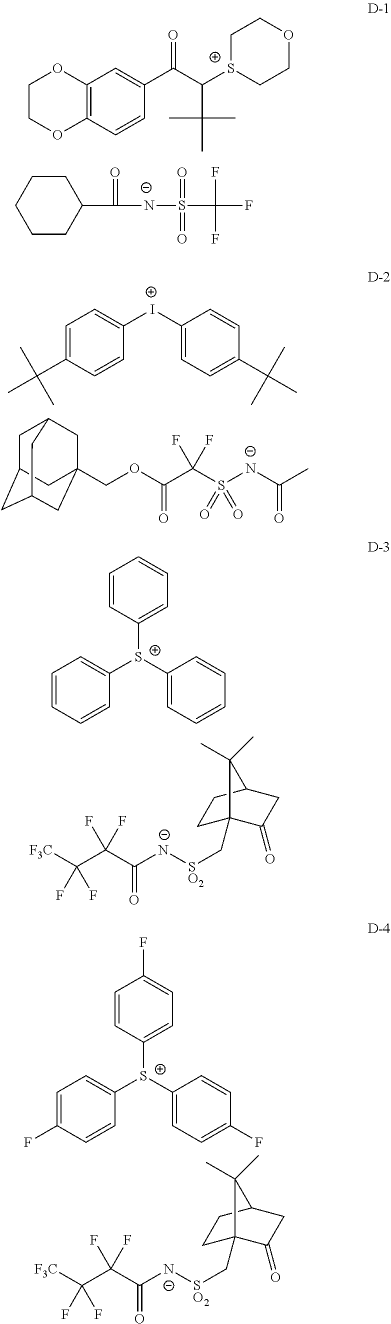

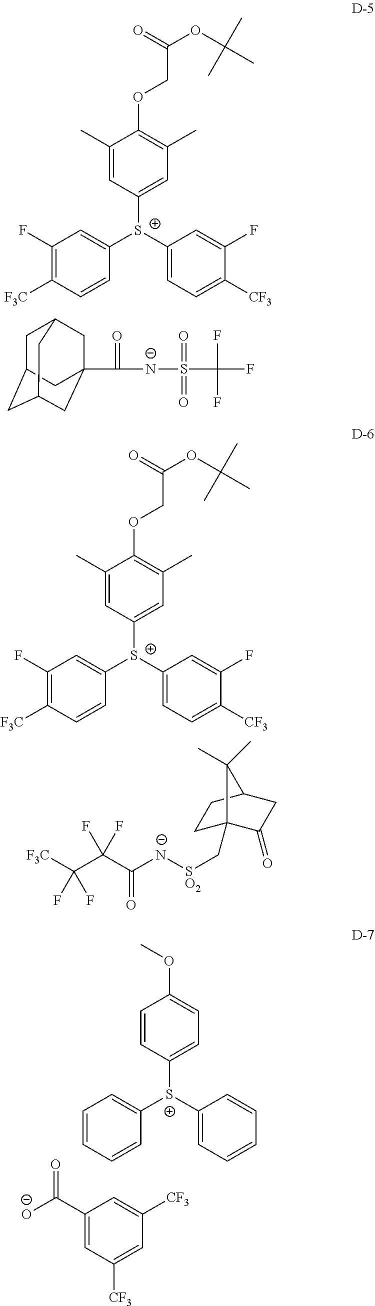 [SMILES: Cc1cc([S+](c2ccc(C(F)(F)F)c(F)c2)c2ccc(C(F)(F)F)c(F)c2)cc(C)c1OCC(=O)OC(C)(C)C ; O=C([N-]S(=O)(=O)C(F)(F)F)C12CC3CC(CC(C3)C1)C2 ; Cc1cc([S+](c2ccc(C(F)(F)F)c(F)c2)c2ccc(C(F)(F)F)c(F)c2)cc(C)c1OCC(=O)OC(C)(C)C ; CC1(C)C2CCC1(CS(=O)(=O)[N-]C(=O)C(F)(F)C(F)(F)C(F)(F)F)C(=O)C2 ; COc1ccc([S+](c2ccccc2)c2ccccc2)cc1 ; O=C([O-])c1cc(C(F)(F)F)cc(C(F)(F)F)c1]

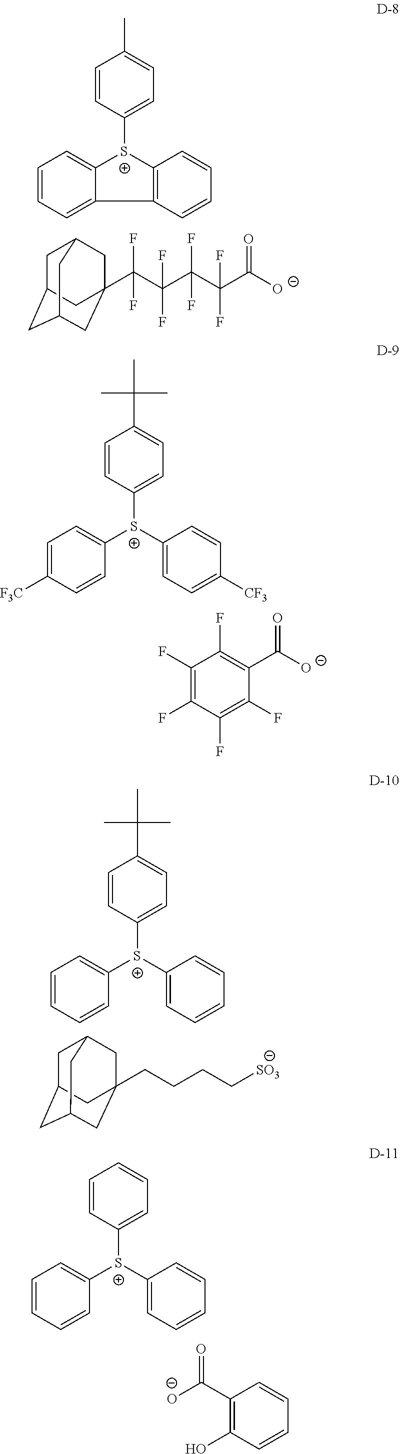

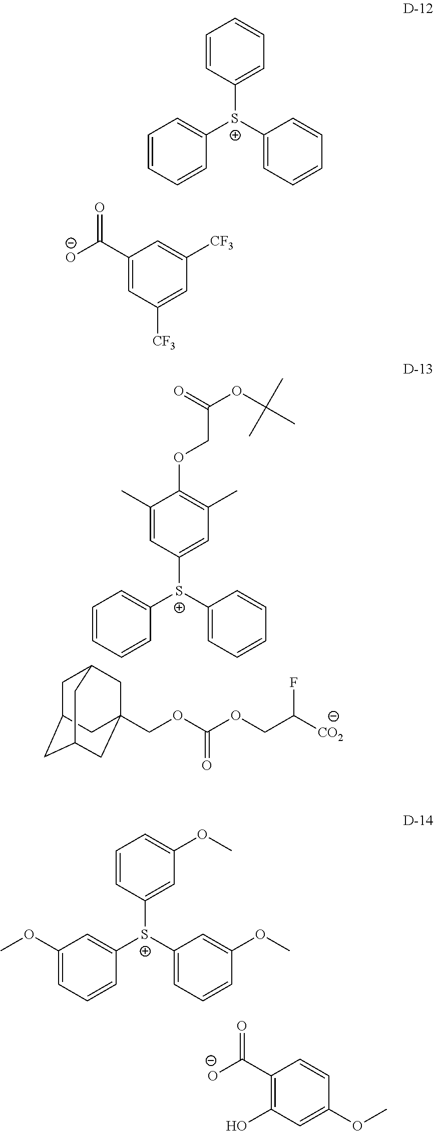

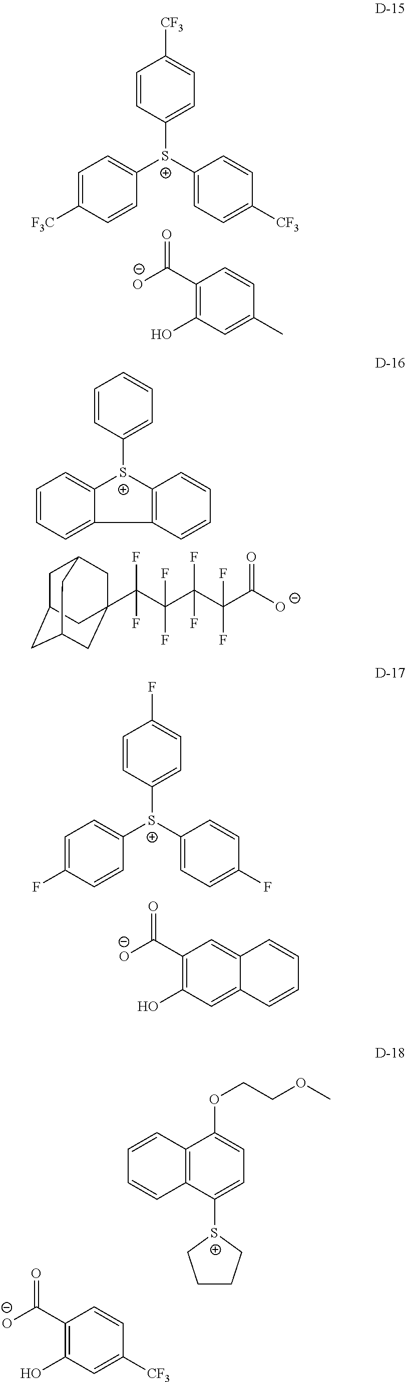

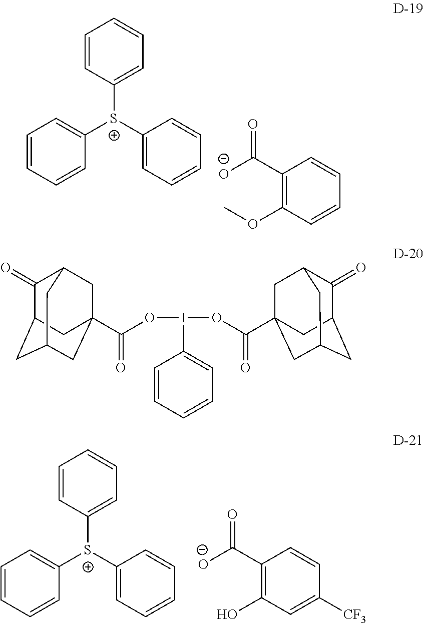 [SMILES: c1ccc([S+](c2ccccc2)c2ccccc2)cc1 ; COc1ccccc1C(=O)[O-] ; O=C1C2CC3CC1CC(C(=O)OI(OC(=O)C14CC5CC(C1)C(=O)C(C5)C4)c1ccccc1)(C3)C2 ; c1ccc([S+](c2ccccc2)c2ccccc2)cc1 ; O=C([O-])c1ccc(C(F)(F)F)cc1O]

### <Acid Diffusion Control Agents G>

The structures of acid diffusion control agents G (compounds G-1 to G-5) listed in Table 3 are shown below.

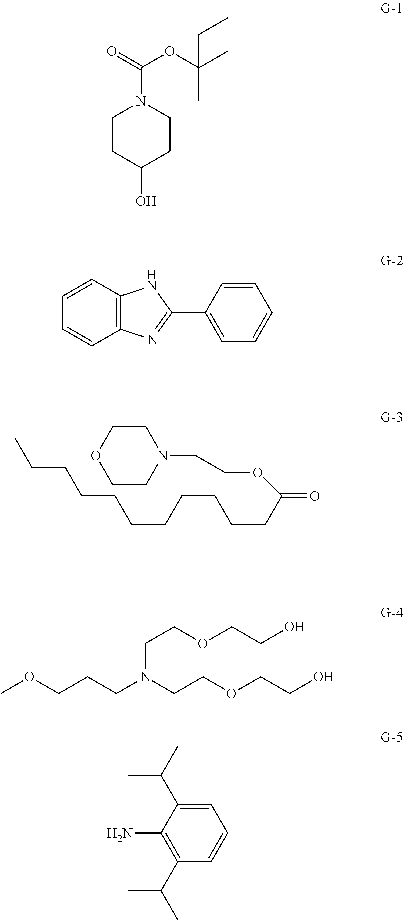 [SMILES: CCC(C)(C)OC(=O)N1CCC(O)CC1 ; c1ccc(-c2nc3ccccc3[nH]2)cc1 ; CCCCCCCCCCCC(=O)OCCN1CCOCC1 ; COCCCN(CCOCCO)CCOCCO ; CC(C)c1cccc(C(C)C)c1N]

### [Resins I]

Resins I (resins I-1 to I-8) listed in Table 3 are as follows.

The resins I-1 to I-8 used were synthesized according to the above-described method for synthesizing the resin A-1 (Synthesis Example 1). The compositional ratios of the repeating units described later (their mass % ratios: in the order from left to right ), their weight average molecular weights (Mw), and their dispersities (Mw/Mn) are shown in Table 2.

The weight average molecular weight (Mw) and dispersity (Mw/Mn) of each of the resins I-1 to I-8 were measured by GPC (carrier: tetrahydrofuran (THF)) (polystyrene-equivalent values). The compositional ratios (mass % ratios) of each resin were measured by ¹³C-NMR (nuclear magnetic resonance).

TABLE 2

| | Mass ratio of repeating unit | | | | Mw | Mw/Mn |
|---|---|---|---|---|---|---|
| Resin I-1 | 50 | 45 | 5 | — | 6500 | 1.52 |
| Resin I-2 | 50 | 50 | — | — | 25000 | 1.65 |
| Resin I-3 | 30 | 65 | 5 | — | 22000 | 1.55 |
| Resin I-4 | 40 | 40 | 20 | — | 12000 | 1.68 |
| Resin I-5 | 40 | 50 | 5 | 5 | 5500 | 1.49 |
| Resin I-6 | 90 | 8 | 2 | — | 12000 | 1.63 |
| Resin I-7 | 20 | 30 | 40 | 10 | 13000 | 1.55 |
| Resin I-8 | 50 | 10 | 40 | — | 9000 | 1.51 |

The structural formulas of the resins I-1 to I-8 listed in Table 2 are shown below.

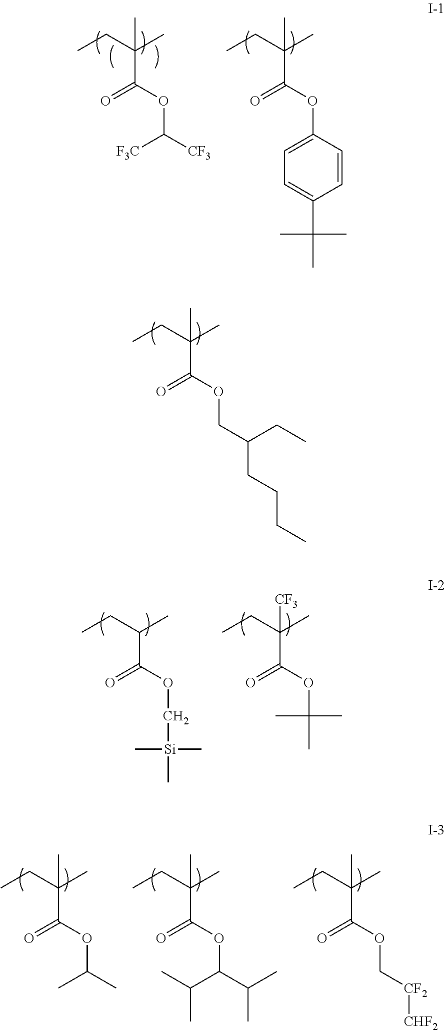

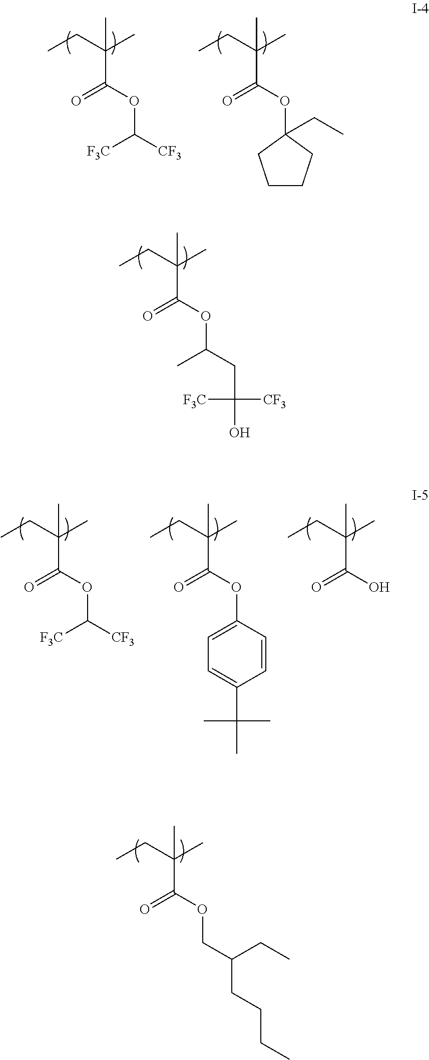

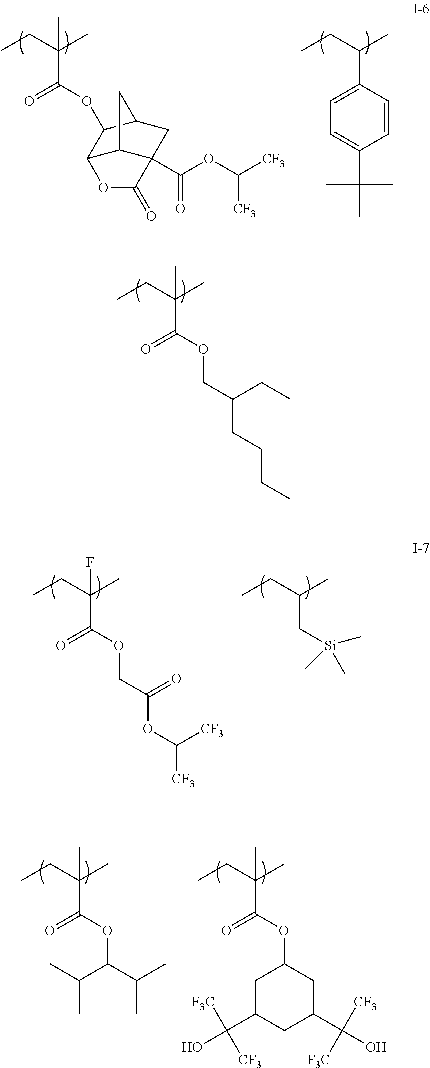

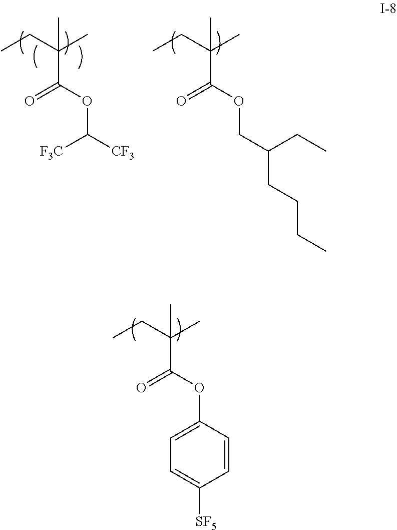

### [Surfactants]

Surfactants listed in Table 3 are as follows.
H-1: MEGAFACE F176 (fluorine-based surfactant manufactured by DIC Corporation)
H-2: MEGAFACE R08 (fluorine- and silicon-based surfactant manufactured by DIC Corporation)
H-3: PF656 (fluorine-based surfactant manufactured by OMNOVA)

### [Solvents]

Solvents listed in Table 3 are as follows.
F-1: Propylene glycol monomethyl ether acetate (PGMEA)
F-2: Propylene glycol monomethyl ether (PGME)
F-3: Propylene glycol monoethyl ether (PGEE)
F-4: Cyclohexanone
F-5: Cyclopentanone
F-6: 2-Heptanone
F-7: Ethyl lactate
F-8: γ-Butyrolactone
F-9: Propylene carbonate

### [Preparation of Resist Compositions]

Components shown in Table 3 were mixed such that the solid concentration was 2.0% by mass. Next, the obtained solution mixtures were independently filtered, i.e., caused to pass through a polyethylene-made filter with a pore size of 50 nm, then through a nylon-made filter with a pore size of 10 nm, and finally through a polyethylene-made filter with a pore size of 5 nm, to thereby prepare resist compositions (Re-1 to Re-45 and Re′-1).

The solids mean all the components other than the solvent. The obtained resist compositions were used in Examples and Comparative Examples.

In the tables, the “Content” columns show the contents (% by mass) of components with respect to the total mass of the solids in the resist compositions.

TABLE 3

| | Resist composition (content: solid content with respect to total mass of solids (mass %) | | | | | | | | | | | |
|---|---|---|---|---|---|---|---|---|---|---|---|---|
| | | | Compound B and | | | | | | | | | |
| | | | comparative | | Photoacid generator | | Photodegradable | | Acid diffusion | | | |
| | Resin A | | compound | | C | | quencher D | | control agent G | | Resin 1 | |
| Table 3 | | Content | | Content | | Content | | Content | | Content | | Content |
| (No. 1) | Type | (mass %) | Type | (mass %) | Type | (mass %) | Type | (mass %) | Type | (mass %) | Type | (mass %) |
| Re-1 | A-1 | 62.0 | B-1 | 32.0 | C-8 | 3.0 | D-21 | 3.0 | — | — | — | — |
| Re-2 | A-2 | 58.0 | B-2 | 38.0 | C-1 | 2.0 | D-1 | 2.0 | — | — | — | — |
| Re-3 | A-3 | 48.0 | B-3 | 44.0 | C-2 | 4.0 | D-2 | 4.0 | — | — | — | — |
| Re-4 | A-4 | 50.0 | B-4 | 40.0 | C-3 | 5.0 | D-3 | 5.0 | — | — | — | — |
| Re-5 | A-5 | 58.0 | B-5 | 38.0 | C-4 | 2.0 | D-4 | 2.0 | — | — | — | — |
| Re-6 | A-6 | 65.0 | B-6 | 23.0 | C-5 | 6.0 | D-5 | 6.0 | — | — | — | — |
| Re-7 | A-7 | 42.0 | B-7 | 33.9 | C-6 | 12.0 | D-6 | 12.0 | — | — | — | — |
| Re-8 | A-8 | 31.0 | B-8 | 55.0 | C-7 | 7.0 | D-7 | 7.0 | — | — | — | — |
| Re-9 | A-9 | 50.0 | B-9 | 35.0 | C-8 | 8.0 | D-8 | 7.0 | — | — | — | — |
| Re-10 | A-10 | 50.0 | B-10 | 40.0 | C-9 | 5.0 | D-9 | 5.0 | — | — | — | — |
| Re-11 | A-11 | 55.0 | B-11 | 30.0 | C-10 | 8.0 | D-10 | 7.0 | — | — | — | — |
| Re-12 | A-12 | 90.0 | B-12 | 6.0 | C-11 | 2.0 | D-11 | 2.0 | — | — | — | — |
| Re-13 | A-13 | 52.0 | B-13 | 30.0 | C-12 | 8.0 | D-12 | 8.0 | — | — | 1-1 | 2.0 |
| Re-14 | A-14 | 63.0 | B-14 | 20.0 | C-13 | 7.0 | D-13 | 7.0 | — | — | 1-2 | 2.9 |
| Re-15 | A-15 | 65.0 | B-15 | 24.0 | C-14 | 4.0 | D-14 | 4.0 | G-1 | 3.0 | — | — |
| Re-16 | A-16 | 80.0 | B-16 | 11.0 | C-15 | 3.0 | D-15 | 1.0 | G-2 | 5.0 | — | — |
| Re-17 | A-17 | 63.5 | B-17 | 24.0 | C-16 | 6.5 | D-16 | 2.0 | — | — | 1-3 | 4.0 |
| Re-18 | A-18 | 87.0 | B-18 | 8.0 | C-17 | 2.0 | D-37 | 3.0 | G-3 | 2.0 | — | — |
| Re-19 | A-19 | 65.5 | B-19 | 20.0 | C-18 | 6.5 | D-18 | 6.0 | — | — | 1-4 | 2.0 |
| Re-20 | A-20 | 68.0 | B-20 | 23.0 | C-19 | 2.0 | D-19 | 2.0 | G-4 | 5.0 | — | — |
| Re-21 | A-21 | 55.0 | B-21 | 37.0 | C-20 | 4.0 | D-20 | 2.0 | G-5 | 2.0 | — | — |
| Re-22 | A-22 | 53.0 | B-22 | 30.0 | C-21 | 4.0 | D-21 | 4.0 | — | — | 1-5 | 8.9 |
| Re-23 | A-23 | 80.0 | B-23 | 12.0 | C-22 | 5.0 | — | — | — | — | 1-6 | 3.0 |
| Re-24 | A-24 | 82.0 | B-17 | 8.0 | C-23 | 2.0 | — | — | G-1 | 3.0 | 1-7 | 5.0 |

| | | | Solvent | |
|---|---|---|---|---|
| | Resist composition (content: solid content with respect to total mass of solids (mass %) | | | Mixing |
| | Surfactant | | | ratio |
| Table 3 | | Content | | (mass |
| (No. 1) | Type | (mass %) | Type | ratio) |
| Re-1 | — | — | F-1/F-2 | 80/20 |
| Re-2 | — | — | F-1/F-5 | 85/15 |
| Re-3 | — | — | F-1/F-2 | 80/20 |
| Re-4 | — | — | F-1/F-2/F-8 | 40/20/40 |
| Re-5 | — | — | F-1/F-2 | 80/20 |
| Re-6 | — | — | F-1/F-9 | 85/15 |
| Re-7 | H-1 | 0.1 | F-1/F-7 | 90/10 |
| Re-8 | — | — | F-1/F-2 | 80/20 |
| Re-9 | — | — | F-1/F-2 | 80/20 |
| Re-10 | — | — | F-1/F-2/F-6 | 70/20/10 |
| Re-11 | — | — | F-1/F-2 | 80/20 |
| Re-12 | — | — | F-1/F-4 | 80/20 |
| Re-13 | — | — | F-1/F-2 | 80/20 |
| Re-14 | H-2 | 0.1 | F-4 | 100 |
| Re-15 | — | — | F-1/F-2/F-8 | 85/12/3 |
| Re-16 | — | — | F-1/F-5 | 80/20 |
| Re-17 | — | — | F-1/F-2 | 75/25 |
| Re-18 | — | — | F-1/F-2/F-8 | 34/33/33 |
| Re-19 | — | — | F-1/F-2 | 80/20 |
| Re-20 | — | — | F-1/F-9 | 80/20 |
| Re-21 | — | — | F-1/F-2/F-8 | 85/12/3 |
| Re-22 | H-3 | 0.1 | F-1/F-2 | 85/15 |
| Re-23 | — | — | F-1/F-2 | 80/20 |
| Re-24 | — | — | F-1/F-2/F-6 | 80/15/5 |

TABLE 4

| | Resist composition (content: solid content with respect to total mass of solids (mass %)) | | | | | | | | | | | |
|---|---|---|---|---|---|---|---|---|---|---|---|---|
| | | | Compound B and | | | | | | | | | |
| | | | comparative | | | | Photodegradable | | Acid diffusion | | | |
| | Resin A | | compound | | Photoacid generator C | | quencher D | | control agent G | | Resin 1 | |
| Table 3 | | Content | | Content | | Content | | Content | | Content | | Content |
| (No. 2) | Type | (mass %) | Type | (mass %) | Type | (mass %) | Type | (mass %) | Type | (mass %) | Type | (mass %) |
| Re-25 | A-25 | 70.0 | B-16 | 18.0 | C-24 | 8.0 | — | — | — | — | 1-8 | 4.0 |
| Re-26 | A-26 | 65.0 | B-15 | 25.0 | C-25 | 10.0 | — | — | — | — | — | — |
| Re-27 | A-27 | 55.0 | B-14 | 27.0 | C-26 | 15.0 | D-8 | 3.0 | — | — | — | — |
| Re-28 | A-28 | 45.0 | B-13 | 35.0 | C-27 | 15.9 | D-9 | 4.0 | — | — | — | — |
| Re-29 | A-29 | 40.0 | B-12 | 45,0 | C-28 | 5.0 | D-10 | 3.1 | — | — | 1-5 | 8.9 |
| Re-30 | A-30 | 75.0 | B-11 | 12.0 | C-29 | 5.0 | D-11 | 5.0 | — | — | 1-6 | 3.0 |
| Re-31 | A-31 | 60.1 | B-10 | 15.0 | C-30 | 9.9 | D-12 | 9.9 | — | — | 1-7 | 5.0 |
| Re-32 | A-32 | 61.0 | B-9 | 15.0 | C-31 | 10.0 | D-13 | 30.0 | — | — | 1-8 | 4.0 |
| Re-33 | A-33 | 70.0 | B-8 | 25.0 | C-32 | 5.0 | — | — | — | — | — | — |
| Re-34 | A-34 | 75.0 | B-7 | 22.0 | — | — | — | — | G-1 | 3.0 | — | — |
| Re-35 | A-35 | 60.0 | B-6 | 40.0 | — | — | — | — | — | — | — | — |
| Re-36 | A-1 | 65.0 | B-5 | 31.0 | — | — | D-7 | 2.0 | — | — | 1-1 | 2.0 |
| Re-37 | A-2 | 67.0 | B-4 | 30.0 | — | — | D-1 | 3.0 | — | — | — | — |
| Re-38 | A-3 | 50.0 | B-3 | 40.0 | C-22 | 5.0 | D-2 | 5.0 | — | — | — | — |
| Re-39 | A-4 | 50.0 | B-2 | 40.0 | C-23 | 5.0 | D-3 | 5.0 | — | — | — | — |
| Re-40 | A-5 | 48.0 | B-1 | 44.0 | C-24 | 4.0 | D-4 | 4.0 | — | — | — | — |
| Re-41 | A-6 | 60.0 | B-20 | 27.0 | C-25 | 7.0 | D-5 | 3.0 | — | — | 1-6 | 3.0 |
| Re-42 | A-6 | 60.0 | B-3 | 14.0 | C-25 | 5.0 | D.5 | 5.0 | — | — | 1-6 | 3.0 |
| | | | B-4 | 13.0 | | | | | — | — | — | — |
| Re-43 | A-6 | 60.0 | B-3 | 14.0 | C-25 | 5.0 | D-5 | 5.0 | — | — | 1-6 | 3.0 |
| | | | Ba-1 | 13.0 | | | | | — | — | — | — |
| Re-44 | A-6 | 50.0 | B-20 | 27.0 | C-25 | 5.0 | D-5 | 10.0 | — | — | 1-6 | 3.0 |
| | | | | | C-23 | 5.0 | | | — | — | — | — |
| Re-45 | A-6 | 50.0 | B-20 | 27.0 | C-25 | 10.0 | D-3 | 5.0 | — | — | 1-6 | 3.0 |
| | | | | | | | D-11 | 5.0 | — | — | — | — |
| CRe-1 | A-1 | 65.0 | Ba-1 | 29.0 | C-8 | 3.0 | D-21 | 3.0 | — | — | — | — |

| | | | Solvent | |
|---|---|---|---|---|
| | Resist composition (content: solid content with respect to total mass of solids (mass9%)) | | | Mixing |
| | Surfactant | | | ratio |
| Table 3 | | Content | | (mass |
| (No. 2) | Type | (mass %) | Type | ratio) |
| Re-25 | — | — | F-1/F-2 | 90/10 |
| Re-26 | — | — | F-1/F-4 | 80/20 |
| Re-27 | — | — | F-1/F-2 | 80/20 |
| Re-28 | H-3 | 0.1 | F-4 | 100 |
| Re-29 | — | — | F-1/F-3 | 85/15 |
| Re-30 | — | — | F-1/F-5 | 80/20 |
| Re-31 | H-1 | 0.1 | F-1/F-2 | 75/25 |
| Re-32 | — | — | F-3/F-2/F-8 | 40/20/40 |
| Re-33 | — | — | F-1/F-2 | 80/20 |
| Re-34 | — | — | F-1/F-9 | 80/20 |
| Re-35 | — | — | F-1/F-7 | 80/20 |
| Re-36 | — | — | F-1/F-2 | 85/15 |
| Re-37 | — | — | F-1/F-2 | 90/10 |
| Re-38 | — | — | F-1/F-2/F-6 | 60/20/20 |
| Re-39 | — | — | F-1/F-2 | 90/10 |
| Re-40 | — | — | F-1/F-2 | 80/20 |
| Re-41 | — | — | F-1/F-2 | 80/20 |
| Re-42 | — | — | F-1/F-2 | 80/20 |
| Re-43 | — | — | F-1/F-2 | 80/20 |
| Re-44 | — | — | F-1/F-2 | 80/20 |
| Re-45 | — | — | F-1/F-2 | 80/20 |
| CRe-1 | — | — | F-1/F-2 | 80/20 |

### [Pattern Formation and Evaluation]

[Pattern Formation by EUV Exposure and Development with Organic Solvent and Evaluation]

### <Pattern Formation>

A composition AL412 (manufactured by Brewer Science) for the formation of an underlayer film was applied to a silicon wafer with a diameter of 12 inches and baked at 205° C. for 60 seconds to form an underlayer film having a film thickness of 20 nm. A resist composition shown in Table 4 was applied to the underlayer film and baked at 100° C. for 60 seconds to form a resist film having a film thickness of 30 nm.

An EUV exposure device (Micro Exposure Tool manufactured by Exitech, NA: 0.3, Quadrupole, outer sigma: 0.68, inner sigma: 0.36) was used to subject the obtained silicon wafer having the resist film to pattern irradiation such that the average line width of the pattern was 14 nm. The reticle used was a mask with a line size of 14 nm and a line:space ratio of 1:1.

The resist film exposed to light was baked at 90° C. for 60 seconds, developed with n-butyl acetate for 30 seconds, and spin-dried to thereby obtain a negative-type pattern.

Two resist compositions, i.e., a resist composition immediately after its preparation and a resist composition stored in a thermostatic oven at 35° C. for 6 months after preparation, were used.

### <Evaluation>

(Stability of Pattern Shape after Storage (Change in Pattern Shape))

The cross-sectional shapes of the obtained patterns were observed using a critical dimension scanning electron microscope (SEM S-9380II manufactured by Hitachi, Ltd.). For the resist pattern formed using the resist composition immediately after preparation, the pattern line width Lb of the resist pattern at the bottom and the pattern line width La of the resist pattern at the top were measured. For the resist pattern formed using the resist composition stored in the thermostatic oven at 35° C. for 6 months after preparation, the pattern line width Ld of the resist pattern at the bottom and the pattern line width Lc of the resist pattern at the top were measured.

The value (absolute value) |(Ld/Lc)−(Lb/La)| was used as an indicator of the amount of change in pattern shape over time, and the change in pattern shape was evaluated according to the following criteria. “A” is the best, and “E” is the worst. Practically, ratings higher than or equal to “D” are preferred.

### <<Evaluation Criteria>>

$$A : 0 \leq \vert ( Ld / Lc ) - ( Lb / La ) \vert < 0.01$$

$$B : 0.01 \leq \vert ( Ld / Lc ) - ( Lb / La ) \vert < 0.02$$

$$C : 0.02 \leq \vert ( Ld / Lc ) - ( Lb / La ) \vert < 0.03$$

$$D : 0.03 \leq \vert ( Ld / Lc ) - ( Lb / La ) \vert < 0.04$$

$$E : 0.04 \leq \vert ( Ld / Lc ) - ( Lb / La ) \vert$$

The results are shown in Table 4.

|(Ld/Lc)−(Lb/La)| represents the absolute value of (Ld/Lc)−(Lb/La).

TABLE 5

| | Resist | [Evaluation item] Stability |
|---|---|---|
| Table 4 | composition | of pattern shape over time |
| Example 1-1 | Re-1 | C |
| Example 1-2 | Re-2 | B |
| Example 1-3 | Re-3 | C |
| Example 1-4 | Re-4 | C |
| Example 1-5 | Re-5 | A |
| Example 1-6 | Re-6 | C |
| Example 1-7 | Re-7 | B |
| Example 1-8 | Re-8 | B |
| Example 1-9 | Re-9 | B |
| Example 1-10 | Re-10 | C |
| Example 1-11 | Re-11 | C |
| Example 1-12 | Re-12 | D |
| Example 1-13 | Re-13 | D |
| Example 1-14 | Re-14 | C |
| Example 1-15 | Re-15 | C |
| Example 1-16 | Re-16 | A |
| Example 1-17 | Re-17 | C |
| Example 1-18 | Re-18 | C |
| Example 1-19 | Re-19 | C |
| Example 1-20 | Re-20 | D |
| Example 1-21 | Re-21 | B |
| Example 1-22 | Re-22 | D |
| Example 1-23 | Re-23 | B |
| Example 1-24 | Re-24 | B |
| Example 1-25 | Re-25 | A |
| Example 1-26 | Re-26 | D |
| Example 1-27 | Re-27 | C |
| Example 1-28 | Re-28 | C |
| Example 1-29 | Re-29 | C |
| Example 1-30 | Re-30 | D |
| Example 1-31 | Re-31 | B |
| Example 1-32 | Re-32 | C |
| Example 1-33 | Re-33 | B |
| Example 1-34 | Re-34 | C |
| Example 1-35 | Re-35 | B |
| Example 1-36 | Re-36 | B |
| Example 1-37 | Re-37 | C |
| Example 1-38 | Re-38 | C |
| Example 1-39 | Re-39 | B |
| Example 1-40 | Re-40 | B |
| Example 1-41 | Re-41 | D |
| Example 1-42 | Re-42 | C |
| Example 1-43 | Re-43 | C |
| Example 1-44 | Re-44 | D |
| Example 1-45 | Re-45 | D |
| Comparative Example 1-1 | CRe-1 | E |

As is clear from the results shown in Table 4, even when the resist compositions of the invention stored for a long time were used for pattern formation (development with the organic solvent), the shape profiles of the patterns formed could be maintained (i.e., the shape profiles of the patterns formed were comparable to those of the patterns formed using the resist compositions immediately after their preparation).

As can be seen from the comparison among the Examples, when a resist composition satisfies at least one (preferable two or more, more preferably three or more, and still more preferably all four) of the following requirements Y1 to Y4, the shape profile of the pattern formed using the resist composition can be better maintained.
Requirement Y1: The group represented by A in the compound (specific onium salt) represented by formula (1), bonded to the nitrogen atom contained in W, and dissociable under the action of acid or light is the group represented by formula (3).
Requirement Y2: At least one of the organic cations represented by M₁⁺ and M₂⁺ in the compound (specific onium salt) represented by formula (1) has a halogen atom.
Requirement Y3: The structures of moieties corresponding to the “moiety represented by -L₁-Rf₁—X₁⁻” and the “moiety represented by -L₂-Rf₂—X₂⁻” in the compound (specific onium salt) represented by formula (1) are each the structure represented by formula (F1) or formula (F2).
Requirement Y4: The acid-decomposable resin (the resin (A)) has a repeating unit having a phenolic hydroxy group.

However, with the resist composition in the Comparative Example, the desired results were not obtained.

[Pattern Formation by EUV Exposure and Development with Alkali Aqueous Solution and Evaluation]

### <Pattern Formation>

A composition AL412 (manufactured by Brewer Science) for the formation of an underlayer film was applied to a silicon wafer with a diameter of 12 inches and baked at 205° C. for 60 seconds to form an underlayer film having a film thickness of 20 nm. A resist composition shown in Table 5 was applied to the underlayer film and baked at 100° C. for 60 seconds to form a resist film having a film thickness of 30 nm.

An EUV exposure device (Micro Exposure Tool manufactured by Exitech, NA: 0.3, Quadrupole, outer sigma: 0.68, inner sigma: 0.36) was used to subject the obtained silicon wafer having the resist film to pattern irradiation such that the average line width of the pattern was 14 nm. The reticle used was a mask with a line size of 14 nm and a line:space ratio of 1:1.

The resist film exposed to light was baked at 90° C. for 60 seconds, developed with an aqueous tetramethylammonium hydroxide solution (2.38% by mass) for 30 seconds, and rinsed with pure water for 30 seconds. The resulting silicon wafer was spin-dried to thereby obtain a positive-type pattern.

Two resist compositions, i.e., a resist composition immediately after its preparation and a resist composition stored in a thermostatic oven at 35° C. for 6 months after preparation, were used.

### <Evaluation>

The positive-type patterns obtained were used to evaluate the stability of the shape profile of the pattern formed using the resist composition stored for a long time using the evaluation method described above in <Pattern formation> in [Pattern formation by EUV exposure and development with organic solvent and evaluation].

The evaluation results are shown in Table 5.

TABLE 6

| | Resist | [Evaluation item 1] Stability |
|---|---|---|
| Table 5 | composition | of pattern shape over time |
| Example 2-1 | Re-1 | C |
| Example 2-2 | Re-2 | B |
| Example 2-3 | Re-3 | C |
| Example 2-4 | Re-4 | C |
| Example 2-5 | Re-5 | A |
| Example 2-6 | Re-6 | C |
| Example 2-7 | Re-7 | B |
| Example 2-8 | Re-8 | B |
| Example 2-9 | Re-9 | B |
| Example 2-10 | Re-10 | C |
| Example 2-11 | Re-11 | C |
| Example 2-12 | Re-12 | D |
| Example 2-13 | Re-13 | D |
| Example 2-14 | Re-14 | C |
| Example 2-15 | Re-15 | C |
| Example 2-16 | Re-16 | A |
| Example 2-17 | Re-17 | C |
| Example 2-18 | Re-18 | C |
| Example 2-19 | Re-19 | C |
| Example 2-20 | Re-20 | D |
| Example 2-21 | Re-21 | B |
| Example 2-22 | Re-22 | D |
| Example 2-23 | Re-23 | B |
| Example 2-24 | Re-24 | B |
| Example 2-25 | Re-25 | A |
| Example 2-26 | Re-26 | D |
| Example 2-27 | Re-27 | C |
| Example 2-28 | Re-28 | C |
| Example 2-29 | Re-29 | C |
| Example 2-30 | Re-30 | D |
| Example 2-31 | Re-31 | B |
| Example 2-32 | Re-32 | C |
| Example 2-33 | Re-33 | B |
| Example 2-34 | Re-34 | C |
| Example 2-35 | Re-35 | B |
| Example 2-36 | Re-36 | B |
| Example 2-37 | Re-37 | C |
| Example 2-38 | Re-38 | C |
| Example 2-39 | Re-39 | B |
| Example 2-40 | Re-40 | B |
| Example 2-41 | Re-41 | D |
| Example 2-42 | Re-42 | C |
| Example 2-43 | Re-43 | C |
| Example 2-44 | Re-44 | D |
| Example 2-45 | Re-45 | D |
| Comparative Example 2-1 | CRe-1 | E |

As is clear from the results shown in Table 5, even when the resist compositions of the invention stored for a long time were used for pattern formation (development with the alkali aqueous solution), the shape profiles of the patterns formed could be maintained (i.e., the shape profiles of the patterns formed were comparable to those of the patterns formed using the resist compositions immediately after their preparation).

As can be seen from the comparison among the Examples, when a resist composition satisfies at least one (preferable two or more, more preferably three or more, and still more preferably all four) of the following requirements Y1 to Y4, the shape profile of the pattern formed using the resist composition can be better maintained.
Requirement Y1: The group represented by A in the compound (specific onium salt) represented by formula (1), bonded to the nitrogen atom contained in W, and dissociable under the action of acid or light is the group represented by formula (3).
Requirement Y2: At least one of the organic cations represented by M₁⁺ and M₂⁺ in the compound (specific onium salt) represented by formula (1) has a halogen atom.
Requirement Y3: The structures of moieties corresponding to the “moiety represented by -L₁-Rf₁—X₁⁻” and the “moiety represented by -L₂-Rf₂—X₂⁻” in the compound (specific onium salt) represented by formula (1) are each the structure represented by formula (F1) or formula (F2).
Requirement Y4: The acid-decomposable resin (the resin (A)) has a repeating unit having a phenolic hydroxy group.

However, with the resist composition in the Comparative Example, the desired results were not obtained.

What is claimed is:

1. An actinic ray-sensitive or radiation-sensitive resin composition comprising:
an onium salt represented by formula (1);
an acid-decomposable resin; and
a solvent: 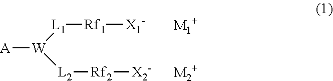
wherein, in formula (1), W represents a trivalent group having a nitrogen atom;
A represents a group that is bonded to the nitrogen atom included in W and that is dissociable under the action of acid or light; when A is dissociated under the action of acid or light, a primary amino group including the nitrogen atom or a secondary amino group including the nitrogen atom is generated;
L₁ and L₂ each independently represent *—O—**, *—CO—O—**, *—SO₂—**, *—O—CO—O—**, or *—O—SO₂—**; * represents a bonding position to W; ** represents a bonding position to Rf₁ or Rf₂;
Rf₁ and Rf₂ each independently represent a divalent organic group having a fluorine atom;
X₁⁻ and X₂⁻ each independently represent *—SO₃⁻, *—SO₂—N⁻—Y, or a group represented by formula (2); * represents a bonding position; Y represents an electron-withdrawing group; and M₁⁺ and M₂⁺ each independently represent an organic cation: 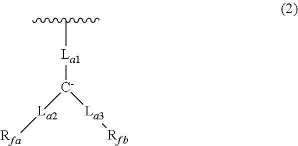
wherein, in formula (2), Lₐ₁, Lₐ₂, and Las each independently represent —CO— or —SO₂—;
R_{fa} and R_{f} each independently represent a fluorinated alkyl group; and a wavy line represents a bonding position to Rf₁ or Rf₂.

2. The actinic ray-sensitive or radiation-sensitive resin composition according to claim 1, wherein W represents a group represented by any of formulas (W1) to (W4): 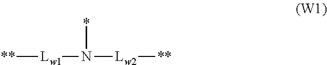
wherein, in formula (W1), L_{W1} and L_{W2} each independently represent a divalent linking group;
* represents a bonding position to A; and ** represents a bonding position to L₁ or L₂: 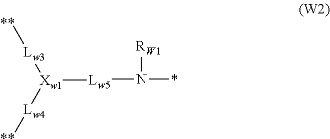
wherein, in formula (W2), L_{W3} and L_{W4} each independently represent a single bond or an alkylene group optionally including at least one of —S— or —O—;
L_{W5} represents a single bond or a divalent linking group;
R_{W1} represents a hydrogen atom or an alkyl group;
X_{W1} represents a trivalent aromatic ring group or a trivalent aliphatic ring group;
* represents a bonding position to A; and ** represents a bonding position to L₁ or L₂: 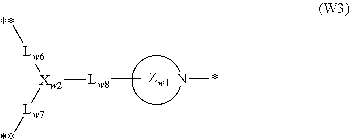
wherein, in formula (W3), L_{W6} and L_{W7} each independently represent a single bond or an alkylene group optionally including at least one of —S— or —O—;
L_{W8} represents a single bond or a divalent linking group;
X_{W2} represents a trivalent aromatic ring group or a trivalent aliphatic ring group;
Z_{W1} represents a ring including a nitrogen atom as a ring member atom;
* represents a bonding position to A; and ** represents a bonding position to L₁ or L₂: 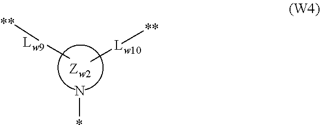
wherein, in formula (W4), L_{W9} and L_{W10} each independently represent a single bond or a divalent linking group;
Z_{W2} represents a ring including a nitrogen atom as a ring member atom;
* represents a bonding position to A, and ** represents a bonding position to L₁ or L₂.

3. The actinic ray-sensitive or radiation-sensitive resin composition according to claim 1, wherein A represents a group represented by formula (3): 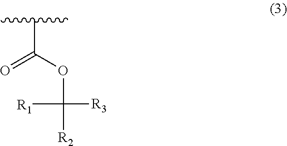
wherein, in formula (3), R₁, R₂, and R₃ each independently represent an organic group; two selected from the group consisting of R₁, R₂, and R₃ may be bonded together to form a ring; and
a wavy line represents a bonding position to the nitrogen atom included in W.

4. The actinic ray-sensitive or radiation-sensitive resin composition according to claim 1, wherein at least one of M₁⁺ or M₂⁺ is an organic cation having a halogen atom in a molecule thereof.

5. The actinic ray-sensitive or radiation-sensitive resin composition according to claim 1, wherein the acid-decomposable resin includes a repeating unit having a phenolic hydroxy group.

6. A resist film formed of the actinic ray-sensitive or radiation-sensitive resin composition according to claim 1.

7. A pattern forming method comprising the steps of:
forming a resist film on a substrate using the actinic ray-sensitive or radiation-sensitive resin composition according to claim 1;
exposing the resist film to light; and
developing the resist film exposed to the light using a developer to form a pattern.

8. A method for producing an electronic device, the method comprising the pattern forming method according to claim 7.

9. The actinic ray-sensitive or radiation-sensitive resin composition according to claim 2, wherein A represents a group represented by formula (3): 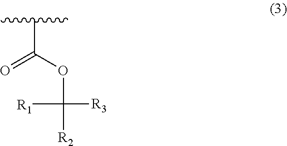
wherein, in formula (3), R₁, R₂, and R₃ each independently represent an organic group;
two selected from the group consisting of R₁, R₂, and R₃ may be bonded together to form a ring; and
a wavy line represents a bonding position to the nitrogen atom included in W.

10. The actinic ray-sensitive or radiation-sensitive resin composition according to claim 2, wherein at least one of M₁⁺ or M₂⁺ is an organic cation having a halogen atom in a molecule thereof.

11. The actinic ray-sensitive or radiation-sensitive resin composition according to claim 2, wherein the acid-decomposable resin includes a repeating unit having a phenolic hydroxy group.

12. A resist film formed of the actinic ray-sensitive or radiation-sensitive resin composition according to claim 2.

13. A pattern forming method comprising the steps of:
forming a resist film on a substrate using the actinic ray-sensitive or radiation-sensitive resin composition according to claim 2;
exposing the resist film to light; and
developing the resist film exposed to the light using a developer to form a pattern.

14. A method for producing an electronic device, the method comprising the pattern forming method according to claim 13.

15. The actinic ray-sensitive or radiation-sensitive resin composition according to claim 3, wherein at least one of M₁⁺ or M₂⁺ is an organic cation having a halogen atom in a molecule thereof.

16. The actinic ray-sensitive or radiation-sensitive resin composition according to claim 3, wherein the acid-decomposable resin includes a repeating unit having a phenolic hydroxy group.

17. A resist film formed of the actinic ray-sensitive or radiation-sensitive resin composition according to claim 3.

18. A pattern forming method comprising the steps of:
forming a resist film on a substrate using the actinic ray-sensitive or radiation-sensitive resin composition according to claim 3;
exposing the resist film to light; and
developing the resist film exposed to the light using a developer to form a pattern.

19. A method for producing an electronic device, the method comprising the pattern forming method according to claim 18.

20. The actinic ray-sensitive or radiation-sensitive resin composition according to claim 4, wherein the acid-decomposable resin includes a repeating unit having a phenolic hydroxy group.
